(19) United States
(12) Patent Application Publication
(10) Pub. No.: US 2026/0195049 A1
(43) Pub. Date: Jul. 9, 2026

(54) REDUCING TEMPORAL FAILURE CORRELATION ACROSS DATA STRIPES IN A STORAGE SYSTEM

(71) Applicant: PURE STORAGE, INC., SANTA CLARA, CA (US)

(72) Inventors: ERIC VERWILLOW, MOUNTAIN VIEW, CA (US); HARI KANNAN, LOS ALTOS, CA (US)

(21) Appl. No.: 19/556,968

(22) Filed: Mar. 4, 2026

Related U.S. Application Data
(63) Continuation-in-part of application No. 19/067,578, filed on Feb. 28, 2025.
Application No. 19/067,578 is a continuation-in-part of application No. 18/954,379, filed on Nov. 20, 2024, now abandoned.
Application No. 18/954,379 is a continuation of application No. 15/605,840, filed on May 25, 2017, now abandoned.

(51) Int. Cl. G06F 3/06; G06F 12/02; G11C 16/14

(52) U.S. Cl. CPC G06F 3/0616; G06F 3/0631; G06F 3/0688; G06F 12/0246; G06F 12/0253; G11C 16/14; G06F 2212/7205

(57) ABSTRACT

A method to reduce time-related failure correlations across data stripes is provided. The method includes receiving a stripe of data to be written across a plurality of storage devices, the stripe of data comprising a plurality of shards to be written to different devices of the plurality of storage devices, varying, for each shard of the plurality of shards, one or more data storage parameters associated with storing the plurality of shards at the plurality of storage devices, and writing the plurality of shards to the plurality of storage devices based on the varied one or more data storage parameters, wherein the varied one or more data storage parameters reduce temporal correlation among the plurality of shards written to the plurality of storage devices.

### CROSS REFERENCE TO RELATED APPLICATIONS

This application is a continuation-in-part application for patent entitled to a filing date and claiming the benefit of earlier-filed U.S. Patent Application No. 19/067,578, filed February 28, 2025, which is a continuation-in-part application of U.S. Patent Application No. 18/954,379, filed November 20, 2024, which is a continuation application of U.S. Patent Application No. 15/605,840, filed May 25, 2017, all of which are hereby incorporated herein by reference in their entirety.

### BACKGROUND

Storage systems such as storage arrays and storage clusters are expected to have high reliability for writing, storing and reading data. Use of redundant data, error correction coding, data rebuilds in case of failure and other techniques and mechanisms act to improve long-term system reliability, but there is always a need for more improvement. Solid-state memory such as flash memory experiences wear from repeated program and erasure (P/E) cycles or write cycles, and can fail as the memory cells wear out over time. There is concern that multiple solid-state drive failures in a storage system designed for recovery from a lesser number of solid-state drive failures could prove catastrophic, resulting in unrecoverable data loss and damaging system reliability. It is within this context that the embodiments arise.

### SUMMARY

In some embodiments, a method to increase long-term system reliability of a storage system is provided. The method includes selecting one of a plurality of solid-state drives or solid-state storage blades of the storage system and biasing one or more storage system operations that include writing to or erasing solid-state memory towards the one of the plurality of solid-state drives or solid-state storage blades. The method includes performing the one or more storage system operations in repetition over time, with the biasing, so as to have increased wear on the one of the plurality of solid-state drives or solid-state storage blades in comparison to others of the plurality of solid-state drives or solid-state storage blades. The method may be embodied as computer readable instructions.

In some embodiments, a storage system is provided. The system includes a plurality of solid-state drives or solid-state storage blades and one or more processors coupled to or included in the plurality of solid-state drives or solid-state storage blades. The one or more processors are configurable to select one of the plurality of solid-state drives or solid-state storage blades, establish a rule of emphasizing usage of the selected one of the plurality of solid-state drives or solid-state storage blades in one or more storage system operations that include writing to or erasing solid-state memory, and perform the one or more storage system operations in repetition over time in accordance with the rule, to increase wear on the one of the plurality of solid-state drives or solid-state storage blades in comparison to others of the plurality of solid-state drives or solid-state storage blades.

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

The present disclosure is illustrated by way of example, and not by way of limitation, and can be more fully understood with reference to the following detailed description when considered in connection with the figures as described below.

FIG. 1A illustrates a first example system for data storage in accordance with some implementations.

FIG. 1B illustrates a second example system for data storage in accordance with some implementations.

FIG. 1C illustrates a third example system for data storage in accordance with some implementations.

FIG. 1D illustrates a fourth example system for data storage in accordance with some implementations.

FIG. 2A is a perspective view of a storage cluster with multiple storage nodes and internal storage coupled to each storage node to provide network attached storage, in accordance with some embodiments.

FIG. 2B is a block diagram showing an interconnect switch coupling multiple storage nodes in accordance with some embodiments.

FIG. 2C is a multiple level block diagram, showing contents of a storage node and contents of one of the non-volatile solid state storage units in accordance with some embodiments.

FIG. 2D shows a storage server environment, which uses embodiments of the storage nodes and storage units of FIGS. 1-3 in accordance with some embodiments.

FIG. 2E is a blade hardware block diagram, showing a control plane, compute and storage planes, and authorities interacting with underlying physical resources, in accordance with some embodiments.

FIG. 2F depicts elasticity software layers in blades of a storage cluster, in accordance with some embodiments.

FIG. 2G depicts authorities and storage resources in blades of a storage cluster, in accordance with some embodiments.

FIG. 3A sets forth a diagram of a storage system that is coupled for data communications with a cloud services provider in accordance with some embodiments of the present disclosure.

FIG. 3B sets forth a diagram of a storage system in accordance with some embodiments of the present disclosure.

FIG. 4A is a diagram of a storage array with rule(s) that emphasize usage of a specified solid-state storage drive, to increase long-term system reliability in accordance with some embodiments.

FIG. 4B is a diagram of a storage cluster with rule(s) that emphasize usage of a specified blade, to increase long-term system reliability in accordance with some embodiments.

FIG. 5 depicts example data stripes that emphasize usage of a specified blade, suitable for the storage cluster of FIG. 4B in accordance with some embodiments.

FIG. 6 depicts example write groups that emphasize usage of a specified solid-state storage drive, suitable for the storage array of FIG. 4A in accordance with some embodiments.

FIG. 7 depicts example data stripes for writing hot data to emphasize usage of a specified solid-state storage drive or blade, and data stripes for writing cold data to exclude usage of a specified solid-state storage drive or blade, suitable for the storage array of FIG. 4A or the storage cluster of FIG. 4B in accordance with some embodiments.

FIG. 8 shows a garbage collection module that is more active on a selected solid-state storage drive or blade, and less active on other solid-state storage drives or blades, suitable for the storage array of FIG. 4A or the storage cluster of FIG. 4B in accordance with some embodiments.

FIG. 9 shows page group writing recommendations, relative to word lines or bit columns, for read reliability in accordance with some embodiments.

FIG. 10 shows a technique of writing junk pages in differing amounts to starting physical addresses in flash memory, for read reliability in accordance with some embodiments.

FIG. 11 is a flow diagram of a method to increase long-term reliability of a storage system, which can be practiced by embodiments of storage systems, including storage arrays and storage clusters described herein in accordance with some embodiments.

FIG. 12 is an illustration showing an exemplary computing device which may implement the embodiments described herein.

FIG. 13A is a block diagram illustrating a system for training a neural network to predict storage device lifecycle and failure, in accordance with embodiments described herein.

FIG. 13B is a block diagram illustrating a system to collect operating data and metrics may be from various sources within a storage system for training of and use by a failure prediction model, in accordance with embodiments described herein.

FIG. 13C is a block diagram illustrating a system for aggregating and down-sampling data collected from various sources within a storage system, in accordance with embodiments described herein.

FIG. 14 is a block diagram illustrating a system for applying a trained neural network to predict storage device lifecycle and failure, in accordance with embodiments described herein.

FIG. 15 is a block illustrating a local deployment of a failure prediction model to a storage device to estimate lifecycle and failure of the storage device, in accordance with embodiments described herein.

FIG. 16 is a flow diagram of a method of training a neural network to predict storage device lifecycle and failure, in accordance with embodiments described herein.

FIG. 17 is a flow diagram of a method of applying a trained neural network to storage device data to predict storage device lifecycle and failure, in accordance with embodiments described herein.

FIG. 18 is a block diagram illustrating an example system for varying data storage parameters across shards of a data stripe to reduce time-related correlations among the shards, according to some embodiments.

FIG. 19 is a flow diagram illustrating an example method of varying data storage parameters across shards of a data stripe to reduce time-related correlations among the shards, according to some embodiments.

### DETAILED DESCRIPTION

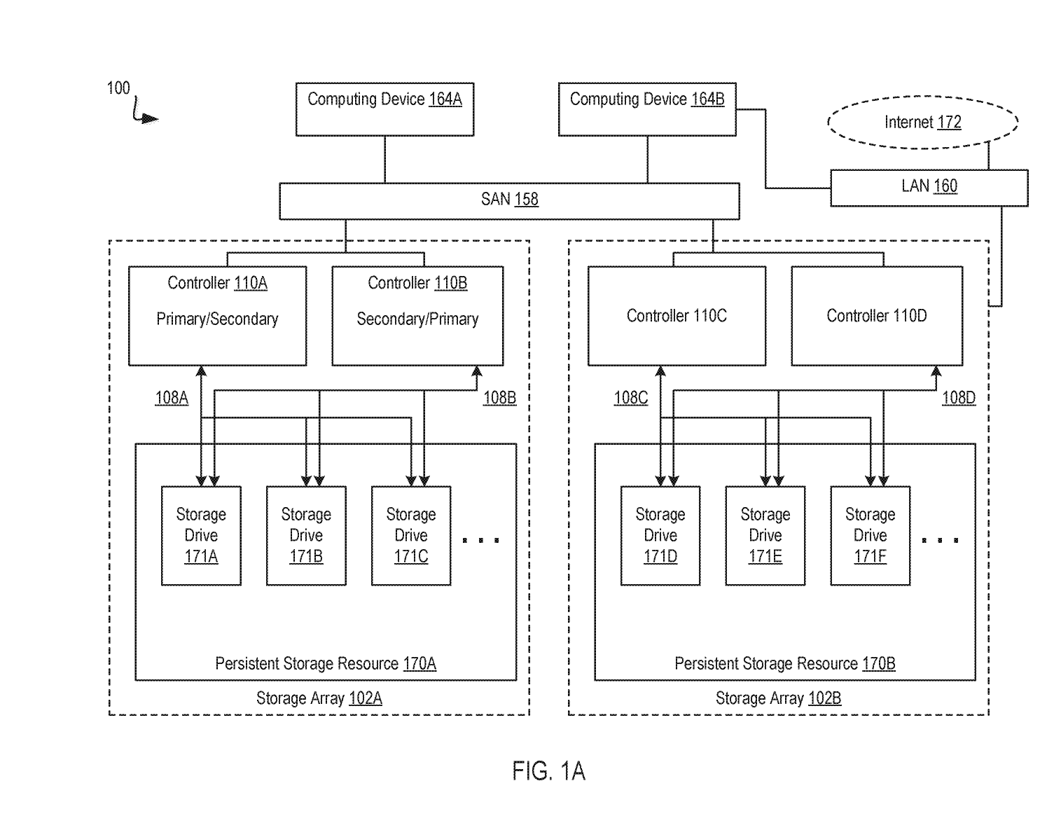

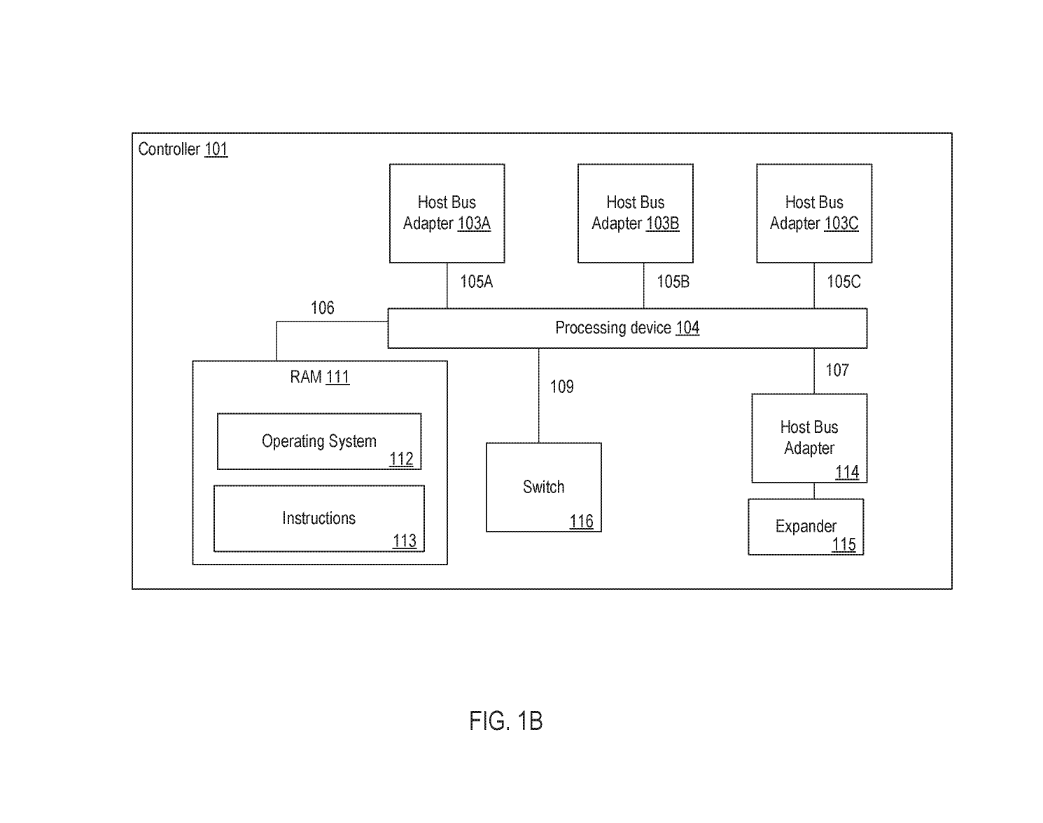

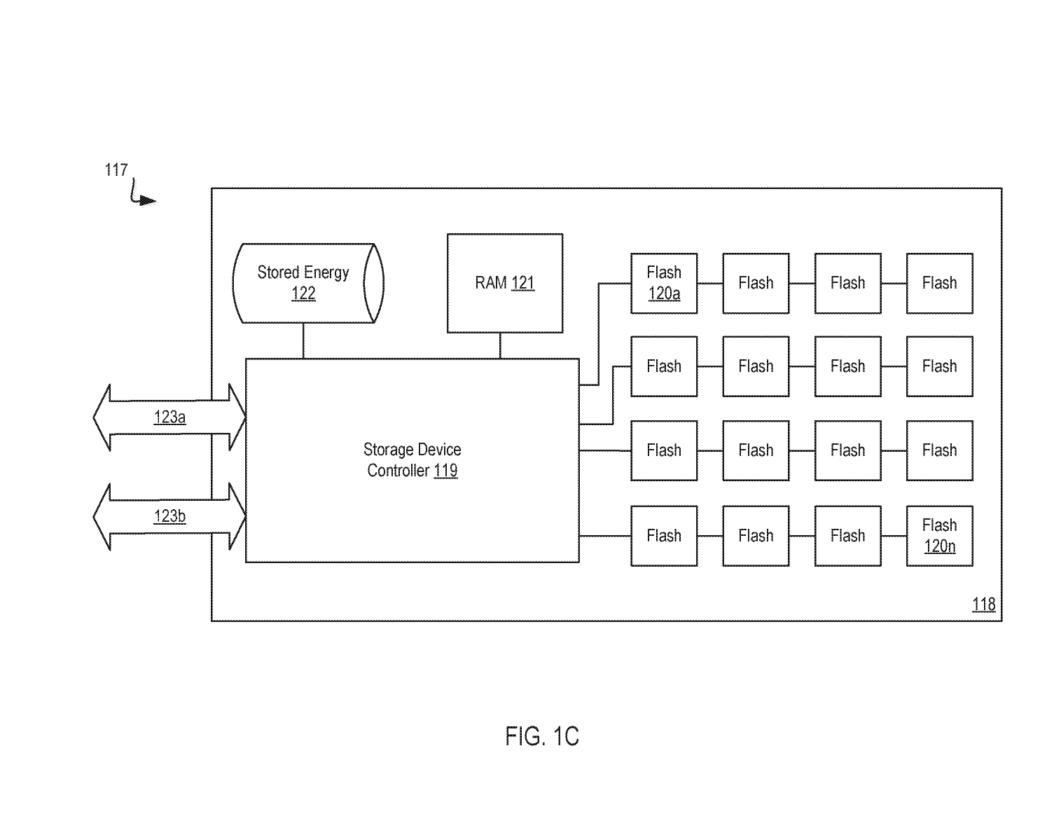

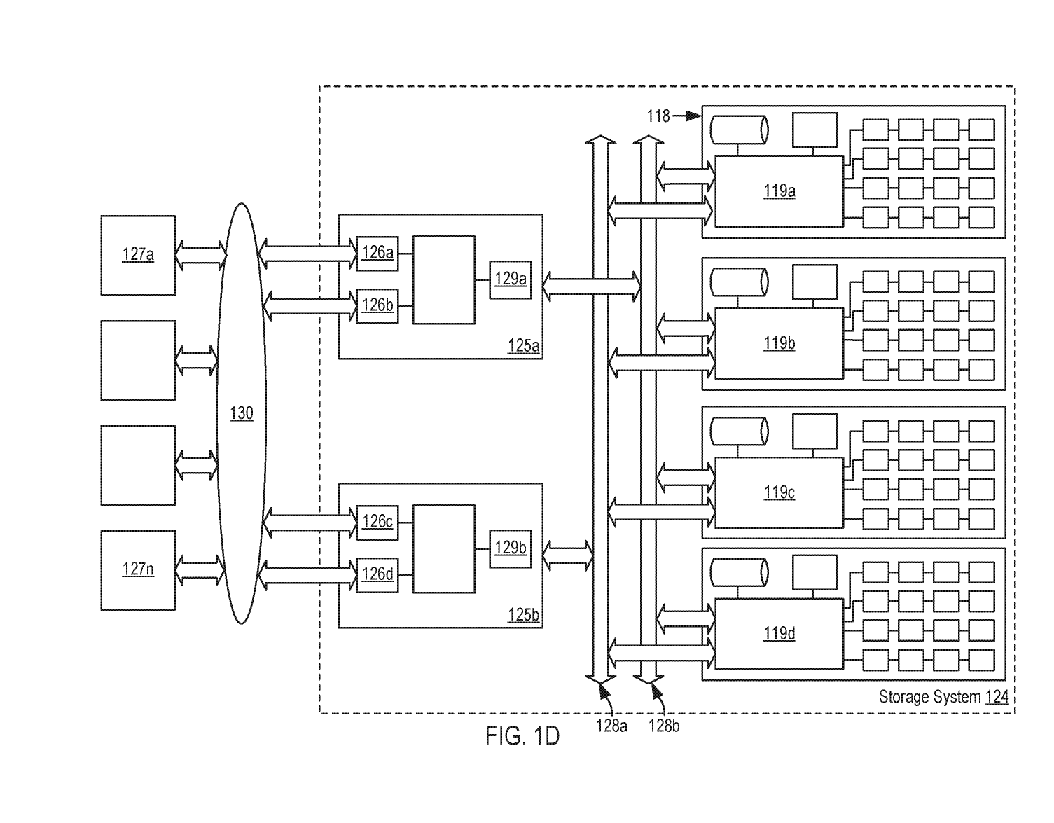

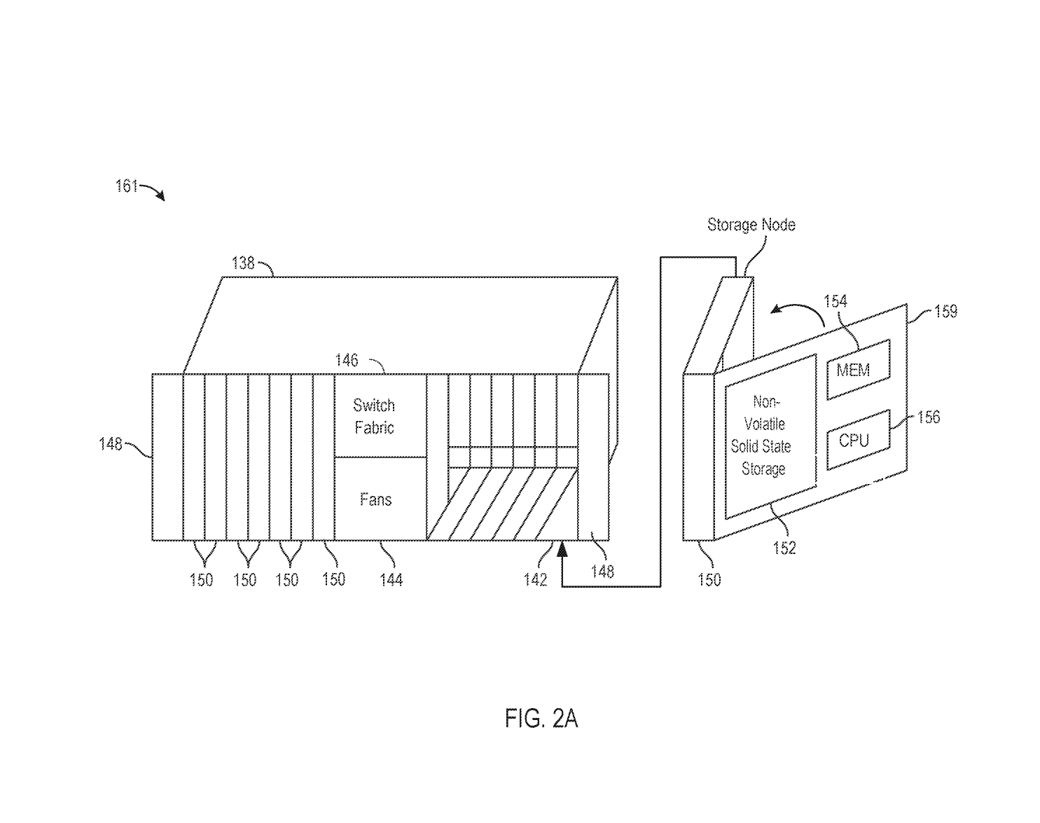

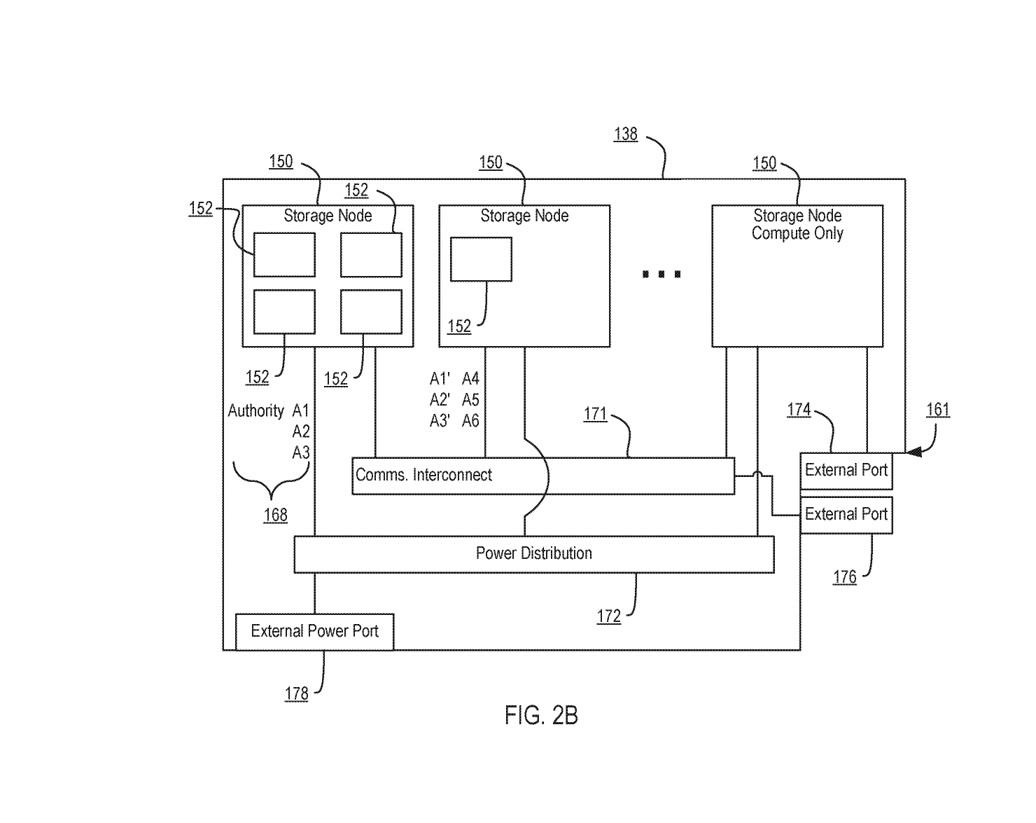

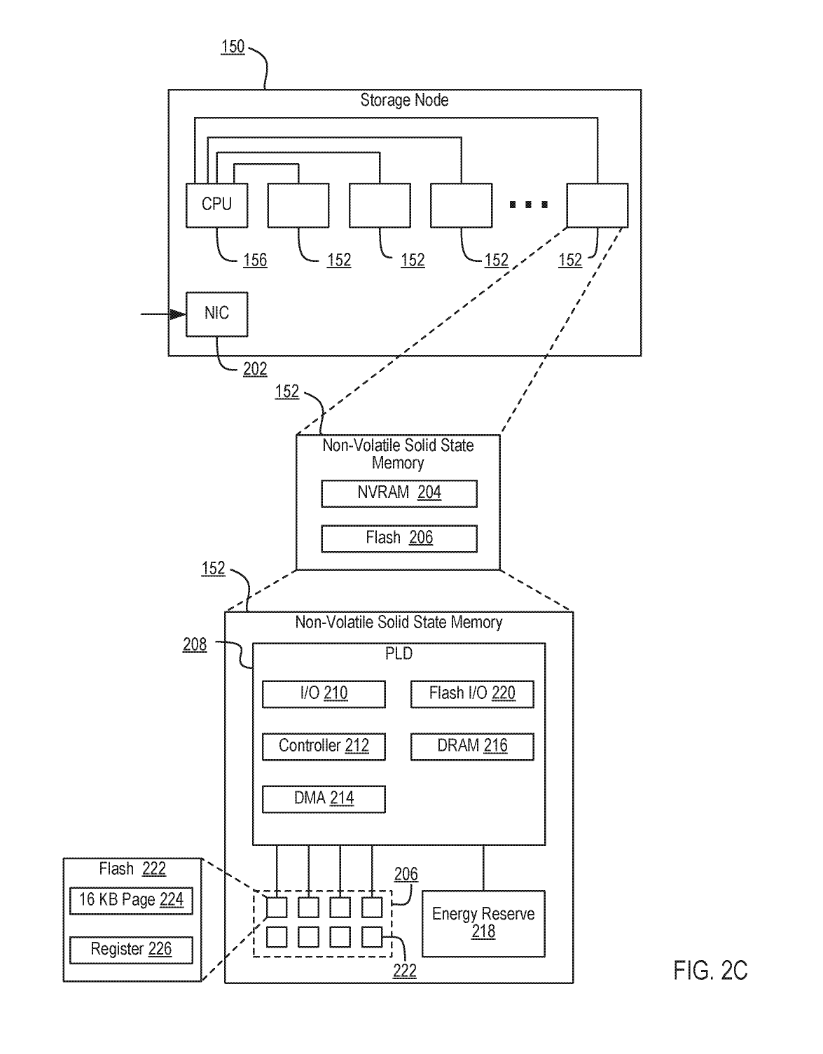

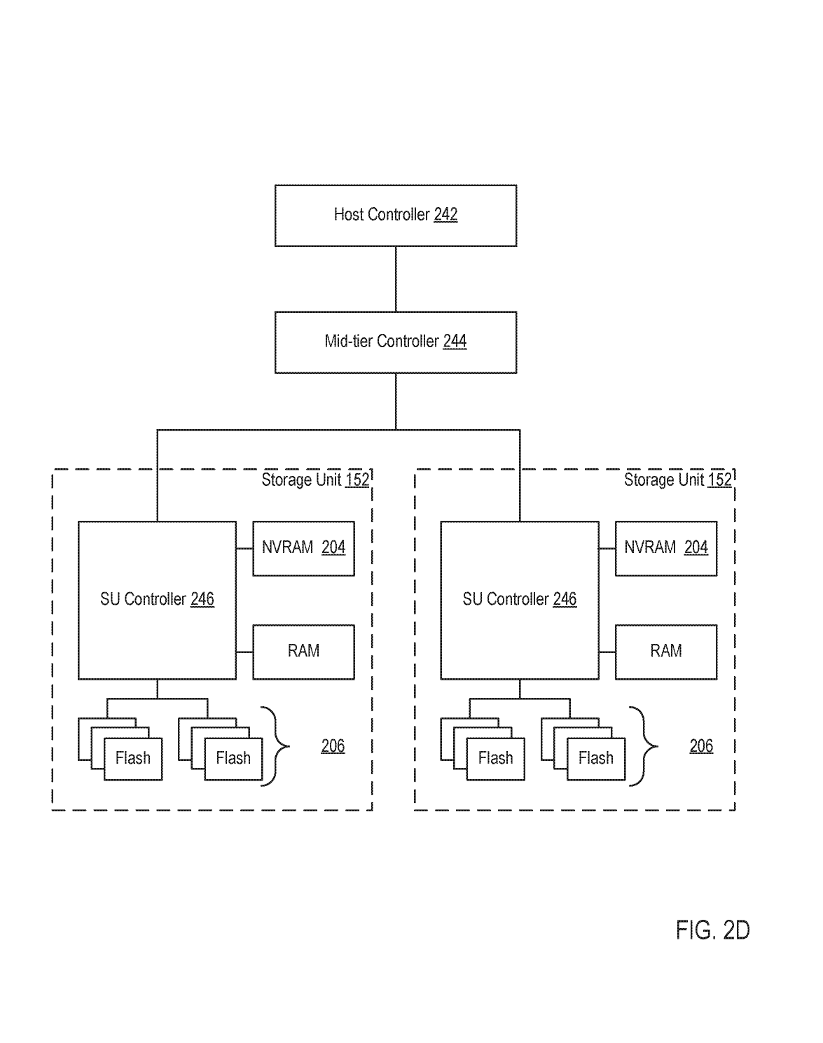

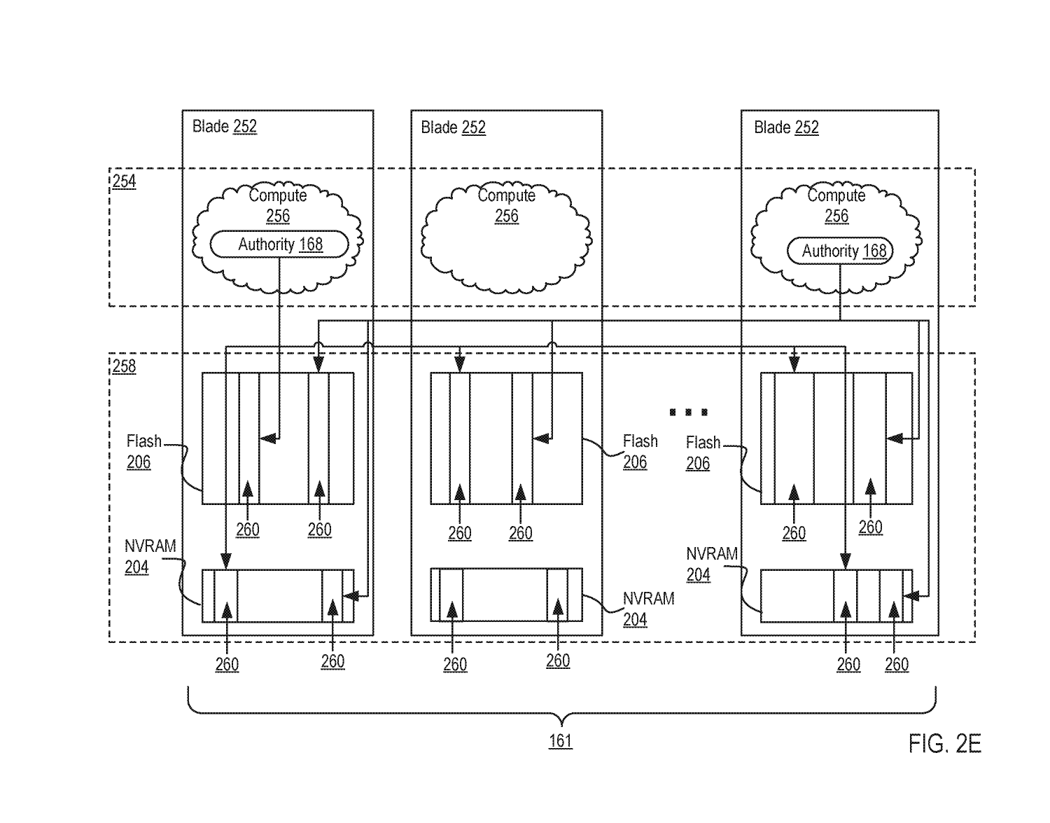

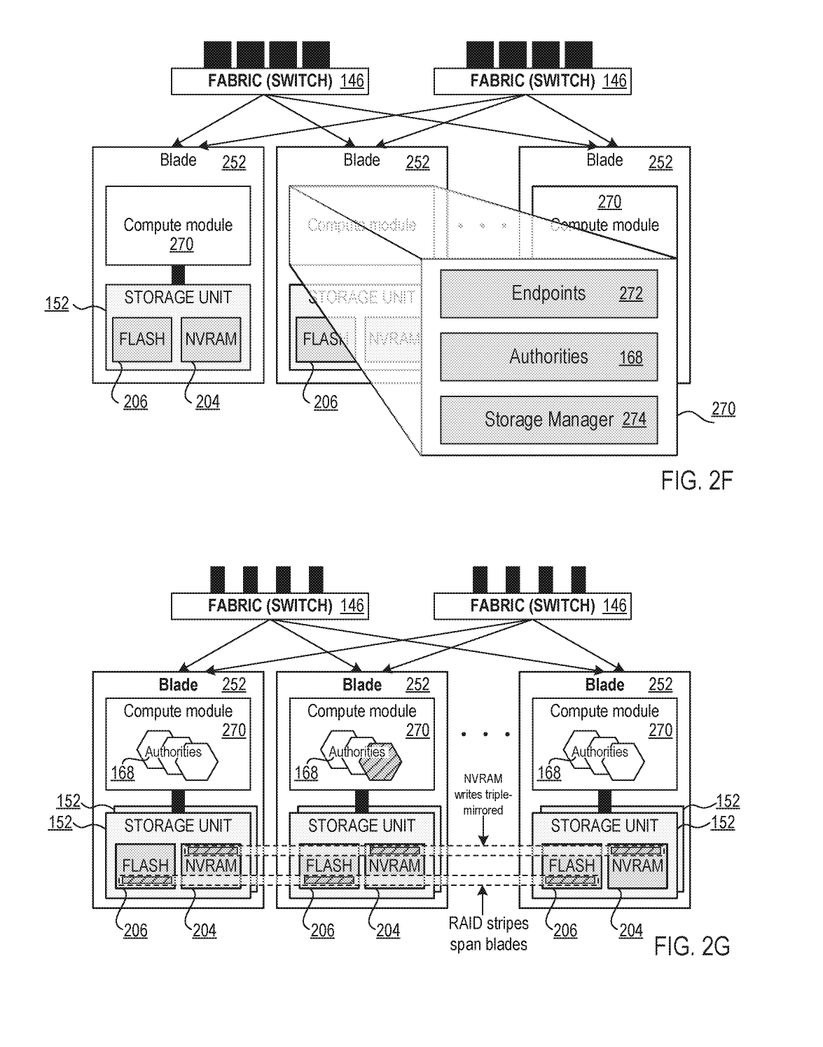

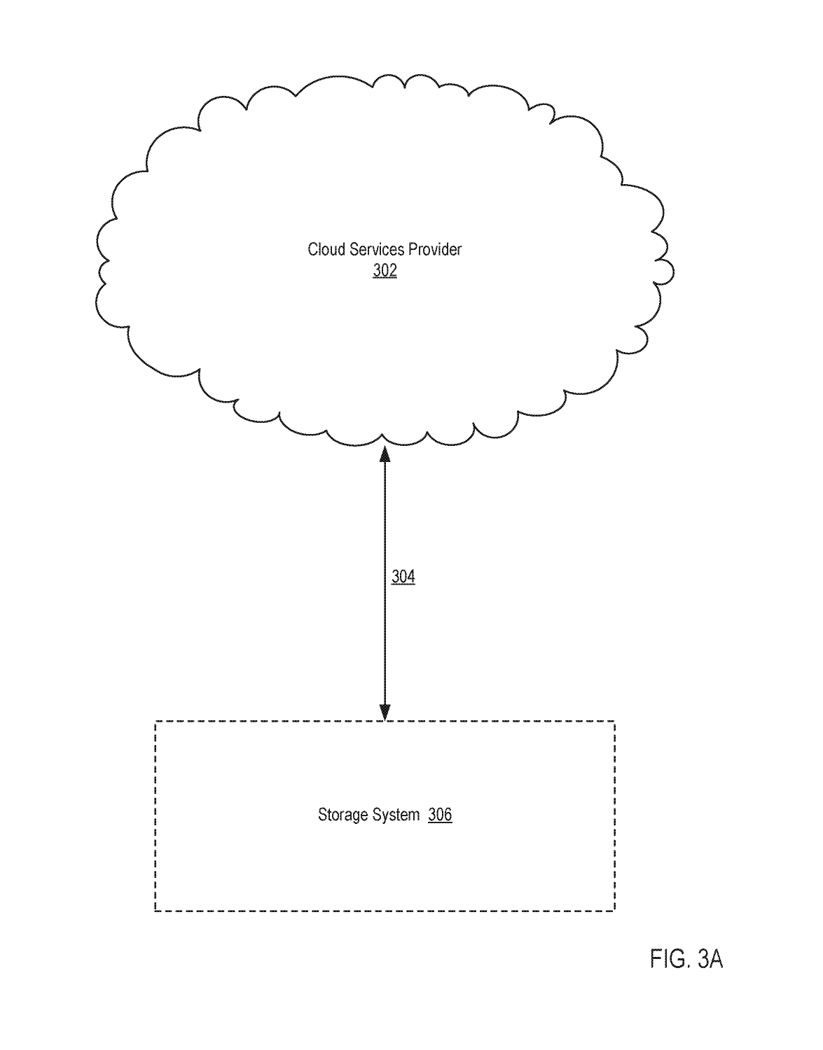

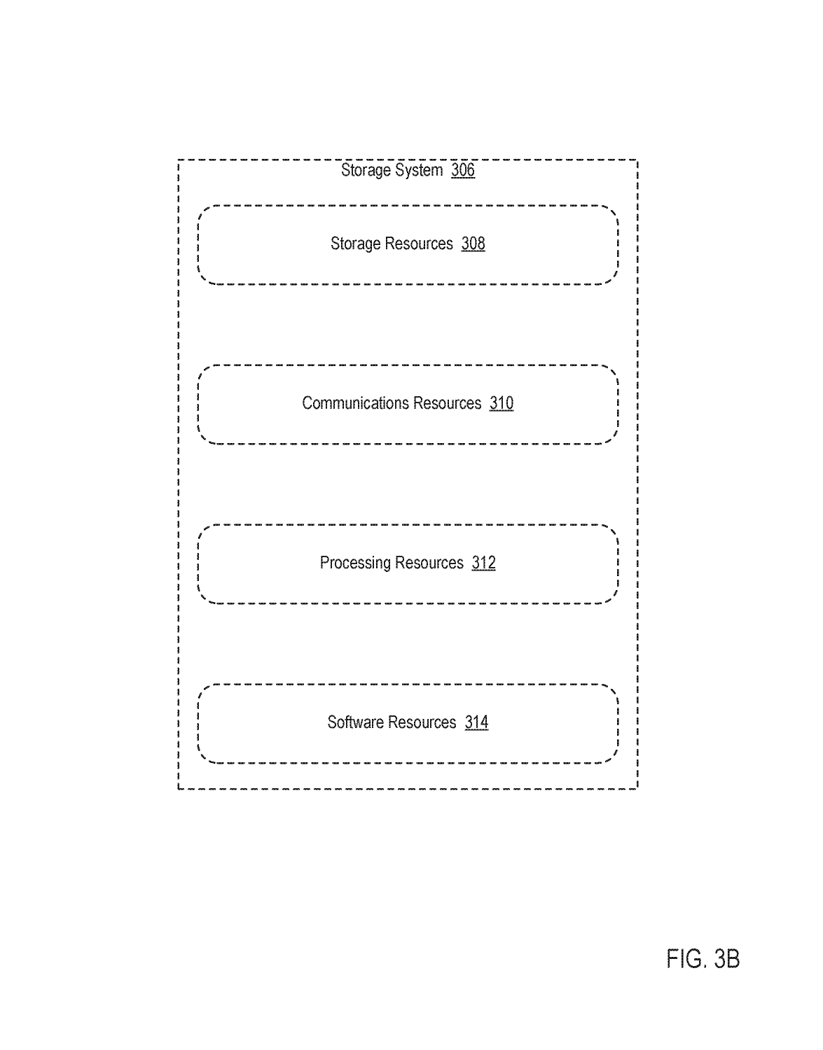

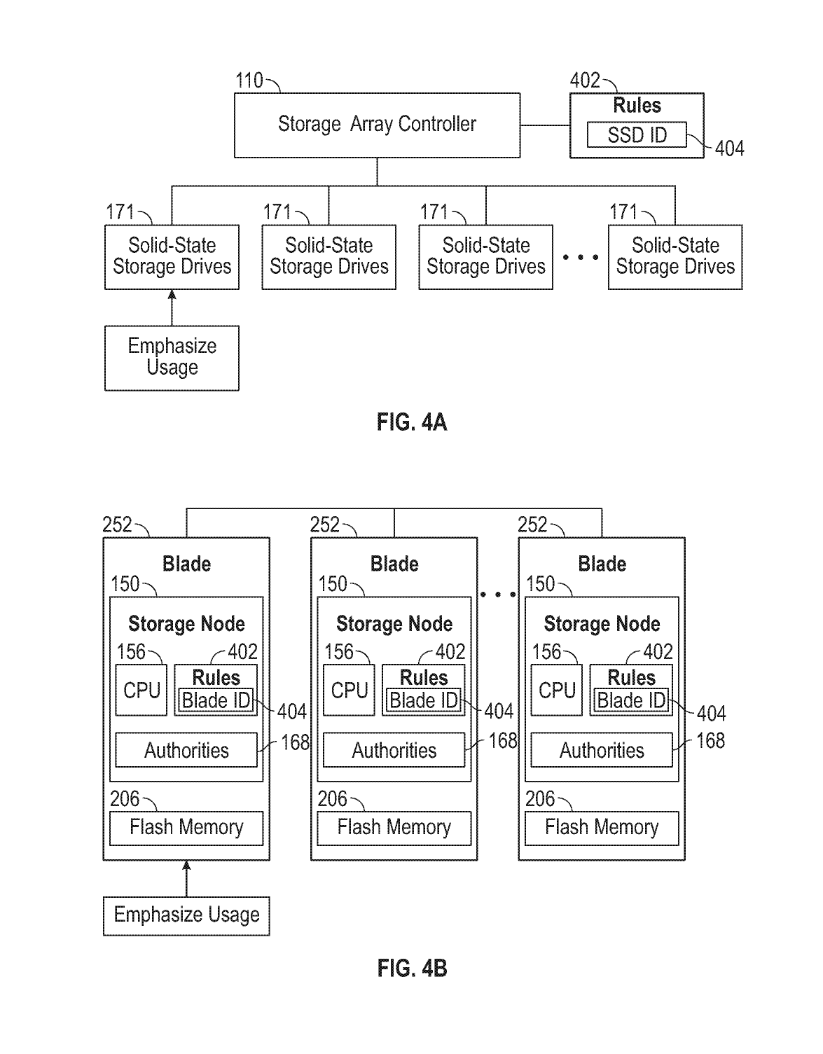

Solid-state storage systems described herein have multiple mechanisms for system reliability. A storage array with high availability storage array controller and flash memory has a stored energy device and may use mirroring and erasure coding, as shown and described with reference to FIGS. 1A-1D. A storage cluster with flash memory has an energy reserve, erasure coding and metadata redundancy, as shown and described with reference to FIGS. 2A-3B. Mechanisms for further increasing storage system reliability are described with reference to FIGS. 4A-11.

FIG. 1A illustrates an example system for data storage, in accordance with some implementations. System 100 (also referred to as “storage system” herein) includes numerous elements for purposes of illustration rather than limitation. It may be noted that system 100 may include the same, more, or fewer elements configured in the same or different manner in other implementations.

System 100 includes a number of computing devices 164. Computing devices (also referred to as “client devices” herein) may be for example, a server in a data center, a workstation, a personal computer, a notebook, or the like. Computing devices 164 are coupled for data communications to one or more storage arrays 102 through a storage area network (SAN) 158 or a local area network (LAN) 160.

The SAN 158 may be implemented with a variety of data communications fabrics, devices, and protocols. For example, the fabrics for SAN 158 may include Fibre Channel, Ethernet, Infiniband, Serial Attached Small Computer System Interface (SAS), or the like. Data communications protocols for use with SAN 158 may include Advanced Technology Attachment (ATA), Fibre Channel Protocol, Small Computer System Interface (SCSI), Internet Small Computer System Interface (iSCSI), HyperSCSI, Non-Volatile Memory Express (NVMe) over Fabrics, or the like. It may be noted that SAN 158 is provided for illustration, rather than limitation. Other data communication couplings may be implemented between computing devices 164 and storage arrays 102.

The LAN 160 may also be implemented with a variety of fabrics, devices, and protocols. For example, the fabrics for LAN 160 may include Ethernet (802.3), wireless (802.11), or the like. Data communication protocols for use in LAN 160 may include Transmission Control Protocol (TCP), User Datagram Protocol (UDP), Internet Protocol (IP), HyperText Transfer Protocol (HTTP), Wireless Access Protocol (WAP), Handheld Device Transport Protocol (HDTP), Session Initiation Protocol (SIP), Real Time Protocol (RTP), or the like.

Storage arrays 102 may provide persistent data storage for the computing devices 164. Storage array 102A may be contained in a chassis (not shown), and storage array 102B may be contained in another chassis (not shown), in implementations. Storage array 102A and 102B may include one or more storage array controllers 110 (also referred to as “controller” herein). A storage array controller 110 may be embodied as a module of automated computing machinery comprising computer hardware, computer software, or a combination of computer hardware and software. In some implementations, the storage array controllers 110 may be configured to carry out various storage tasks. Storage tasks may include writing data received from the computing devices 164 to storage array 102, erasing data from storage array 102, retrieving data from storage array 102 and providing data to computing devices 164, monitoring and reporting of disk utilization and performance, performing redundancy operations, such as Redundant Array of Independent Drives (RAID) or RAID-like data redundancy operations, compressing data, encrypting data, and so forth.

Storage array controller 110 may be implemented in a variety of ways, including as a Field Programmable Gate Array (FPGA), a Programmable Logic Chip (PLC), an Application Specific Integrated Circuit (ASIC), System-on-Chip (SOC), or any computing device that includes discrete components such as a processing device, central processing unit, computer memory, or various adapters. Storage array controller 110 may include, for example, a data communications adapter configured to support communications via the SAN 158 or LAN 160. In some implementations, storage array controller 110 may be independently coupled to the LAN 160. In implementations, storage array controller 110 may include an I/O controller or the like that couples the storage array controller 110 for data communications, through a midplane (not shown), to a persistent storage resource 170 (also referred to as a “storage resource” herein). The persistent storage resource 170 main include any number of storage drives 171 (also referred to as “storage devices” herein) and any number of non-volatile Random Access Memory (NVRAM) devices (not shown).

In some implementations, the NVRAM devices of a persistent storage resource 170 may be configured to receive, from the storage array controller 110, data to be stored in the storage drives 171. In some examples, the data may originate from computing devices 164. In some examples, writing data to the NVRAM device may be carried out more quickly than directly writing data to the storage drive 171. In implementations, the storage array controller 110 may be configured to utilize the NVRAM devices as a quickly accessible buffer for data destined to be written to the storage drives 171. Latency for write requests using NVRAM devices as a buffer may be improved relative to a system in which a storage array controller 110 writes data directly to the storage drives 171. In some implementations, the NVRAM devices may be implemented with computer memory in the form of high bandwidth, low latency RAM. The NVRAM device is referred to as “non-volatile” because the NVRAM device may receive or include a unique power source that maintains the state of the RAM after main power loss to the NVRAM device. Such a power source may be a battery, one or more capacitors, or the like. In response to a power loss, the NVRAM device may be configured to write the contents of the RAM to a persistent storage, such as the storage drives 171.

In implementations, storage drive 171 may refer to any device configured to record data persistently, where “persistently” or “persistent” refers to a device’s ability to maintain recorded data after loss of power. In some implementations, storage drive 171 may correspond to non-disk storage media. For example, the storage drive 171 may be one or more solid-state drives (SSDs), flash memory based storage, any type of solid-state non-volatile memory, or any other type of non-mechanical storage device. In other implementations, storage drive 171 may include mechanical or spinning hard disk, such as hard-disk drives (HDD).

In some implementations, the storage array controllers 110 may be configured for offloading device management responsibilities from storage drive 171 in storage array 102. For example, storage array controllers 110 may manage control information that may describe the state of one or more memory blocks in the storage drives 171. The control information may indicate, for example, that a particular memory block has failed and should no longer be written to, that a particular memory block contains boot code for a storage array controller 110, the number of program-erase (P/E) cycles that have been performed on a particular memory block, the age of data stored in a particular memory block, the type of data that is stored in a particular memory block, and so forth. In some implementations, the control information may be stored with an associated memory block as metadata. In other implementations, the control information for the storage drives 171 may be stored in one or more particular memory blocks of the storage drives 171 that are selected by the storage array controller 110. The selected memory blocks may be tagged with an identifier indicating that the selected memory block contains control information. The identifier may be utilized by the storage array controllers 110 in conjunction with storage drives 171 to quickly identify the memory blocks that contain control information. For example, the storage controllers 110 may issue a command to locate memory blocks that contain control information. It may be noted that control information may be so large that parts of the control information may be stored in multiple locations, that the control information may be stored in multiple locations for purposes of redundancy, for example, or that the control information may otherwise be distributed across multiple memory blocks in the storage drive 171.

In implementations, storage array controllers 110 may offload device management responsibilities from storage drives 171 of storage array 102 by retrieving, from the storage drives 171, control information describing the state of one or more memory blocks in the storage drives 171. Retrieving the control information from the storage drives 171 may be carried out, for example, by the storage array controller 110 querying the storage drives 171 for the location of control information for a particular storage drive 171. The storage drives 171 may be configured to execute instructions that enable the storage drive 171 to identify the location of the control information. The instructions may be executed by a controller (not shown) associated with or otherwise located on the storage drive 171 and may cause the storage drive 171 to scan a portion of each memory block to identify the memory blocks that store control information for the storage drives 171. The storage drives 171 may respond by sending a response message to the storage array controller 110 that includes the location of control information for the storage drive 171. Responsive to receiving the response message, storage array controllers 110 may issue a request to read data stored at the address associated with the location of control information for the storage drives 171.

In other implementations, the storage array controllers 110 may further offload device management responsibilities from storage drives 171 by performing, in response to receiving the control information, a storage drive management operation. A storage drive management operation may include, for example, an operation that is typically performed by the storage drive 171 (e.g., the controller (not shown) associated with a particular storage drive 171). A storage drive management operation may include, for example, ensuring that data is not written to failed memory blocks within the storage drive 171, ensuring that data is written to memory blocks within the storage drive 171 in such a way that adequate wear leveling is achieved, and so forth.

In implementations, storage array 102 may implement two or more storage array controllers 110. For example, storage array 102A may include storage array controllers 110A and storage array controllers 110B. At a given instance, a single storage array controller 110 (e.g., storage array controller 110A) of a storage system 100 may be designated with primary status (also referred to as “primary controller” herein), and other storage array controllers 110 (e.g., storage array controller 110A) may be designated with secondary status (also referred to as “secondary controller” herein). The primary controller may have particular rights, such as permission to alter data in persistent storage resource 170 (e.g., writing data to persistent storage resource 170). At least some of the rights of the primary controller may supersede the rights of the secondary controller. For instance, the secondary controller may not have permission to alter data in persistent storage resource 170 when the primary controller has the right. The status of storage array controllers 110 may change. For example, storage array controller 110A may be designated with secondary status, and storage array controller 110B may be designated with primary status.

In some implementations, a primary controller, such as storage array controller 110A, may serve as the primary controller for one or more storage arrays 102, and a second controller, such as storage array controller 110B, may serve as the secondary controller for the one or more storage arrays 102. For example, storage array controller 110A may be the primary controller for storage array 102A and storage array 102B, and storage array controller 110B may be the secondary controller for storage array 102A and 102B. In some implementations, storage array controllers 110C and 110D (also referred to as “storage processing modules”) may neither have primary or secondary status. Storage array controllers 110C and 110D, implemented as storage processing modules, may act as a communication interface between the primary and secondary controllers (e.g., storage array controllers 110A and 110B, respectively) and storage array 102B. For example, storage array controller 110A of storage array 102A may send a write request, via SAN 158, to storage array 102B. The write request may be received by both storage array controllers 110C and 110D of storage array 102B. Storage array controllers 110C and 110D facilitate the communication, e.g., send the write request to the appropriate storage drive 171. It may be noted that in some implementations storage processing modules may be used to increase the number of storage drives controlled by the primary and secondary controllers.

In implementations, storage array controllers 110 are communicatively coupled, via a midplane (not shown), to one or more storage drives 171 and to one or more NVRAM devices (not shown) that are included as part of a storage array 102. The storage array controllers 110 may be coupled to the midplane via one or more data communication links and the midplane may be coupled to the storage drives 171 and the NVRAM devices via one or more data communications links. The data communications links described herein are collectively illustrated by data communications links 108 and may include a Peripheral Component Interconnect Express (PCIe) bus, for example.

FIG. 1B illustrates an example system for data storage, in accordance with some implementations. Storage array controller 101 illustrated in FIG. 1B may similar to the storage array controllers 110 described with respect to FIG. 1A. In one example, storage array controller 101 may be similar to storage array controller 110A or storage array controller 110B. Storage array controller 101 includes numerous elements for purposes of illustration rather than limitation. It may be noted that storage array controller 101 may include the same, more, or fewer elements configured in the same or different manner in other implementations. It may be noted that elements of FIG. 1A may be included below to help illustrate features of storage array controller 101.

Storage array controller 101 may include one or more processing devices 104 and random access memory (RAM) 111. Processing device 104 (or controller 101) represents one or more general-purpose processing devices such as a microprocessor, central processing unit, or the like. More particularly, the processing device 104 (or controller 101) may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 104 (or controller 101) may also be one or more special-purpose processing devices such as an application specific integrated circuit (ASIC), a field programmable gate array (FPGA), a digital signal processor (DSP), network processor, or the like.

The processing device 104 may be connected to the RAM 111 via a data communications link 106, which may be embodied as a high speed memory bus such as a Double-Data Rate 4 (DDR4) bus. Stored in RAM 111 is an operating system 112. In some implementations, instructions 113 are stored in RAM 111. Instructions 113 may include computer program instructions for performing operations in in a direct-mapped flash storage system. In one embodiment, a direct-mapped flash storage system is one that addresses data blocks within flash drives directly and without an address translation performed by the storage controllers of the flash drives.

In implementations, storage array controller 101 includes one or more host bus adapters 103 that are coupled to the processing device 104 via a data communications link 105. In implementations, host bus adapters 103 may be computer hardware that connects a host system (e.g., the storage array controller) to other network and storage arrays. In some examples, host bus adapters 103 may be a Fibre Channel adapter that enables the storage array controller 101 to connect to a SAN, an Ethernet adapter that enables the storage array controller 101 to connect to a LAN, or the like. Host bus adapters 103 may be coupled to the processing device 104 via a data communications link 105 such as, for example, a PCIe bus.

In implementations, storage array controller 101 may include a host bus adapter 114 that is coupled to an expander 115. The expander 115 may be used to attach a host system to a larger number of storage drives. The expander 115 may, for example, be a SAS expander utilized to enable the host bus adapter 114 to attach to storage drives in an implementation where the host bus adapter 114 is embodied as a SAS controller.

In implementations, storage array controller 101 may include a switch 116 coupled to the processing device 104 via a data communications link 109. The switch 116 may be a computer hardware device that can create multiple endpoints out of a single endpoint, thereby enabling multiple devices to share a single endpoint. The switch 116 may, for example, be a PCIe switch that is coupled to a PCIe bus (e.g., data communications link 109) and presents multiple PCIe connection points to the midplane.

In implementations, storage array controller 101 includes a data communications link 107 for coupling the storage array controller 101 to other storage array controllers. In some examples, data communications link 107 may be a QuickPath Interconnect (QPI) interconnect.

A traditional storage system that uses traditional flash drives may implement a process across the flash drives that are part of the traditional storage system. For example, a higher level process of the storage system may initiate and control a process across the flash drives. However, a flash drive of the traditional storage system may include its own storage controller that also performs the process. Thus, for the traditional storage system, a higher level process (e.g., initiated by the storage system) and a lower level process (e.g., initiated by a storage controller of the storage system) may both be performed.

To resolve various deficiencies of a traditional storage system, operations may be performed by higher level processes and not by the lower level processes. For example, the flash storage system may include flash drives that do not include storage controllers that provide the process. Thus, the operating system of the flash storage system itself may initiate and control the process. This may be accomplished by a direct-mapped flash storage system that addresses data blocks within the flash drives directly and without an address translation performed by the storage controllers of the flash drives.

The operating system of the flash storage system may identify and maintain a list of allocation units across multiple flash drives of the flash storage system. The allocation units may be entire erase blocks or multiple erase blocks. The operating system may maintain a map or address range that directly maps addresses to erase blocks of the flash drives of the flash storage system.

Direct mapping to the erase blocks of the flash drives may be used to rewrite data and erase data. For example, the operations may be performed on one or more allocation units that include a first data and a second data where the first data is to be retained and the second data is no longer being used by the flash storage system. The operating system may initiate the process to write the first data to new locations within other allocation units and erasing the second data and marking the allocation units as being available for use for subsequent data. Thus, the process may only be performed by the higher level operating system of the flash storage system without an additional lower level process being performed by controllers of the flash drives.

Advantages of the process being performed only by the operating system of the flash storage system include increased reliability of the flash drives of the flash storage system as unnecessary or redundant write operations are not being performed during the process. One possible point of novelty here is the concept of initiating and controlling the process at the operating system of the flash storage system. In addition, the process can be controlled by the operating system across multiple flash drives. This is contrast to the process being performed by a storage controller of a flash drive.

A storage system can consist of two storage array controllers that share a set of drives for failover purposes, or it could consist of a single storage array controller that provides a storage service that utilizes multiple drives, or it could consist of a distributed network of storage array controllers each with some number of drives or some amount of Flash storage where the storage array controllers in the network collaborate to provide a complete storage service and collaborate on various aspects of a storage service including storage allocation and garbage collection.

FIG. 1C illustrates a third example system 117 for data storage in accordance with some implementations. System 117 (also referred to as “storage system” herein) includes numerous elements for purposes of illustration rather than limitation. It may be noted that system 117 may include the same, more, or fewer elements configured in the same or different manner in other implementations.

In one embodiment, system 117 includes a dual Peripheral Component Interconnect (PCI) flash storage device 118 with separately addressable fast write storage. System 117 may include a storage controller 119. In one embodiment, storage controller 119 may be a CPU, ASIC, FPGA, or any other circuitry that may implement control structures necessary according to the present disclosure. In one embodiment, system 117 includes flash memory devices (e.g., including flash memory devices 120a-n), operatively coupled to various channels of the storage device controller 119. Flash memory devices 120a-n, may be presented to the controller 119 as an addressable collection of Flash pages, erase blocks, and/or control elements sufficient to allow the storage device controller 119 to program and retrieve various aspects of the Flash. In one embodiment, storage device controller 119 may perform operations on flash memory devices 120A-N including storing and retrieving data content of pages, arranging and erasing any blocks, tracking statistics related to the use and reuse of Flash memory pages, erase blocks, and cells, tracking and predicting error codes and faults within the Flash memory, controlling voltage levels associated with programming and retrieving contents of Flash cells, etc.

In one embodiment, system 117 may include random access memory (RAM) 121 to store separately addressable fast-write data. In one embodiment, RAM 121 may be one or more separate discrete devices. In another embodiment, RAM 121 may be integrated into storage device controller 119 or multiple storage device controllers. The RAM 121 may be utilized for other purposes as well, such as temporary program memory for a processing device (E.g., a central processing unit (CPU)) in the storage device controller 119.

In one embodiment, system 119 may include a stored energy device 122, such as a rechargeable battery or a capacitor. Stored energy device 122 may store energy sufficient to power the storage device controller 119, some amount of the RAM (e.g., RAM 121), and some amount of Flash memory (e.g., Flash memory 120a-120n) for sufficient time to write the contents of RAM to Flash memory. In one embodiment, storage device controller 119 may write the contents of RAM to Flash Memory if the storage device controller detects loss of external power.

In one embodiment, system 117 includes two data communications links 123a, 123b. In one embodiment, data communications links 123a, 123b may be PCI interfaces. In another embodiment, data communications links 123a, 123b may be based on other communications standards (e.g., HyperTransport, InfiBand, etc.). Data communications links 123a, 123b may be based on non-volatile memory express (NVMe) or NCMe over fabrics (NVMf) specifications that allow external connection to the storage device controller 119 from other components in the storage system 117. It should be noted that data communications links may be interchangeably referred to herein as PCI buses for convenience.

System 117 may also include an external power source (not shown), which may be provided over one or both data communications links 123a, 123b, or which may be provided separately. An alternative embodiment includes a separate Flash memory (not shown) dedicated for use in storing the content of RAM 121. The storage device controller 119 may present a logical device over a PCI bus which may include an addressable fast-write logical device, or a distinct part of the logical address space of the storage device 118, which may be presented as PCI memory or as persistent storage. In one embodiment, operations to store into the device are directed into the RAM 121. On power failure, the storage device controller 119 may write stored content associated with the addressable fast-write logical storage to Flash memory (e.g., Flash memory 120a-n) for long-term persistent storage.

In one embodiment, the logical device may include some presentation of some or all of the content of the Flash memory devices 120a-n, where that presentation allows a storage system including a storage device 118 (e.g., storage system 117) to directly address Flash memory pages and directly reprogram erase blocks from storage system components that are external to the storage device through the PCI bus. The presentation may also allow one or more of the external components to control and retrieve other aspects of the Flash memory including some or all of: tracking statistics related to use and reuse of Flash memory pages, erase blocks, and cells across all the Flash memory devices; tracking and predicting error codes and faults within and across the Flash memory devices; controlling voltage levels associated with programming and retrieving contents of Flash cells; etc.

In one embodiment, the stored energy device 122 may be sufficient to ensure completion of in-progress operations to the Flash memory devices 107a-120n stored energy device 122 may power storage device controller 119 and associated Flash memory devices (e.g., 120a-n) for those operations, as well as for the storing of fast-write RAM to Flash memory. Stored energy device 122 may be used to store accumulated statistics and other parameters kept and tracked by the Flash memory devices 120a-n and/or the storage device controller 119. Separate capacitors or stored energy devices (such as smaller capacitors near or embedded within the Flash memory devices themselves) may be used for some or all of the operations described herein.

Various schemes may be used to track and optimize the life span of the stored energy component, such as adjusting voltage levels over time, partially discharging the storage energy device 122 to measure corresponding discharge characteristics, etc. If the available energy decreases over time, the effective available capacity of the addressable fast-write storage may be decreased to ensure that it can be written safely based on the currently available stored energy.

FIG. 1D illustrates a third example system 124 for data storage in accordance with some implementations. In one embodiment, system 124 includes storage controllers 125a, 125b. In one embodiment, storage controllers 125a, 125b are operatively coupled to Dual PCI storage devices 119a, 119b and 119c, 119d, respectively. Storage controllers 125a, 125b may be operatively coupled (e.g., via a storage network 130) to some number of host computers 127a-n.

In one embodiment, two storage controllers (e.g., 125a and 125b) provide storage services, such as a small computer system interface (SCSI) block storage array, a file server, an object server, a database or data analytics service, etc. The storage controllers 125a, 125b may provide services through some number of network interfaces (e.g., 126a-d) to host computers 127a-n outside of the storage system 124. Storage controllers 125a, 125b may provide integrated services or an application entirely within the storage system 124, forming a converged storage and compute system. The storage controllers 125a, 125b may utilize the fast write memory within or across storage devices119a-d to journal in progress operations to ensure the operations are not lost on a power failure, storage controller removal, storage controller or storage system shutdown, or some fault of one or more software or hardware components within the storage system 124.

In one embodiment, controllers 125a, 125b operate as PCI masters to one or the other PCI buses 128a, 128b. In another embodiment, 128a and 128b may be based on other communications standards (e.g., HyperTransport, InfiBand, etc.). Other storage system embodiments may operate storage controllers 125a, 125b as multi-masters for both PCI buses 128a, 128b. Alternately, a PCI/NVMe/NVMf switching infrastructure or fabric may connect multiple storage controllers. Some storage system embodiments may allow storage devices to communicate with each other directly rather than communicating only with storage controllers. In one embodiment, a storage device controller 119a may be operable under direction from a storage controller 125a to synthesize and transfer data to be stored into Flash memory devices from data that has been stored in RAM (e.g., RAM 121 of FIG. 1C). For example, a recalculated version of RAM content may be transferred after a storage controller has determined that an operation has fully committed across the storage system, or when fast-write memory on the device has reached a certain used capacity, or after a certain amount of time, to ensure improve safety of the data or to release addressable fast-write capacity for reuse. This mechanism may be used, for example, to avoid a second transfer over a bus (e.g., 128a, 128b) from the storage controllers 125a, 125b. In one embodiment, a recalculation may include compressing data, attaching indexing or other metadata, combining multiple data segments together, performing erasure code calculations, etc.

In one embodiment, under direction from a storage controller 125a, 125b, a storage device controller 119a, 119b may be operable to calculate and transfer data to other storage devices from data stored in RAM (e.g., RAM 121 of FIG. 1C) without involvement of the storage controllers 125a, 125b. This operation may be used to mirror data stored in one controller 125a to another controller 125b, or it could be used to offload compression, data aggregation, and/or erasure coding calculations and transfers to storage devices to reduce load on storage controllers or the storage controller interface 129a, 129b to the PCI bus 128a, 128b.

A storage device controller 119 may include mechanisms for implementing high availability primitives for use by other parts of a storage system external to the Dual PCI storage device 118. For example, reservation or exclusion primitives may be provided so that, in a storage system with two storage controllers providing a highly available storage service, one storage controller may prevent the other storage controller from accessing or continuing to access the storage device. This could be used, for example, in cases where one controller detects that the other controller is not functioning properly or where the interconnect between the two storage controllers may itself not be functioning properly.

In one embodiment, a storage system for use with Dual PCI direct mapped storage devices with separately addressable fast write storage includes systems that manage erase blocks or groups of erase blocks as allocation units for storing data on behalf of the storage service, or for storing metadata (e.g., indexes, logs, etc.) associated with the storage service, or for proper management of the storage system itself. Flash pages, which may be a few kilobytes in size, may be written as data arrives or as the storage system is to persist data for long intervals of time (e.g., above a defined threshold of time). To commit data more quickly, or to reduce the number of writes to the Flash memory devices, the storage controllers may first write data into the separately addressable fast write storage on one more storage devices.

In one embodiment, the storage controllers 125a, 125b may initiate the use of erase blocks within and across storage devices (e.g., 118) in accordance with an age and expected remaining lifespan of the storage devices, or based on other statistics. The storage controllers 125a, 125b may initiate garbage collection and data migration data between storage devices in accordance with pages that are no longer needed as well as to manage Flash page and erase block lifespans and to manage overall system performance.

In one embodiment, the storage system 124 may utilize mirroring and/or erasure coding schemes as part of storing data into addressable fast write storage and/or as part of writing data into allocation units associated with erase blocks. Erasure codes may be used across storage devices, as well as within erase blocks or allocation units, or within and across Flash memory devices on a single storage device, to provide redundancy against single or multiple storage device failures or to protect against internal corruptions of Flash memory pages resulting from Flash memory operations or from degradation of Flash memory cells. Mirroring and erasure coding at various levels may be used to recover from multiple types of failures that occur separately or in combination.

The embodiments depicted with reference to FIGS. 2A-G illustrate a storage cluster that stores user data, such as user data originating from one or more user or client systems or other sources external to the storage cluster. The storage cluster distributes user data across storage nodes housed within a chassis, or across multiple chassis, using erasure coding and redundant copies of metadata. Erasure coding refers to a method of data protection or reconstruction in which data is stored across a set of different locations, such as disks, storage nodes or geographic locations. Flash memory is one type of solid-state memory that may be integrated with the embodiments, although the embodiments may be extended to other types of solid-state memory or other storage medium, including non- solid state memory. Control of storage locations and workloads are distributed across the storage locations in a clustered peer-to-peer system. Tasks such as mediating communications between the various storage nodes, detecting when a storage node has become unavailable, and balancing I/Os (inputs and outputs) across the various storage nodes, are all handled on a distributed basis. Data is laid out or distributed across multiple storage nodes in data fragments or stripes that support data recovery in some embodiments. Ownership of data can be reassigned within a cluster, independent of input and output patterns. This architecture described in more detail below allows a storage node in the cluster to fail, with the system remaining operational, since the data can be reconstructed from other storage nodes and thus remain available for input and output operations. In various embodiments, a storage node may be referred to as a cluster node, a blade, or a server.

The storage cluster may be contained within a chassis, i.e., an enclosure housing one or more storage nodes. A mechanism to provide power to each storage node, such as a power distribution bus, and a communication mechanism, such as a communication bus that enables communication between the storage nodes are included within the chassis. The storage cluster can run as an independent system in one location according to some embodiments. In one embodiment, a chassis contains at least two instances of both the power distribution and the communication bus which may be enabled or disabled independently. The internal communication bus may be an Ethernet bus, however, other technologies such as Peripheral Component Interconnect (PCI) Express, InfiniBand, and others, are equally suitable. The chassis provides a port for an external communication bus for enabling communication between multiple chassis, directly or through a switch, and with client systems. The external communication may use a technology such as Ethernet, InfiniBand, Fibre Channel, etc. In some embodiments, the external communication bus uses different communication bus technologies for inter-chassis and client communication. If a switch is deployed within or between chassis, the switch may act as a translation between multiple protocols or technologies. When multiple chassis are connected to define a storage cluster, the storage cluster may be accessed by a client using either proprietary interfaces or standard interfaces such as network file system (NFS), common internet file system (CIFS), small computer system interface (SCSI) or hypertext transfer protocol (HTTP). Translation from the client protocol may occur at the switch, chassis external communication bus or within each storage node. In some embodiments, multiple chassis may be coupled or connected to each other through an aggregator switch. A portion and/or all of the coupled or connected chassis may be designated as a storage cluster. As discussed above, each chassis can have multiple blades, each blade has a MAC (media access control) address, but the storage cluster is presented to an external network as having a single cluster IP (Internet Protocol) address and a single MAC address in some embodiments.

Each storage node may be one or more storage servers and each storage server is connected to one or more non-volatile solid state memory units, which may be referred to as storage units or storage devices. One embodiment includes a single storage server in each storage node and between one to eight non-volatile solid state memory units, however this one example is not meant to be limiting. The storage server may include a processor, dynamic random access memory (DRAM) and interfaces for the internal communication bus and power distribution for each of the power buses. Inside the storage node, the interfaces and storage unit share a communication bus, e.g., PCI Express, in some embodiments. The non-volatile solid state memory units may directly access the internal communication bus interface through a storage node communication bus, or request the storage node to access the bus interface. The non-volatile solid state memory unit contains an embedded central processing unit (CPU), solid state storage controller, and a quantity of solid state mass storage, e.g., between 2-32 terabytes (TB) in some embodiments. An embedded volatile storage medium, such as DRAM, and an energy reserve apparatus are included in the non-volatile solid state memory unit. In some embodiments, the energy reserve apparatus is a capacitor, super-capacitor, or battery that enables transferring a subset of DRAM contents to a stable storage medium in the case of power loss. In some embodiments, the non-volatile solid state memory unit is constructed with a storage class memory, such as phase change or magnetoresistive random access memory (MRAM) that substitutes for DRAM and enables a reduced power hold-up apparatus.

One of many features of the storage nodes and non-volatile solid state storage is the ability to proactively rebuild data in a storage cluster. The storage nodes and non-volatile solid state storage can determine when a storage node or non-volatile solid state storage in the storage cluster is unreachable, independent of whether there is an attempt to read data involving that storage node or non-volatile solid state storage. The storage nodes and non-volatile solid state storage then cooperate to recover and rebuild the data in at least partially new locations. This constitutes a proactive rebuild, in that the system rebuilds data without waiting until the data is needed for a read access initiated from a client system employing the storage cluster. These and further details of the storage memory and operation thereof are discussed below.

FIG. 2A is a perspective view of a storage cluster 161, with multiple storage nodes 150 and internal solid-state memory coupled to each storage node to provide network attached storage or storage area network, in accordance with some embodiments. A network attached storage, storage area network, or a storage cluster, or other storage memory, could include one or more storage clusters 161, each having one or more storage nodes 150, in a flexible and reconfigurable arrangement of both the physical components and the amount of storage memory provided thereby. The storage cluster 161 is designed to fit in a rack, and one or more racks can be set up and populated as desired for the storage memory. The storage cluster 161 has a chassis 138 having multiple slots 142. It should be appreciated that chassis 138 may be referred to as a housing, enclosure, or rack unit. In one embodiment, the chassis 138 has fourteen slots 142, although other numbers of slots are readily devised. For example, some embodiments have four slots, eight slots, sixteen slots, thirty-two slots, or other suitable number of slots. Each slot 142 can accommodate one storage node 150 in some embodiments. Chassis 138 includes flaps 148 that can be utilized to mount the chassis 138 on a rack. Fans 144 provide air circulation for cooling of the storage nodes 150 and components thereof, although other cooling components could be used, or an embodiment could be devised without cooling components. A switch fabric 146 couples storage nodes 150 within chassis 138 together and to a network for communication to the memory. In an embodiment depicted in FIG. 1, the slots 142 to the left of the switch fabric 146 and fans 144 are shown occupied by storage nodes 150, while the slots 142 to the right of the switch fabric 146 and fans 144 are empty and available for insertion of storage node 150 for illustrative purposes. This configuration is one example, and one or more storage nodes 150 could occupy the slots 142 in various further arrangements. The storage node arrangements need not be sequential or adjacent in some embodiments. Storage nodes 150 are hot pluggable, meaning that a storage node 150 can be inserted into a slot 142 in the chassis 138, or removed from a slot 142, without stopping or powering down the system. Upon insertion or removal of storage node 150 from slot 142, the system automatically reconfigures in order to recognize and adapt to the change. Reconfiguration, in some embodiments, includes restoring redundancy and/or rebalancing data or load.

Each storage node 150 can have multiple components. In the embodiment shown here, the storage node 150 includes a printed circuit board 159 populated by a CPU 156, i.e., processor, a memory 154 coupled to the CPU 156, and a non-volatile solid state storage 152 coupled to the CPU 156, although other mountings and/or components could be used in further embodiments. The memory 154 has instructions which are executed by the CPU 156 and/or data operated on by the CPU 156. As further explained below, the non-volatile solid state storage 152 includes flash or, in further embodiments, other types of solid-state memory.

Referring to FIG. 2A, storage cluster 161 is scalable, meaning that storage capacity with non-uniform storage sizes is readily added, as described above. One or more storage nodes 150 can be plugged into or removed from each chassis and the storage cluster self-configures in some embodiments. Plug-in storage nodes 150, whether installed in a chassis as delivered or later added, can have different sizes. For example, in one embodiment a storage node 150 can have any multiple of 4 TB, e.g., 8 TB, 12 TB, 16 TB, 32 TB, etc. In further embodiments, a storage node 150 could have any multiple of other storage amounts or capacities. Storage capacity of each storage node 150 is broadcast, and influences decisions of how to stripe the data. For maximum storage efficiency, an embodiment can self-configure as wide as possible in the stripe, subject to a predetermined requirement of continued operation with loss of up to one, or up to two, non-volatile solid state storage units 152 or storage nodes 150 within the chassis.

FIG. 2B is a block diagram showing a communications interconnect 171 and power distribution bus 172 coupling multiple storage nodes 150. Referring back to FIG. 2A, the communications interconnect 171 can be included in or implemented with the switch fabric 146 in some embodiments. Where multiple storage clusters 161 occupy a rack, the communications interconnect 171 can be included in or implemented with a top of rack switch, in some embodiments. As illustrated in FIG. 2B, storage cluster 161 is enclosed within a single chassis 138. External port 176 is coupled to storage nodes 150 through communications interconnect 171, while external port 174 is coupled directly to a storage node. External power port 178 is coupled to power distribution bus 172. Storage nodes 150 may include varying amounts and differing capacities of non-volatile solid state storage 152 as described with reference to FIG. 2A. In addition, one or more storage nodes 150 may be a compute only storage node as illustrated in FIG. 2B. Authorities 168 are implemented on the non-volatile solid state storages 152, for example as lists or other data structures stored in memory. In some embodiments the authorities are stored within the non-volatile solid state storage 152 and supported by software executing on a controller or other processor of the non-volatile solid state storage 152. In a further embodiment, authorities 168 are implemented on the storage nodes 150, for example as lists or other data structures stored in the memory 154 and supported by software executing on the CPU 156 of the storage node 150. Authorities 168 control how and where data is stored in the non-volatile solid state storages 152 in some embodiments. This control assists in determining which type of erasure coding scheme is applied to the data, and which storage nodes 150 have which portions of the data. Each authority 168 may be assigned to a non-volatile solid state storage 152. Each authority may control a range of inode numbers, segment numbers, or other data identifiers which are assigned to data by a file system, by the storage nodes 150, or by the non-volatile solid state storage 152, in various embodiments.

Every piece of data, and every piece of metadata, has redundancy in the system in some embodiments. In addition, every piece of data and every piece of metadata has an owner, which may be referred to as an authority. If that authority is unreachable, for example through failure of a storage node, there is a plan of succession for how to find that data or that metadata. In various embodiments, there are redundant copies of authorities 168. Authorities 168 have a relationship to storage nodes 150 and non-volatile solid state storage 152 in some embodiments. Each authority 168, covering a range of data segment numbers or other identifiers of the data, may be assigned to a specific non-volatile solid state storage 152. In some embodiments the authorities 168 for all of such ranges are distributed over the non-volatile solid state storages 152 of a storage cluster. Each storage node 150 has a network port that provides access to the non-volatile solid state storage(s) 152 of that storage node 150. Data can be stored in a segment, which is associated with a segment number and that segment number is an indirection for a configuration of a RAID (redundant array of independent disks) stripe in some embodiments. The assignment and use of the authorities 168 thus establishes an indirection to data. Indirection may be referred to as the ability to reference data indirectly, in this case via an authority 168, in accordance with some embodiments. A segment identifies a set of non-volatile solid state storage 152 and a local identifier into the set of non-volatile solid state storage 152 that may contain data. In some embodiments, the local identifier is an offset into the device and may be reused sequentially by multiple segments. In other embodiments the local identifier is unique for a specific segment and never reused. The offsets in the non-volatile solid state storage 152 are applied to locating data for writing to or reading from the non-volatile solid state storage 152 (in the form of a RAID stripe). Data is striped across multiple units of non-volatile solid state storage 152, which may include or be different from the non-volatile solid state storage 152 having the authority 168 for a particular data segment.

If there is a change in where a particular segment of data is located, e.g., during a data move or a data reconstruction, the authority 168 for that data segment should be consulted, at that non-volatile solid state storage 152 or storage node 150 having that authority 168. In order to locate a particular piece of data, embodiments calculate a hash value for a data segment or apply an inode number or a data segment number. The output of this operation points to a non-volatile solid state storage 152 having the authority 168 for that particular piece of data. In some embodiments there are two stages to this operation. The first stage maps an entity identifier (ID), e.g., a segment number, inode number, or directory number to an authority identifier. This mapping may include a calculation such as a hash or a bit mask. The second stage is mapping the authority identifier to a particular non-volatile solid state storage 152, which may be done through an explicit mapping. The operation is repeatable, so that when the calculation is performed, the result of the calculation repeatably and reliably points to a particular non-volatile solid state storage 152 having that authority 168. The operation may include the set of reachable storage nodes as input. If the set of reachable non-volatile solid state storage units changes the optimal set changes. In some embodiments, the persisted value is the current assignment (which is always true) and the calculated value is the target assignment the cluster will attempt to reconfigure towards. This calculation may be used to determine the optimal non-volatile solid state storage 152 for an authority in the presence of a set of non-volatile solid state storage 152 that are reachable and constitute the same cluster. The calculation also determines an ordered set of peer non-volatile solid state storage 152 that will also record the authority to non-volatile solid state storage mapping so that the authority may be determined even if the assigned non-volatile solid state storage is unreachable. A duplicate or substitute authority 168 may be consulted if a specific authority 168 is unavailable in some embodiments.

With reference to FIGS. 2A and 2B, two of the many tasks of the CPU 156 on a storage node 150 are to break up write data, and reassemble read data. When the system has determined that data is to be written, the authority 168 for that data is located as above. When the segment ID for data is already determined the request to write is forwarded to the non-volatile solid state storage 152 currently determined to be the host of the authority 168 determined from the segment. The host CPU 156 of the storage node 150, on which the non-volatile solid state storage 152 and corresponding authority 168 reside, then breaks up or shards the data and transmits the data out to various non-volatile solid state storage 152. The transmitted data is written as a data stripe in accordance with an erasure coding scheme. In some embodiments, data is requested to be pulled, and in other embodiments, data is pushed. In reverse, when data is read, the authority 168 for the segment ID containing the data is located as described above. The host CPU 156 of the storage node 150 on which the non-volatile solid state storage 152 and corresponding authority 168 reside requests the data from the non-volatile solid state storage and corresponding storage nodes pointed to by the authority. In some embodiments the data is read from flash storage as a data stripe. The host CPU 156 of storage node 150 then reassembles the read data, correcting any errors (if present) according to the appropriate erasure coding scheme, and forwards the reassembled data to the network. In further embodiments, some or all of these tasks can be handled in the non-volatile solid state storage 152. In some embodiments, the segment host requests the data be sent to storage node 150 by requesting pages from storage and then sending the data to the storage node making the original request.

In some systems, for example in UNIX-style file systems, data is handled with an index node or inode, which specifies a data structure that represents an object in a file system. The object could be a file or a directory, for example. Metadata may accompany the object, as attributes such as permission data and a creation timestamp, among other attributes. A segment number could be assigned to all or a portion of such an object in a file system. In other systems, data segments are handled with a segment number assigned elsewhere. For purposes of discussion, the unit of distribution is an entity, and an entity can be a file, a directory or a segment. That is, entities are units of data or metadata stored by a storage system. Entities are grouped into sets called authorities. Each authority has an authority owner, which is a storage node that has the exclusive right to update the entities in the authority. In other words, a storage node contains the authority, and that the authority, in turn, contains entities.

A segment is a logical container of data in accordance with some embodiments. A segment is an address space between medium address space and physical flash locations, i.e., the data segment number, are in this address space. Segments may also contain meta-data, which enable data redundancy to be restored (rewritten to different flash locations or devices) without the involvement of higher level software. In one embodiment, an internal format of a segment contains client data and medium mappings to determine the position of that data. Each data segment is protected, e.g., from memory and other failures, by breaking the segment into a number of data and parity shards, where applicable. The data and parity shards are distributed, i.e., striped, across non-volatile solid state storage 152 coupled to the host CPUs 156 (See FIGS. 2E and 2G) in accordance with an erasure coding scheme. Usage of the term segments refers to the container and its place in the address space of segments in some embodiments. Usage of the term stripe refers to the same set of shards as a segment and includes how the shards are distributed along with redundancy or parity information in accordance with some embodiments.

A series of address-space transformations takes place across an entire storage system. At the top are the directory entries (file names) which link to an inode. Inodes point into medium address space, where data is logically stored. Medium addresses may be mapped through a series of indirect mediums to spread the load of large files, or implement data services like deduplication or snapshots. Medium addresses may be mapped through a series of indirect mediums to spread the load of large files, or implement data services like deduplication or snapshots. Segment addresses are then translated into physical flash locations. Physical flash locations have an address range bounded by the amount of flash in the system in accordance with some embodiments. Medium addresses and segment addresses are logical containers, and in some embodiments use a 128 bit or larger identifier so as to be practically infinite, with a likelihood of reuse calculated as longer than the expected life of the system. Addresses from logical containers are allocated in a hierarchical fashion in some embodiments. Initially, each non-volatile solid state storage unit 152 may be assigned a range of address space. Within this assigned range, the non-volatile solid state storage 152 is able to allocate addresses without synchronization with other non-volatile solid state storage 152.

Data and metadata is stored by a set of underlying storage layouts that are optimized for varying workload patterns and storage devices. These layouts incorporate multiple redundancy schemes, compression formats and index algorithms. Some of these layouts store information about authorities and authority masters, while others store file metadata and file data. The redundancy schemes include error correction codes that tolerate corrupted bits within a single storage device (such as a NAND flash chip), erasure codes that tolerate the failure of multiple storage nodes, and replication schemes that tolerate data center or regional failures. In some embodiments, low density parity check (LDPC) code is used within a single storage unit. Reed-Solomon encoding is used within a storage cluster, and mirroring is used within a storage grid in some embodiments. Metadata may be stored using an ordered log structured index (such as a Log Structured Merge Tree), and large data may not be stored in a log structured layout.

In order to maintain consistency across multiple copies of an entity, the storage nodes agree implicitly on two things through calculations: (1) the authority that contains the entity, and (2) the storage node that contains the authority. The assignment of entities to authorities can be done by pseudo randomly assigning entities to authorities, by splitting entities into ranges based upon an externally produced key, or by placing a single entity into each authority. Examples of pseudorandom schemes are linear hashing and the Replication Under Scalable Hashing (RUSH) family of hashes, including Controlled Replication Under Scalable Hashing (CRUSH). In some embodiments, pseudo-random assignment is utilized only for assigning authorities to nodes because the set of nodes can change. The set of authorities cannot change so any subjective function may be applied in these embodiments. Some placement schemes automatically place authorities on storage nodes, while other placement schemes rely on an explicit mapping of authorities to storage nodes. In some embodiments, a pseudorandom scheme is utilized to map from each authority to a set of candidate authority owners. A pseudorandom data distribution function related to CRUSH may assign authorities to storage nodes and create a list of where the authorities are assigned. Each storage node has a copy of the pseudorandom data distribution function, and can arrive at the same calculation for distributing, and later finding or locating an authority. Each of the pseudorandom schemes requires the reachable set of storage nodes as input in some embodiments in order to conclude the same target nodes. Once an entity has been placed in an authority, the entity may be stored on physical devices so that no expected failure will lead to unexpected data loss. In some embodiments, rebalancing algorithms attempt to store the copies of all entities within an authority in the same layout and on the same set of machines.

Examples of expected failures include device failures, stolen machines, datacenter fires, and regional disasters, such as nuclear or geological events. Different failures lead to different levels of acceptable data loss. In some embodiments, a stolen storage node impacts neither the security nor the reliability of the system, while depending on system configuration, a regional event could lead to no loss of data, a few seconds or minutes of lost updates, or even complete data loss.

In the embodiments, the placement of data for storage redundancy is independent of the placement of authorities for data consistency. In some embodiments, storage nodes that contain authorities do not contain any persistent storage. Instead, the storage nodes are connected to non-volatile solid state storage units that do not contain authorities. The communications interconnect between storage nodes and non-volatile solid state storage units consists of multiple communication technologies and has non-uniform performance and fault tolerance characteristics. In some embodiments, as mentioned above, non-volatile solid state storage units are connected to storage nodes via PCI express, storage nodes are connected together within a single chassis using Ethernet backplane, and chassis are connected together to form a storage cluster. Storage clusters are connected to clients using Ethernet or fiber channel in some embodiments. If multiple storage clusters are configured into a storage grid, the multiple storage clusters are connected using the Internet or other long-distance networking links, such as a “metro scale” link or private link that does not traverse the internet.

Authority owners have the exclusive right to modify entities, to migrate entities from one non-volatile solid state storage unit to another non-volatile solid state storage unit, and to add and remove copies of entities. This allows for maintaining the redundancy of the underlying data. When an authority owner fails, is going to be decommissioned, or is overloaded, the authority is transferred to a new storage node. Transient failures make it non-trivial to ensure that all non-faulty machines agree upon the new authority location. The ambiguity that arises due to transient failures can be achieved automatically by a consensus protocol such as Paxos, hot-warm failover schemes, via manual intervention by a remote system administrator, or by a local hardware administrator (such as by physically removing the failed machine from the cluster, or pressing a button on the failed machine). In some embodiments, a consensus protocol is used, and failover is automatic. If too many failures or replication events occur in too short a time period, the system goes into a self-preservation mode and halts replication and data movement activities until an administrator intervenes in accordance with some embodiments.

As authorities are transferred between storage nodes and authority owners update entities in their authorities, the system transfers messages between the storage nodes and non-volatile solid state storage units. With regard to persistent messages, messages that have different purposes are of different types. Depending on the type of the message, the system maintains different ordering and durability guarantees. As the persistent messages are being processed, the messages are temporarily stored in multiple durable and non-durable storage hardware technologies. In some embodiments, messages are stored in RAM, NVRAM and on NAND flash devices, and a variety of protocols are used in order to make efficient use of each storage medium. Latency-sensitive client requests may be persisted in replicated NVRAM, and then later NAND, while background rebalancing operations are persisted directly to NAND.

Persistent messages are persistently stored prior to being transmitted. This allows the system to continue to serve client requests despite failures and component replacement. Although many hardware components contain unique identifiers that are visible to system administrators, manufacturer, hardware supply chain and ongoing monitoring quality control infrastructure, applications running on top of the infrastructure address virtualize addresses. These virtualized addresses do not change over the lifetime of the storage system, regardless of component failures and replacements. This allows each component of the storage system to be replaced over time without reconfiguration or disruptions of client request processing, i.e., the system supports non-disruptive upgrades.

In some embodiments, the virtualized addresses are stored with sufficient redundancy. A continuous monitoring system correlates hardware and software status and the hardware identifiers. This allows detection and prediction of failures due to faulty components and manufacturing details. The monitoring system also enables the proactive transfer of authorities and entities away from impacted devices before failure occurs by removing the component from the critical path in some embodiments.

FIG. 2C is a multiple level block diagram, showing contents of a storage node 150 and contents of a non-volatile solid state storage 152 of the storage node 150. Data is communicated to and from the storage node 150 by a network interface controller (NIC) 202 in some embodiments. Each storage node 150 has a CPU 156, and one or more non-volatile solid state storage 152, as discussed above. Moving down one level in FIG. 2C, each non-volatile solid state storage 152 has a relatively fast non-volatile solid state memory, such as nonvolatile random access memory (NVRAM) 204, and flash memory 206. In some embodiments, NVRAM 204 may be a component that does not require program/erase cycles (DRAM, MRAM, PCM), and can be a memory that can support being written vastly more often than the memory is read from. Moving down another level in FIG. 2C, the NVRAM 204 is implemented in one embodiment as high speed volatile memory, such as dynamic random access memory (DRAM) 216, backed up by energy reserve 218. Energy reserve 218 provides sufficient electrical power to keep the DRAM 216 powered long enough for contents to be transferred to the flash memory 206 in the event of power failure. In some embodiments, energy reserve 218 is a capacitor, super-capacitor, battery, or other device, that supplies a suitable supply of energy sufficient to enable the transfer of the contents of DRAM 216 to a stable storage medium in the case of power loss. The flash memory 206 is implemented as multiple flash dies 222, which may be referred to as packages of flash dies 222 or an array of flash dies 222. It should be appreciated that the flash dies 222 could be packaged in any number of ways, with a single die per package, multiple dies per package (i.e. multichip packages), in hybrid packages, as bare dies on a printed circuit board or other substrate, as encapsulated dies, etc. In the embodiment shown, the non-volatile solid state storage 152 has a controller 212 or other processor, and an input output (I/O) port 210 coupled to the controller 212. I/O port 210 is coupled to the CPU 156 and/or the network interface controller 202 of the flash storage node 150. Flash input output (I/O) port 220 is coupled to the flash dies 222, and a direct memory access unit (DMA) 214 is coupled to the controller 212, the DRAM 216 and the flash dies 222. In the embodiment shown, the I/O port 210, controller 212, DMA unit 214 and flash I/O port 220 are implemented on a programmable logic device (PLD) 208, e.g., a field programmable gate array (FPGA). In this embodiment, each flash die 222 has pages, organized as sixteen kB (kilobyte) pages 224, and a register 226 through which data can be written to or read from the flash die 222. In further embodiments, other types of solid-state memory are used in place of, or in addition to flash memory illustrated within flash die 222.

Storage clusters 161, in various embodiments as disclosed herein, can be contrasted with storage arrays in general. The storage nodes 150 are part of a collection that creates the storage cluster 161. Each storage node 150 owns a slice of data and computing required to provide the data. Multiple storage nodes 150 cooperate to store and retrieve the data. Storage memory or storage devices, as used in storage arrays in general, are less involved with processing and manipulating the data. Storage memory or storage devices in a storage array receive commands to read, write, or erase data. The storage memory or storage devices in a storage array are not aware of a larger system in which they are embedded, or what the data means. Storage memory or storage devices in storage arrays can include various types of storage memory, such as RAM, solid state drives, hard disk drives, etc. The storage units 152 described herein have multiple interfaces active simultaneously and serving multiple purposes. In some embodiments, some of the functionality of a storage node 150 is shifted into a storage unit 152, transforming the storage unit 152 into a combination of storage unit 152 and storage node 150. Placing computing (relative to storage data) into the storage unit 152 places this computing closer to the data itself. The various system embodiments have a hierarchy of storage node layers with different capabilities. By contrast, in a storage array, a controller owns and knows everything about all of the data that the controller manages in a shelf or storage devices. In a storage cluster 161, as described herein, multiple controllers in multiple storage units 152 and/or storage nodes 150 cooperate in various ways (e.g., for erasure coding, data sharding, metadata communication and redundancy, storage capacity expansion or contraction, data recovery, and so on).

FIG. 2D shows a storage server environment, which uses embodiments of the storage nodes 150 and storage units 152 of FIGS. 2A-C. In this version, each storage unit 152 has a processor such as controller 212 (see FIG. 2C), an FPGA (field programmable gate array), flash memory 206, and NVRAM 204 (which is super-capacitor backed DRAM 216, see FIGS. 2B and 2C) on a PCIe (peripheral component interconnect express) board in a chassis 138 (see FIG. 2A). The storage unit 152 may be implemented as a single board containing storage, and may be the largest tolerable failure domain inside the chassis. In some embodiments, up to two storage units 152 may fail and the device will continue with no data loss.

The physical storage is divided into named regions based on application usage in some embodiments. The NVRAM 204 is a contiguous block of reserved memory in the storage unit 152 DRAM 216, and is backed by NAND flash. NVRAM 204 is logically divided into multiple memory regions written for two as spool (e.g., spool_region). Space within the NVRAM 204 spools is managed by each authority 168 independently. Each device provides an amount of storage space to each authority 168. That authority 168 further manages lifetimes and allocations within that space. Examples of a spool include distributed transactions or notions. When the primary power to a storage unit 152 fails, onboard super-capacitors provide a short duration of power hold up. During this holdup interval, the contents of the NVRAM 204 are flushed to flash memory 206. On the next power-on, the contents of the NVRAM 204 are recovered from the flash memory 206.

As for the storage unit controller, the responsibility of the logical “controller” is distributed across each of the blades containing authorities 168. This distribution of logical control is shown in FIG. 2D as a host controller 242, mid-tier controller 244 and storage unit controller(s) 246. Management of the control plane and the storage plane are treated independently, although parts may be physically co-located on the same blade. Each authority 168 effectively serves as an independent controller. Each authority 168 provides its own data and metadata structures, its own background workers, and maintains its own lifecycle.

FIG. 2E is a blade 252 hardware block diagram, showing a control plane 254, compute and storage planes 256, 258, and authorities 168 interacting with underlying physical resources, using embodiments of the storage nodes 150 and storage units 152 of FIGS. 2A-C in the storage server environment of FIG. 2D. The control plane 254 is partitioned into a number of authorities 168 which can use the compute resources in the compute plane 256 to run on any of the blades 252. The storage plane 258 is partitioned into a set of devices, each of which provides access to flash 206 and NVRAM 204 resources.

In the compute and storage planes 256, 258 of FIG. 2E, the authorities 168 interact with the underlying physical resources (i.e., devices). From the point of view of an authority 168, its resources are striped over all of the physical devices. From the point of view of a device, it provides resources to all authorities 168, irrespective of where the authorities happen to run. Each authority 168 has allocated or has been allocated one or more partitions 260 of storage memory in the storage units 152, e.g. partitions 260 in flash memory 206 and NVRAM 204. Each authority 168 uses those allocated partitions 260 that belong to it, for writing or reading user data. Authorities can be associated with differing amounts of physical storage of the system. For example, one authority 168 could have a larger number of partitions 260 or larger sized partitions 260 in one or more storage units 152 than one or more other authorities 168.

FIG. 2F depicts elasticity software layers in blades 252 of a storage cluster 161, in accordance with some embodiments. In the elasticity structure, elasticity software is symmetric, i.e., each blade’s compute module 270 runs the three identical layers of processes depicted in FIG. 2F. Storage managers 274 execute read and write requests from other blades 252 for data and metadata stored in local storage unit 152 NVRAM 204 and flash 206. Authorities 168 fulfill client requests by issuing the necessary reads and writes to the blades 252 on whose storage units 152 the corresponding data or metadata resides. Endpoints 272 parse client connection requests received from switch fabric 146 supervisory software, relay the client connection requests to the authorities 168 responsible for fulfillment, and relay the authorities’ 168 responses to clients. The symmetric three-layer structure enables the storage system’s high degree of concurrency. Elasticity scales out efficiently and reliably in these embodiments. In addition, elasticity implements a unique scale-out technique that balances work evenly across all resources regardless of client access pattern, and maximizes concurrency by eliminating much of the need for inter-blade coordination that typically occurs with conventional distributed locking.

Still referring to FIG. 2F, authorities 168 running in the compute modules 270 of a blade 252 perform the internal operations required to fulfill client requests. One feature of elasticity is that authorities 168 are stateless, i.e., they cache active data and metadata in their own blades’ 168 DRAMs for fast access, but the authorities store every update in their NVRAM 204 partitions on three separate blades 252 until the update has been written to flash 206. All the storage system writes to NVRAM 204 are in triplicate to partitions on three separate blades 252 in some embodiments. With triple-mirrored NVRAM 204 and persistent storage protected by parity and Reed-Solomon RAID checksums, the storage system can survive concurrent failure of two blades 252 with no loss of data, metadata, or access to either.

Because authorities 168 are stateless, they can migrate between blades 252. Each authority 168 has a unique identifier. NVRAM 204 and flash 206 partitions are associated with authorities’ 168 identifiers, not with the blades 252 on which they are running in some . Thus, when an authority 168 migrates, the authority 168 continues to manage the same storage partitions from its new location. When a new blade 252 is installed in an embodiment of the storage cluster 161, the system automatically rebalances load by:

Partitioning the new blade’s 252 storage for use by the system’s authorities 168,

Migrating selected authorities 168 to the new blade 252,

Starting endpoints 272 on the new blade 252 and including them in the switch fabric’s 146 client connection distribution algorithm.

From their new locations, migrated authorities 168 persist the contents of their NVRAM 204 partitions on flash 206, process read and write requests from other authorities 168, and fulfill the client requests that endpoints 272 direct to them. Similarly, if a blade 252 fails or is removed, the system redistributes its authorities 168 among the system’s remaining blades 252. The redistributed authorities 168 continue to perform their original functions from their new locations.

FIG. 2G depicts authorities 168 and storage resources in blades 252 of a storage cluster, in accordance with some embodiments. Each authority 168 is exclusively responsible for a partition of the flash 206 and NVRAM 204 on each blade 252. The authority 168 manages the content and integrity of its partitions independently of other authorities 168. Authorities 168 compress incoming data and preserve it temporarily in their NVRAM 204 partitions, and then consolidate, RAID-protect, and persist the data in segments of the storage in their flash 206 partitions. As the authorities 168 write data to flash 206, storage managers 274 perform the necessary flash translation to optimize write performance and maximize media longevity. In the background, authorities 168 “garbage collect,” or reclaim space occupied by data that clients have made obsolete by overwriting the data. It should be appreciated that since authorities’ 168 partitions are disjoint, there is no need for distributed locking to execute client and writes or to perform background functions.

The embodiments described herein may utilize various software, communication and/or networking protocols. In addition, the configuration of the hardware and/or software may be adjusted to accommodate various protocols. For example, the embodiments may utilize Active Directory, which is a database based system that provides authentication, directory, policy, and other services in a WINDOWSTM environment. In these embodiments, LDAP (Lightweight Directory Access Protocol) is one example application protocol for querying and modifying items in directory service providers such as Active Directory. In some embodiments, a network lock manager (NLM) is utilized as a facility that works in cooperation with the Network File System (NFS) to provide a System V style of advisory file and record locking over a network. The Server Message Block (SMB) protocol, one version of which is also known as Common Internet File System (CIFS), may be integrated with the storage systems discussed herein. SMP operates as an application-layer network protocol typically used for providing shared access to files, printers, and serial ports and miscellaneous communications between nodes on a network. SMB also provides an authenticated inter-process communication mechanism. AMAZONTM S3 (Simple Storage Service) is a web service offered by Amazon Web Services, and the systems described herein may interface with Amazon S3 through web services interfaces (REST (representational state transfer), SOAP (simple object access protocol), and BitTorrent). A RESTful API (application programming interface) breaks down a transaction to create a series of small modules. Each module addresses a particular underlying part of the transaction. The control or permissions provided with these embodiments, especially for object data, may include utilization of an access control list (ACL). The ACL is a list of permissions attached to an object and the ACL specifies which users or system processes are granted access to objects, as well as what operations are allowed on given objects. The systems may utilize Internet Protocol version 6 (IPv6), as well as IPv4, for the communications protocol that provides an identification and location system for computers on networks and routes traffic across the Internet. The routing of packets between networked systems may include Equal-cost multi-path routing (ECMP), which is a routing strategy where next-hop packet forwarding to a single destination can occur over multiple "best paths" which tie for top place in routing metric calculations. Multi-path routing can be used in conjunction with most routing protocols, because it is a per-hop decision limited to a single router. The software may support Multi-tenancy, which is an architecture in which a single instance of a software application serves multiple customers. Each customer may be referred to as a tenant. Tenants may be given the ability to customize some parts of the application, but may not customize the application's code, in some embodiments. The embodiments may maintain audit logs. An audit log is a document that records an event in a computing system. In addition to documenting what resources were accessed, audit log entries typically include destination and source addresses, a timestamp, and user login information for compliance with various regulations. The embodiments may support various key management policies, such as encryption key rotation. In addition, the system may support dynamic root passwords or some variation dynamically changing passwords.

FIG. 3A sets forth a diagram of a storage system 306 that is coupled for data communications with a cloud services provider 302 in accordance with some embodiments of the present disclosure. Although depicted in less detail, the storage system 306 depicted in FIG. 3A may be similar to the storage systems described above with reference to FIGS. 1A-1D and FIGS. 2A-2G. In some embodiments, the storage system 306 depicted in FIG. 3A may be embodied as a storage system that includes imbalanced active/active controllers, as a storage system that includes balanced active/active controllers, as a storage system that includes active/active controllers where less than all of each controller’s resources are utilized such that each controller has reserve resources that may be used to support failover, as a storage system that includes fully active/active controllers, as a storage system that includes dataset-segregated controllers, as a storage system that includes dual-layer architectures with front-end controllers and back-end integrated storage controllers, as a storage system that includes scale-out clusters of dual-controller arrays, as well as combinations of such embodiments.

In the example depicted in FIG. 3A, the storage system 306 is coupled to the cloud services provider 302 via a data communications link 304. The data communications link 304 may be embodied as a dedicated data communications link, as a data communications pathway that is provided through the use of one or data communications networks such as a wide area network (‘WAN’) or local area network (‘LAN’), or as some other mechanism capable of transporting digital information between the storage system 306 and the cloud services provider 302. Such a data communications link 304 may be fully wired, fully wireless, or some aggregation of wired and wireless data communications pathways. In such an example, digital information may be exchanged between the storage system 306 and the cloud services provider 302 via the data communications link 304 using one or more data communications protocols. For example, digital information may be exchanged between the storage system 306 and the cloud services provider 302 via the data communications link 304 using the handheld device transfer protocol (‘HDTP’), hypertext transfer protocol (‘HTTP’), internet protocol (‘IP’), real-time transfer protocol (‘RTP’), transmission control protocol (‘TCP’), user datagram protocol (‘UDP’), wireless application protocol (‘WAP’), or other protocol.

The cloud services provider 302 depicted in FIG. 3A may be embodied, for example, as a system and computing environment that provides services to users of the cloud services provider 302 through the sharing of computing resources via the data communications link 304. The cloud services provider 302 may provide on-demand access to a shared pool of configurable computing resources such as computer networks, servers, storage, applications and services, and so on. The shared pool of configurable resources may be rapidly provisioned and released to a user of the cloud services provider 302 with minimal management effort. Generally, the user of the cloud services provider 302 is unaware of the exact computing resources utilized by the cloud services provider 302 to provide the services. Although in many cases such a cloud services provider 302 may be accessible via the Internet, readers of skill in the art will recognize that any system that abstracts the use of shared resources to provide services to a user through any data communications link may be considered a cloud services provider 302.

In the example depicted in FIG. 3A, the cloud services provider 302 may be configured to provide a variety of services to the storage system 306 and users of the storage system 306 through the implementation of various service models. For example, the cloud services provider 302 may be configured to provide services to the storage system 306 and users of the storage system 306 through the implementation of an infrastructure as a service (‘IaaS’) service model where the cloud services provider 302 offers computing infrastructure such as virtual machines and other resources as a service to subscribers. In addition, the cloud services provider 302 may be configured to provide services to the storage system 306 and users of the storage system 306 through the implementation of a platform as a service (‘PaaS’) service model where the cloud services provider 302 offers a development environment to application developers. Such a development environment may include, for example, an operating system, programming-language execution environment, database, web server, or other components that may be utilized by application developers to develop and run software solutions on a cloud platform. Furthermore, the cloud services provider 302 may be configured to provide services to the storage system 306 and users of the storage system 306 through the implementation of a software as a service (‘SaaS’) service model where the cloud services provider 302 offers application software, databases, as well as the platforms that are used to run the applications to the storage system 306 and users of the storage system 306, providing the storage system 306 and users of the storage system 306 with on-demand software and eliminating the need to install and run the application on local computers, which may simplify maintenance and support of the application. The cloud services provider 302 may be further configured to provide services to the storage system 306 and users of the storage system 306 through the implementation of an authentication as a service (‘AaaS’) service model where the cloud services provider 302 offers authentication services that can be used to secure access to applications, data sources, or other resources. The cloud services provider 302 may also be configured to provide services to the storage system 306 and users of the storage system 306 through the implementation of a storage as a service model where the cloud services provider 302 offers access to its storage infrastructure for use by the storage system 306 and users of the storage system 306. Readers will appreciate that the cloud services provider 302 may be configured to provide additional services to the storage system 306 and users of the storage system 306 through the implementation of additional service models, as the service models described above are included only for explanatory purposes and in no way represent a limitation of the services that may be offered by the cloud services provider 302 or a limitation as to the service models that may be implemented by the cloud services provider 302.

In the example depicted in FIG. 3A, the cloud services provider 302 may be embodied, for example, as a private cloud, as a public cloud, or as a combination of a private cloud and public cloud. In an embodiment in which the cloud services provider 302 is embodied as a private cloud, the cloud services provider 302 may be dedicated to providing services to a single organization rather than providing services to multiple organizations. In an embodiment where the cloud services provider 302 is embodied as a public cloud, the cloud services provider 302 may provide services to multiple organizations. Public cloud and private cloud deployment models may differ and may come with various advantages and disadvantages. For example, because a public cloud deployment involves the sharing of a computing infrastructure across different organization, such a deployment may not be ideal for organizations with security concerns, mission-critical workloads, uptime requirements demands, and so on. While a private cloud deployment can address some of these issues, a private cloud deployment may require on-premises staff to manage the private cloud. In still alternative embodiments, the cloud services provider 302 may be embodied as a mix of a private and public cloud services with a hybrid cloud deployment.

Although not explicitly depicted in FIG. 3A, readers will appreciate that additional hardware components and additional software components may be necessary to facilitate the delivery of cloud services to the storage system 306 and users of the storage system 306. For example, the storage system 306 may be coupled to (or even include) a cloud storage gateway. Such a cloud storage gateway may be embodied, for example, as hardware-based or software-based appliance that is located on premise with the storage system 306. Such a cloud storage gateway may operate as a bridge between local applications that are executing on the storage array 306 and remote, cloud-based storage that is utilized by the storage array 306. Through the use of a cloud storage gateway, organizations may move primary iSCSI or NAS to the cloud services provider 302, thereby enabling the organization to save space on their on-premises storage systems. Such a cloud storage gateway may be configured to emulate a disk array, a block-based device, a file server, or other storage system that can translate the SCSI commands, file server commands, or other appropriate command into REST-space protocols that facilitate communications with the cloud services provider 302.

In order to enable the storage system 306 and users of the storage system 306 to make use of the services provided by the cloud services provider 302, a cloud migration process may take place during which data, applications, or other elements from an organization’s local systems (or even from another cloud environment) are moved to the cloud services provider 302. In order to successfully migrate data, applications, or other elements to the cloud services provider’s 302 environment, middleware such as a cloud migration tool may be utilized to bridge gaps between the cloud services provider’s 302 environment and an organization’s environment. Such cloud migration tools may also be configured to address potentially high network costs and long transfer times associated with migrating large volumes of data to the cloud services provider 302, as well as addressing security concerns associated with sensitive data to the cloud services provider 302 over data communications networks. In order to further enable the storage system 306 and users of the storage system 306 to make use of the services provided by the cloud services provider 302, a cloud orchestrator may also be used to arrange and coordinate automated tasks in pursuit of creating a consolidated process or workflow. Such a cloud orchestrator may perform tasks such as configuring various components, whether those components are cloud components or on-premises components, as well as managing the interconnections between such components. The cloud orchestrator can simplify the inter-component communication and connections to ensure that links are correctly configured and maintained.

In the example depicted in FIG. 3A, and as described briefly above, the cloud services provider 302 may be configured to provide services to the storage system 306 and users of the storage system 306 through the usage of a SaaS service model where the cloud services provider 302 offers application software, databases, as well as the platforms that are used to run the applications to the storage system 306 and users of the storage system 306, providing the storage system 306 and users of the storage system 306 with on-demand software and eliminating the need to install and run the application on local computers, which may simplify maintenance and support of the application. Such applications may take many forms in accordance with various embodiments of the present disclosure. For example, the cloud services provider 302 may be configured to provide access to data analytics applications to the storage system 306 and users of the storage system 306. Such data analytics applications may be configured, for example, to receive telemetry data phoned home by the storage system 306. Such telemetry data may describe various operating characteristics of the storage system 306 and may be analyzed, for example, to determine the health of the storage system 306, to identify workloads that are executing on the storage system 306, to predict when the storage system 306 will run out of various resources, to recommend configuration changes, hardware or software upgrades, workflow migrations, or other actions that may improve the operation of the storage system 306.

The cloud services provider 302 may also be configured to provide access to virtualized computing environments to the storage system 306 and users of the storage system 306. Such virtualized computing environments may be embodied, for example, as a virtual machine or other virtualized computer hardware platforms, virtual storage devices, virtualized computer network resources, and so on. Examples of such virtualized environments can include virtual machines that are created to emulate an actual computer, virtualized desktop environments that separate a logical desktop from a physical machine, virtualized file systems that allow uniform access to different types of concrete file systems, and many others.

For further explanation, FIG. 3B sets forth a diagram of a storage system 306 in accordance with some embodiments of the present disclosure. Although depicted in less detail, the storage system 306 depicted in FIG. 3B may be similar to the storage systems described above with reference to FIGS. 1A-1D and FIGS. 2A-2G as the storage system may include many of the components described above.

The storage system 306 depicted in FIG. 3B may include storage resources 308, which may be embodied in many forms. For example, in some embodiments the storage resources 308 can include nano-RAM or another form of nonvolatile random access memory that utilizes carbon nanotubes deposited on a substrate. In some embodiments, the storage resources 308 may include 3D crosspoint non-volatile memory in which bit storage is based on a change of bulk resistance, in conjunction with a stackable cross-gridded data access array. In some embodiments, the storage resources 308 may include flash memory, including single-level cell (‘SLC’) NAND flash, multi-level cell (‘MLC’) NAND flash, triple-level cell (‘TLC’) NAND flash, quad-level cell (‘QLC’) NAND flash, and others. In some embodiments, the storage resources 308 may include non-volatile magnetoresistive random-access memory (‘MRAM’), including spin transfer torque (‘STT’) MRAM, in which data is stored through the use of magnetic storage elements. In some embodiments, the example storage resources 308 may include non-volatile phase-change memory (‘PCM’) that may have the ability to hold multiple bits in a single cell as cells can achieve a number of distinct intermediary states. In some embodiments, the storage resources 308 may include quantum memory that allows for the storage and retrieval of photonic quantum information. In some embodiments, the example storage resources 308 may include resistive random-access memory (‘ReRAM’) in which data is stored by changing the resistance across a dielectric solid-state material. In some embodiments, the storage resources 308 may include storage class memory (‘SCM’) in which solid-state nonvolatile memory may be manufactured at a high density using some combination of sub-lithographic patterning techniques, multiple bits per cell, multiple layers of devices, and so on. Readers will appreciate that other forms of computer memories and storage devices may be utilized by the storage systems described above, including DRAM, SRAM, EEPROM, universal memory, and many others. The storage resources 308 depicted in FIG. 3A may be embodied in a variety of form factors, including but not limited to, dual in-line memory modules (‘DIMMs’), non-volatile dual in-line memory modules (‘NVDIMMs’), M.2, U.2, and others.

The example storage system 306 depicted in FIG. 3B may implement a variety of storage architectures. For example, storage systems in accordance with some embodiments of the present disclosure may utilize block storage where data is stored in blocks, and each block essentially acts as an individual hard drive. Storage systems in accordance with some embodiments of the present disclosure may utilize object storage, where data is managed as objects. Each object may include the data itself, a variable amount of metadata, and a globally unique identifier, where object storage can be implemented at multiple levels (e.g., device level, system level, interface level). Storage systems in accordance with some embodiments of the present disclosure utilize file storage in which data is stored in a hierarchical structure. Such data may be saved in files and folders, and presented to both the system storing it and the system retrieving it in the same format.

The example storage system 306 depicted in FIG. 3B may be embodied as a storage system in which additional storage resources can be added through the use of a scale-up model, additional storage resources can be added through the use of a scale-out model, or through some combination thereof. In a scale-up model, additional storage may be added by adding additional storage devices. In a scale-out model, however, additional storage nodes may be added to a cluster of storage nodes, where such storage nodes can include additional processing resources, additional networking resources, and so on.

The storage system 306 depicted in FIG. 3B also includes communications resources 310 that may be useful in facilitating data communications between components within the storage system 306, as well as data communications between the storage system 306 and computing devices that are outside of the storage system 306. The communications resources 310 may be configured to utilize a variety of different protocols and data communication fabrics to facilitate data communications between components within the storage systems as well as computing devices that are outside of the storage system. For example, the communications resources 310 can include fibre channel (‘FC’) technologies such as FC fabrics and FC protocols that can transport SCSI commands over FC networks. The communications resources 310 can also include FC over ethernet (‘FCoE’) technologies through which FC frames are encapsulated and transmitted over Ethernet networks. The communications resources 310 can also include InfiniBand (‘IB’) technologies in which a switched fabric topology is utilized to facilitate transmissions between channel adapters. The communications resources 310 can also include NVM Express (‘NVMe’) technologies and NVMe over fabrics (‘NVMeoF’) technologies through which non-volatile storage media attached via a PCI express (‘PCIe’) bus may be accessed. The communications resources 310 can also include mechanisms for accessing storage resources 308 within the storage system 306 utilizing serial attached SCSI (‘SAS’), serial ATA (‘SATA’) bus interfaces for connecting storage resources 308 within the storage system 306 to host bus adapters within the storage system 306, internet small computer systems interface (‘iSCSI’) technologies to provide block-level access to storage resources 308 within the storage system 306, and other communications resources that that may be useful in facilitating data communications between components within the storage system 306, as well as data communications between the storage system 306 and computing devices that are outside of the storage system 306.

The storage system 306 depicted in FIG. 3B also includes processing resources 312 that may be useful in useful in executing computer program instructions and performing other computational tasks within the storage system 306. The processing resources 312 may include one or more application-specific integrated circuits (‘ASICs’) that are customized for some particular purpose as well as one or more central processing units (‘CPUs’). The processing resources 312 may also include one or more digital signal processors (‘DSPs’), one or more field-programmable gate arrays (‘FPGAs’), one or more systems on a chip (‘SoCs’), or other form of processing resources 312. The storage system 306 may utilize the storage resources 312 to perform a variety of tasks including, but not limited to, supporting the execution of software resources 314 that will be described in greater detail below.

The storage system 306 depicted in FIG. 3B also includes software resources 314 that, when executed by processing resources 312 within the storage system 306, may perform various tasks. The software resources 314 may include, for example, one or more modules of computer program instructions that when executed by processing resources 312 within the storage system 306 are useful in carrying out various data protection techniques to preserve the integrity of data that is stored within the storage systems. Readers will appreciate that such data protection techniques may be carried out, for example, by system software executing on computer hardware within the storage system, by a cloud services provider, or in other ways. Such data protection techniques can include, for example, data archiving techniques that cause data that is no longer actively used to be moved to a separate storage device or separate storage system for long-term retention, data backup techniques through which data stored in the storage system may be copied and stored in a distinct location to avoid data loss in the event of equipment failure or some other form of catastrophe with the storage system, data replication techniques through which data stored in the storage system is replicated to another storage system such that the data may be accessible via multiple storage systems, data snapshotting techniques through which the state of data within the storage system is captured at various points in time, data and database cloning techniques through which duplicate copies of data and databases may be created, and other data protection techniques. Through the use of such data protection techniques, business continuity and disaster recovery objectives may be met as a failure of the storage system may not result in the loss of data stored in the storage system.

The software resources 314 may also include software that is useful in implementing software-defined storage (‘SDS’). In such an example, the software resources 314 may include one or more modules of computer program instructions that, when executed, are useful in policy-based provisioning and management of data storage that is independent of the underlying hardware. Such software resources 314 may be useful in implementing storage virtualization to separate the storage hardware from the software that manages the storage hardware.

The software resources 314 may also include software that is useful in facilitating and optimizing I/O operations that are directed to the storage resources 308 in the storage system 306. For example, the software resources 314 may include software modules that perform carry out various data reduction techniques such as, for example, data compression, data deduplication, and others. The software resources 314 may include software modules that intelligently group together I/O operations to facilitate better usage of the underlying storage resource 308, software modules that perform data migration operations to migrate from within a storage system, as well as software modules that perform other functions. Such software resources 314 may be embodied as one or more software containers or in many other ways.

Readers will appreciate that the various components depicted in FIG. 3B may be grouped into one or more optimized computing packages as converged infrastructures. Such converged infrastructures may include pools of computers, storage and networking resources that can be shared by multiple applications and managed in a collective manner using policy-driven processes. Such converged infrastructures may minimize compatibility issues between various components within the storage system 306 while also reducing various costs associated with the establishment and operation of the storage system 306. Such converged infrastructures may be implemented with a converged infrastructure reference architecture, with standalone appliances, with a software driven hyper-converged approach, or in other ways.

Readers will appreciate that the storage system 306 depicted in FIG. 3B may be useful for supporting various types of software applications. For example, the storage system 306 may be useful in supporting artificial intelligence applications, database applications, DevOps projects, electronic design automation tools, event-driven software applications, high performance computing applications, simulation applications, high-speed data capture and analysis applications, machine learning applications, media production applications, media serving applications, picture archiving and communication systems (‘PACS’) applications, software development applications, and many other types of applications by providing storage resources to such applications.

FIG. 4A is a diagram of a storage array with rule(s) 402 that emphasize usage of a specified solid-state storage drive, to increase long-term system reliability. A storage array controller 110 is coupled to and communicates with multiple solid-state storage drives 171. A set of one or more rules 402 is accessible by the storage array controller 110, e.g., in memory coupled to the storage array controller 110. In some embodiments, the storage array controller 110 has multiple storage array controllers 110A, 110B as described above with reference to FIGS. 1A-1D. The rules 402 specify a particular solid-state drive identifier (ID), which is selectable in various embodiments, and specify that usage of the selected solid-state drive 171 is to be emphasized during storage system operations in repetition over time. As a result of many repeated storage system operations with such emphasis, there is increased wear on the solid-state memory on the selected solid-state storage drive 171 in comparison to the other solid-state storage drives 171, over time. Statistically, this will result in the selected solid-state storage drive 171 failing sooner than the other solid-state storage drives 171, and making it less likely that there will be multiple simultaneous failures of solid-state storage drives prior to the failure of the emphasized solid-state storage drive 171. This emphasized usage of the selected solid-state storage drive 171, per the rules 402, thus improves long-term reliability of the storage system. If or when the emphasized solid-state drive 171 fails, or prior to an actual failure, e.g., from a warning from changes in storage system statistics such as increased error rates correctable by error correction coding, the selected solid-state storage drive 171 can be removed and/or replaced by another solid-state storage drive 171. At that time, one of the now older solid-state storage drives 171 may be designated as the drive for which to emphasize usage. In some embodiments, there are tiers of usage emphasis, and one of the more emphasized solid-state storage drives 171 could be designated as the most emphasized solid-state storage drive 171, upon failure or replacement of the previously most-emphasized solid-state storage drive 171.

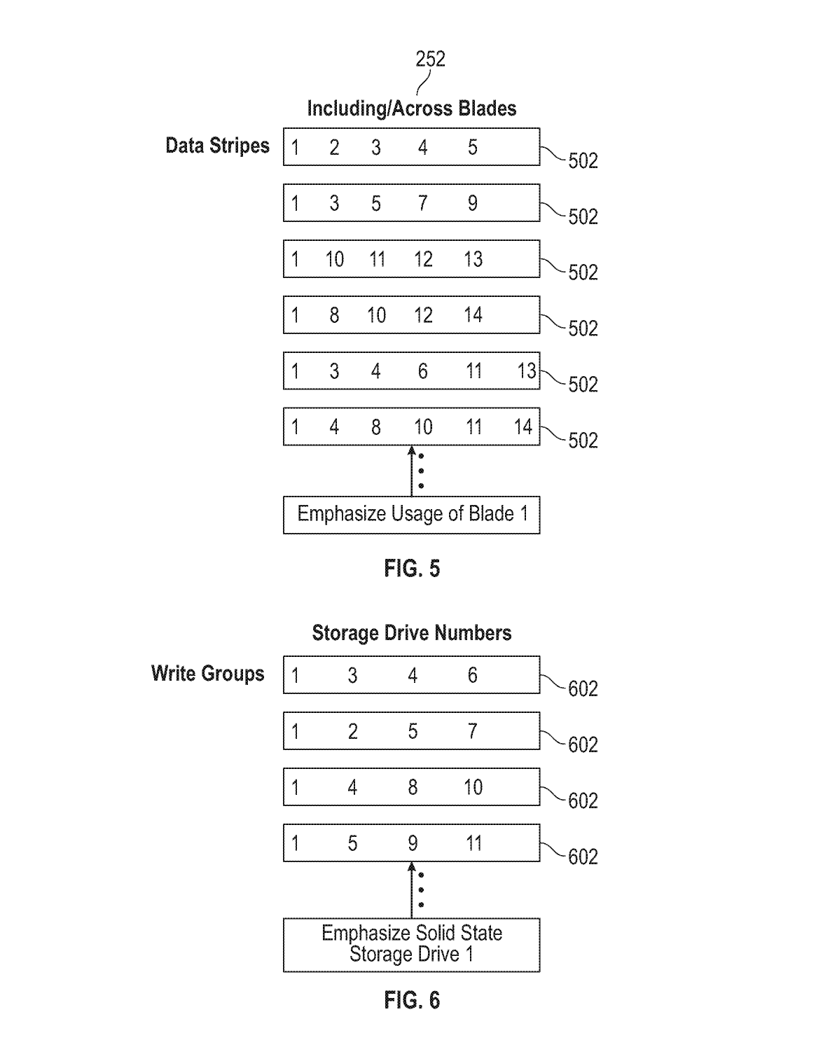

FIG. 4B is a diagram of a storage cluster 160 with rule(s) 402 that emphasize usage of a specified blade, to increase long-term system reliability. In the embodiment shown, the storage cluster 160 has multiple blades 252, each of which has a storage node 150 with flash memory 206, as described above with reference to FIGS. 2A-3B. A set of one or more rules 402 is accessible by the CPU 156 in each storage node 150 or blade 252. In the embodiment shown, authorities 168 are present in each storage node 150 and blade 252, and participate in implementing rules 402. In some versions, each storage node 150 has a copy of the rules 402, for example maintained in a memory coupled to the CPU 156. The rules 402 specify a particular blade 252, which is selectable in various embodiments, and specify that usage of the selected blade 252 is to be emphasized during storage system operations. Similar to the emphasis of a selected solid-state storage drive 171 described above with reference to FIG. 4A, there is increased wear on the flash memory 206 on the selected blade 252 in comparison with the other blades 252 over time. Such emphasis and repetition of the system operations over time is statistically likely to result in the selected blade 252, or more specifically the flash memory 206 on the selected blade 252, failing sooner than flash memory 206 on other blades 252, decreasing the likelihood of multiple simultaneous failures of blades 252. In some embodiments with replaceable storage units 152, a specific storage unit 152 could be designated for emphasis. Further variations with tiered usage emphasis are readily developed. Rules 402 and the mechanism(s) of emphasizing usage of a selected drive or blade, or in further embodiments having tiers of selected drives or blades and tiered emphasis of usage as described above, are readily adaptable to further storage systems, including further storage arrays and storage clusters. Various mechanisms for emphasis of a selected drive or blade, or tiers of selected drives or blades, are described below with reference to FIGS. 5-8.

FIG. 5 depicts example data stripes 502 that emphasize usage of a specified blade 252, suitable for the storage cluster of FIG. 4B. Similar data stripes 502 could be used in other storage systems that use data striping. In this example, the usage of blade 1 is emphasized, and blade 1 is included in all of the stripes 502. By writing data across various blades 252 but always including the selected emphasized blade in each subset of blades used in the data striping, the storage system causes the selected blade 252 to see increased usage as compared to the other blades 252. This is one version of the mechanism for emphasized usage of a selected blade 252 described above with reference to FIG. 4B. In variations, the selected blade 252 is included more often than not in stripes 502, or at least more often than other blades. Emphasis on blade 1 is by example only, and other blades 252 are readily selected for emphasis instead. Similarly, a storage drive can be selected for emphasis in data stripes in further embodiments.

FIG. 6 depicts example write groups 602 that emphasize usage of a specified solid-state storage drive 171, suitable for the storage array of FIG. 4A. Similar write groups 602 could be used in other storage systems that use write groups. A write group is a group of storage drives used for writing specified data. The write groups 602 shown in FIG. 6 emphasizes solid-state storage drive 1, which is included in all of the write groups 602. By writing data to various write groups 602 but always including the selected emphasized solid-state storage drive 171 in each subset of drives used in a specific group, the storage system causes the selected solid-state storage drive 171 to see increased usage as compared to other solid-state storage drives 171. This is one version of the mechanism for emphasized usage of a selected solid-state storage drive 171 described above with reference to FIG. 4A. Variations similar to those described with reference to FIG. 5 are readily developed for write groups 602.

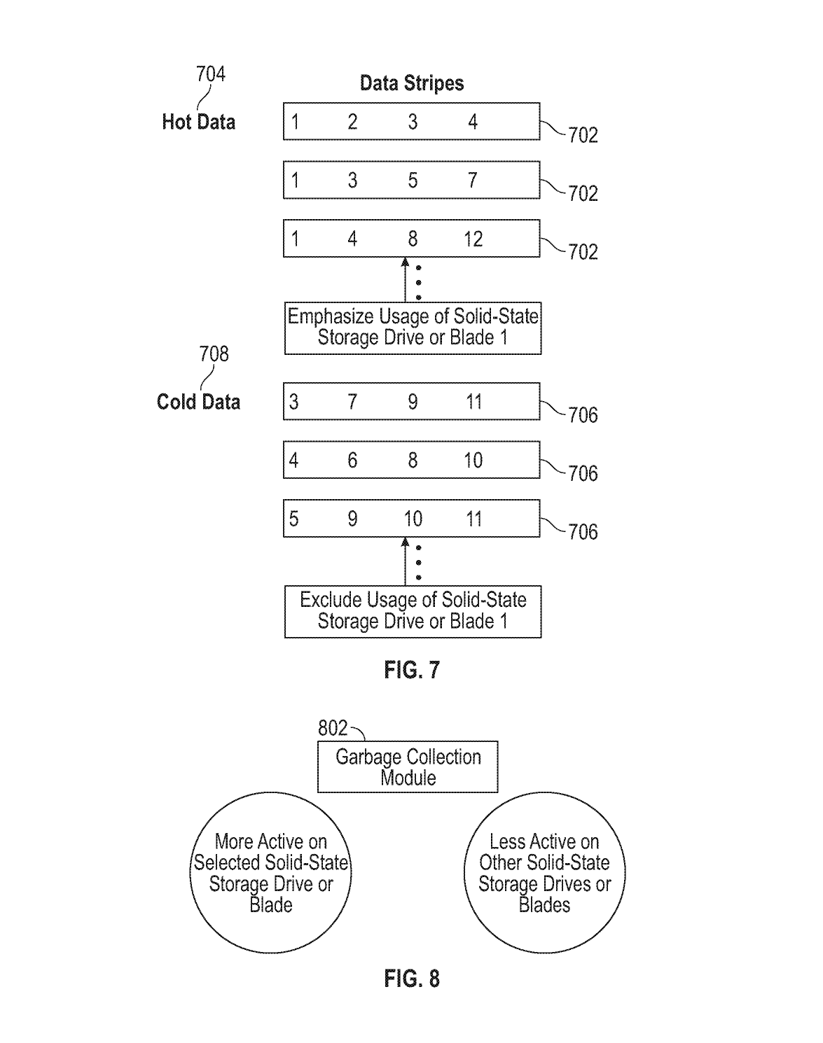

FIG. 7 depicts example data stripes 702 for writing hot data 704 to emphasize usage of a specified solid-state storage drive 171 or blade 252, and data stripes 706 for writing cold data 708 to exclude usage of a specified solid-state storage drive 171 or blade 252, suitable for the storage array of FIG. 4A or the storage cluster 160 of FIG. 4B. Hot data 704 is data that is frequently updated, frequently written to or read, or written recently and expected to be read and modified often, in various versions, while cold data 708 is data that is infrequently written to or read in various versions, such as archive data, legacy data, old data (e.g., per timestamp), etc. Data stripes 702 for hot data 704 all, or in other further embodiments mostly, include the selected solid-state storage drive or blade. For instance, drive or blade 1 in this example is the selected drive or blade, although other drives or blades are readily specified. Data stripes 706 for cold data 708 all, or in further embodiments mostly, do not have the selected solid-state storage drive or blade as one of the drives or blades over which the stripe is written. Because hot data 704 is accessed more often relative to cold data 708, and because the data stripes 702 for hot data 704 emphasize usage of the selected solid-state storage drive or blade (similarly to the data stripes in FIG. 5), the selected drive or blade has increased usage as compared to other drives or blades. This is another version of the mechanism for emphasized usage of specified flash or other solid-state memory.

FIG. 8 shows a garbage collection module 802 that is more active on a selected solid-state storage drive or blade, and less active on other solid-state storage drives or blades, suitable for the storage array of FIG. 4A or the storage cluster of FIG. 4B. The garbage collection module 802 could be tuned, programmed or otherwise directed to perform garbage collection more often on the selected solid-state storage drive or blade, or directed to preferentially write to the selected solid-state storage drive or blade for interim data transfers or final data destination. In the embodiments of storage clusters 160, where each blade 252 could have a garbage collection module 802, the blade 252 designated for emphasized usage could tune the resident garbage collection module 802 for a high activity rate, and other blades 252 could tune the garbage collection modules 802 for a lower activity rate relative to each other. Garbage collection modules 802 could be directed to relocate data in the process of garbage collection so as to set up for the data stripes 502 emphasizing a selected blade as shown in FIG. 5 and/or data stripes 702 for hot data 704 as shown in FIG. 7.

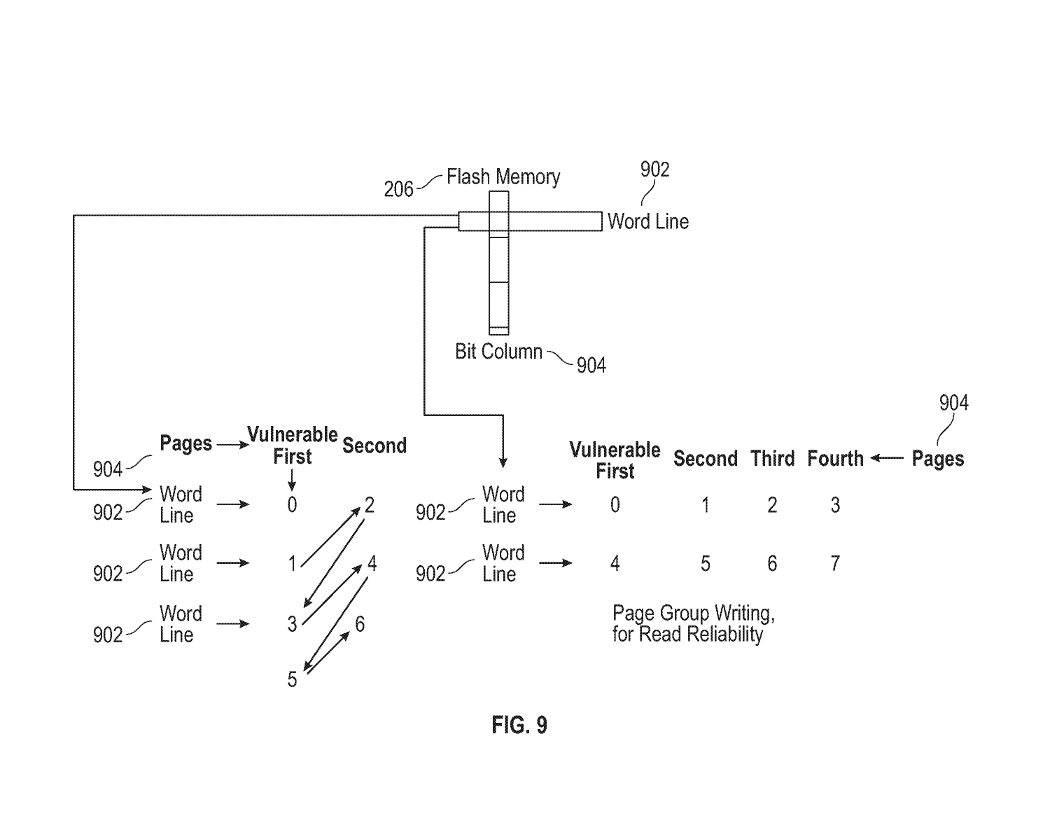

FIG. 9 shows page group writing recommendations, relative to word lines or bit columns, for read reliability. A manufacturer may recommend or specify which pages should be written, and/or in which order pages should be written, for best read reliability of pages. In some types of flash memory, it is desirable to write to two or more pages that share a word line 902, for maximum read reliability of each of the pages on that word line, or for maximum read reliability of the lowest address page on that word line. In some types of flash memory, it is desirable to write to two or more pages that share a bit column 904, for maximum read reliability of each of the pages on that bit column 904, or maximum read reliability of the lowest address page on that bit column 904. It should be appreciated that reasons for such reliability concerns may have to do with capacitive coupling of word lines 902 and/or bit columns 904 under various conditions of programmed or unprogrammed bits, and vary from design to design and manufacturer to manufacturer of flash memory.

One example of page vulnerability and page group writing recommendations is shown at the lower left of FIG. 9. Page 0 is vulnerable to lower read reliability if written while page 2 remains unwritten. Page 1 is vulnerable to lower read reliability if written while page 4 remains unwritten. Page 3 is vulnerable to lower read reliability if written while page 6 remains unwritten, and so on. In this particular sequence, the first page on a word line is the vulnerable page, the second page on that word line, when written, secures the read reliability of both the first and second pages. Reliability is thus improved when both the first and second pages of a page group are written.

Another example of page vulnerability and page group writing recommendations is shown at the lower right of FIG. 9. Page 0 is vulnerable to lower read reliability if written while pages 1, 2 and 3 remain unwritten. This is because pages 0, 1, 2 and 3 share a word line 902, and the first of these pages, page 0 is the vulnerable page. Similarly, page 4 is vulnerable to lower read reliability if written while pages 5, 6 and 7 remain unwritten. This is because pages 4, 5, 6 and 7 share a word line 902. The first page on a word line may be the vulnerable page, and the second, third and fourth pages on that word line 902, when written, secure the read reliability of all of the pages. Reliability is thus improved when first, second, third and fourth pages of a page group are written.

Further examples of page groups for writing, to secure read reliability, are readily developed in keeping with the teachings herein. Various embodiments of storage systems could establish a rule 402 (see FIGS. 4A and 4B) to always write pages in page groups, for read reliability improvement. In one embodiment, if there is a power failure, the storage system senses the power failure and writes dummy pages to any unfilled page groups. Writing to fill page groups is combined with emphasis of usage of a specified storage drive or blade, in some embodiments, in a combination that improves read reliability of the storage system.

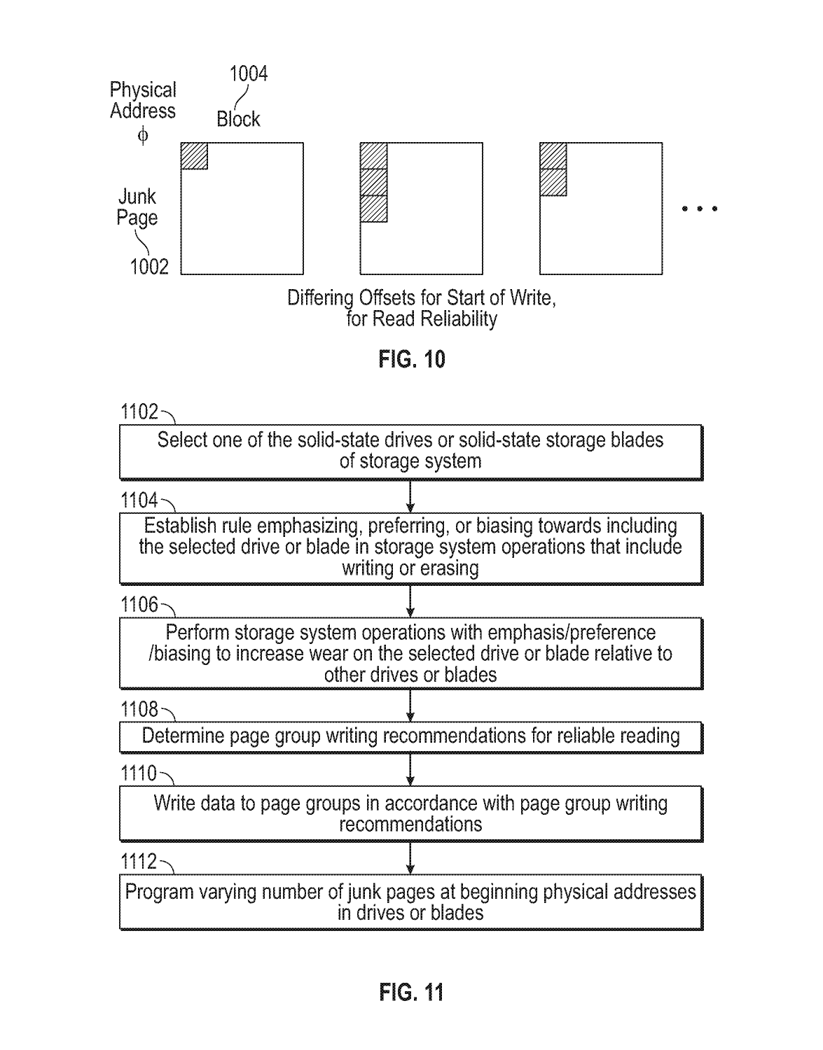

FIG. 10 shows a technique of writing junk pages 1002 in differing amounts to starting physical addresses in flash memory, for read reliability. A junk page 1002 could be all zeros, a pattern of zeros and ones, or all ones. In the example depicted in FIG. 10, one junk page 1002 is written to one block 1004 of flash memory, three junk pages 1002 are written to another block 1004, and two junk pages 1002 are written to yet another block 1004. A specified pattern, or a pseudorandom distribution of numbers of junk pages 1002 could be developed for further blocks. By establishing differing offsets for the start of data writes to various blocks 1004, the likelihood of having multiple vulnerable first pages written without remaining pages in a page group being filled (by data writing) is statistically reduced. Consequently, this reduces the likelihood of having multiple failed data reads across a data stripe, which could be uncorrectable by error correction code. Writing differing numbers of junk pages 1002 to starting physical addresses (e.g., address 0 of a specific flash device) across solid states storage devices 171 of a storage array, or across flash memories 206 of blades 252 thus improves read reliability of the storage system. In some embodiments, this is combined with emphasis of usage of a specified storage driver blade, as described above with reference to FIGS. 4A and 4B and in embodiments described with reference to FIGS. 5-8.

FIG. 11 is a flow diagram of a method to increase long-term reliability of a storage system, which can be practiced by embodiments of storage systems, including storage arrays and storage clusters described herein. The method can be practiced by one or more processors, such as an array controller or a distributed processor of a storage cluster (e.g., processors of blades or nodes). In an action 1102, one of the solid-state drives or solid state storage blades of a storage system is selected. The drive or blade is selected for emphasized usage. For example, the oldest drive or blade could be selected, or one of the oldest drives or blades, could be selected at random or by voting. In an action 1104, a rule is established emphasizing, preferring or biasing towards writing or erasing to the selected driver blade in storage system operations. In an action 1106, storage system operations are performed with emphasis, preference or biasing to increase wear on the selected driver blade, relative to other drives or blades in the system. Examples of system operations emphasizing usage of a selected blade or drive include writing to data stripes or write groups, handling of hot data and cold data with various data stripes, and tuned garbage collection, as depicted in FIGS. 5-8. These actions 1102, 1104, 1106 for emphasizing a selected solid-state storage drive or blade are shown here in combination with actions 1108, 1110, 1112, but are performed separately in further embodiments.

In an action 1108 of FIG. 11, page group writing recommendations are determined for reliable reading of data written to solid-state memory. In an action 1110, data is written to page groups in accordance with the page group writing recommendations. In an action 1112, a varying number of junk pages is programmed at the beginning physical addresses in solid-state storage drives or blades. Examples of page write groups and junk page writing are shown in FIGS. 9 and 10. Actions 1108, 1110, 1112 for improving read reliability are shown here in combination with the actions 1102, 1104, 1106 that emphasize a selected drive or blade in storage system operations, relative to other drives or blades, but could be implemented separately in further embodiments. In addition, while the method is discussed with emphasis toward one storage drive or blade, the method may be extended to a group of storage drives or blades of the system.

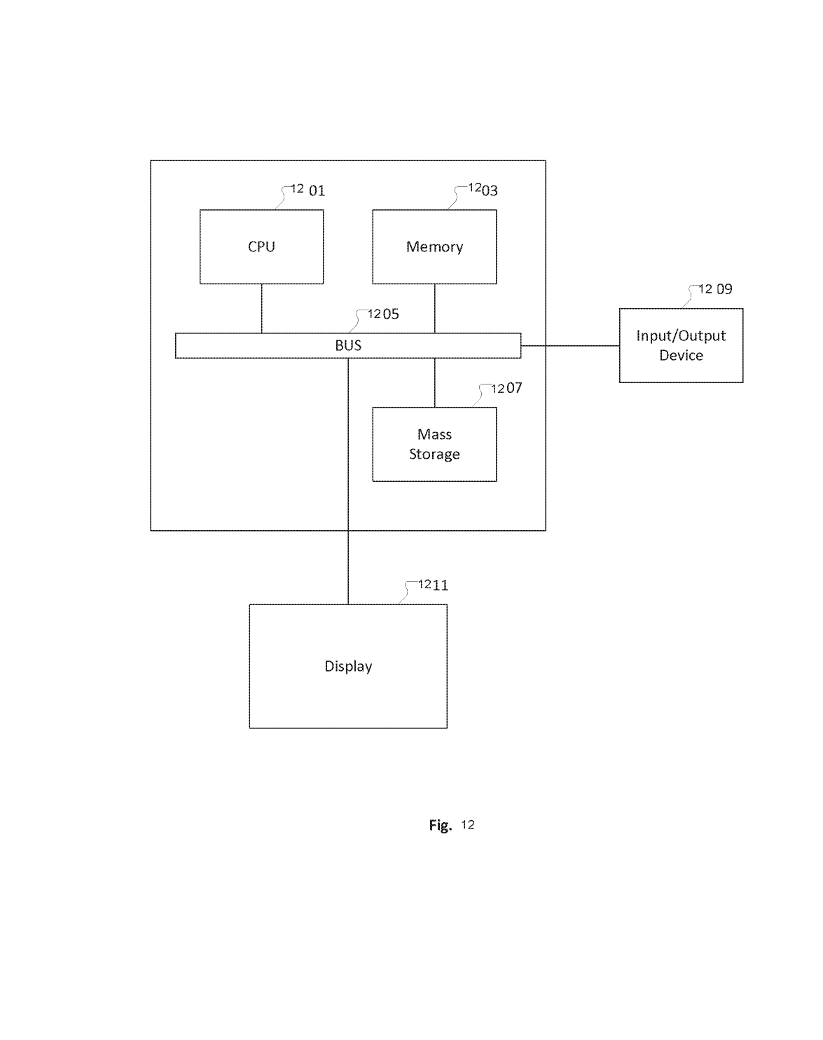

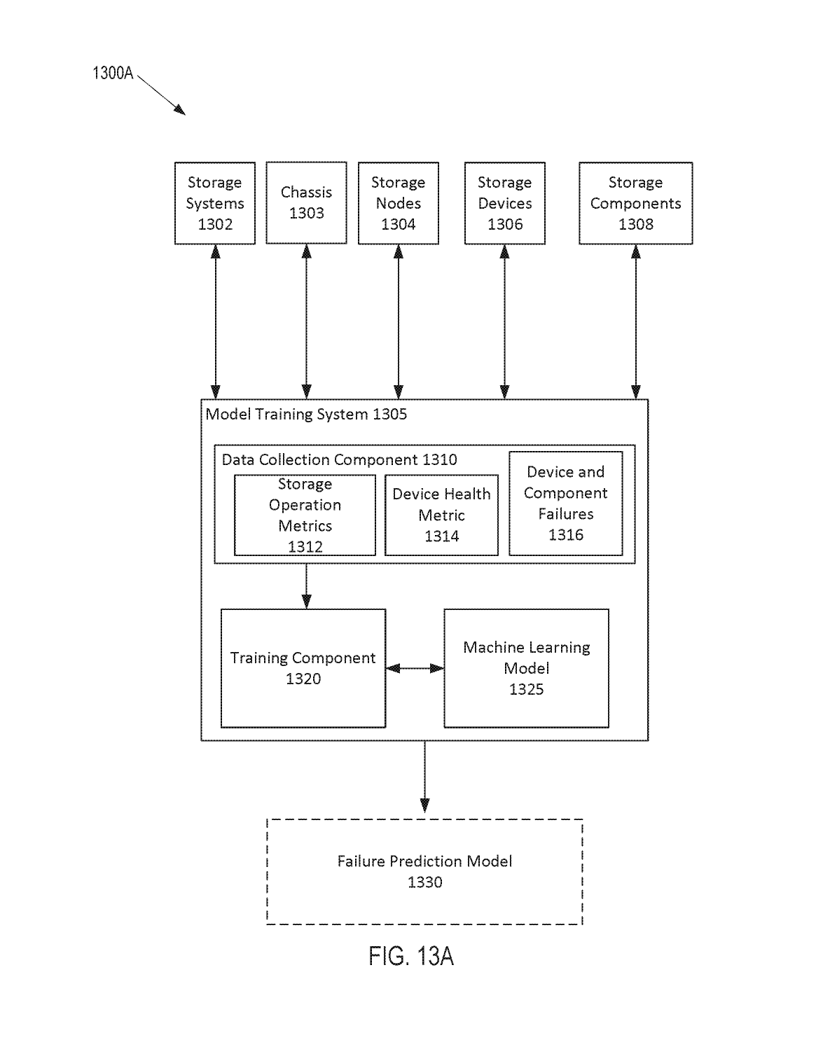

It should be appreciated that the methods described herein may be performed with a digital processing system, such as a conventional, general-purpose computer system. Special purpose computers, which are designed or programmed to perform only one function may be used in the alternative. FIG. 12 is an illustration showing an exemplary computing device which may implement the embodiments described herein. The computing device of FIG. 12 may be used to perform embodiments of the functionality for improvements to system reliability in accordance with some embodiments. The computing device includes a central processing unit (CPU) 1201, which is coupled through a bus 1205 to a memory 1203, and mass storage device 1207. Mass storage device 1207 represents a persistent data storage device such as a floppy disc drive or a fixed disc drive, which may be local or remote in some embodiments. The mass storage device 1207 could implement a backup storage, in some embodiments. Memory 1203 may include read only memory, random access memory, etc. Applications resident on the computing device may be stored on or accessed via a computer readable medium such as memory 1203 or mass storage device 1207 in some embodiments. Applications may also be in the form of modulated electronic signals modulated accessed via a network modem or other network interface of the computing device. It should be appreciated that CPU 1201 may be embodied in a general-purpose processor, a special purpose processor, or a specially programmed logic device in some embodiments.

Display 1211 is in communication with CPU 1201, memory 1203, and mass storage device 1207, through bus 1205. Display 1211 is configured to display any visualization tools or reports associated with the system described herein. Input/output device 1209 is coupled to bus 1205 in order to communicate information in command selections to CPU 1201. It should be appreciated that data to and from external devices may be communicated through the input/output device 1209. CPU 1201 can be defined to execute the functionality described herein to enable the functionality described with reference to FIGS. 1-11. The code embodying this functionality may be stored within memory 1203 or mass storage device 1207 for execution by a processor such as CPU 1201 in some embodiments. The operating system on the computing device may be iOS^{TM}, MS-WINDOWS^{TM}, OS/2^{TM}, UNIX^{TM}, LINUX^{TM}, or other known operating systems. It should be appreciated that the embodiments described herein may also be integrated with a virtualized computing system implemented with physical computing resources. Detailed illustrative embodiments are disclosed herein. However, specific functional details disclosed herein are merely representative for purposes of describing embodiments. Embodiments may, however, be embodied in many alternate forms and should not be construed as limited to only the embodiments set forth herein.

To further provide reliability and performance for storage systems, stored devices, storage services, and so forth, embodiments may provide predictive device wear and failure detection to proactively identify and notify about potential or imminent device failures. Embodiments may include a system to monitor key metrics over time related to device degradation, including tracking the number of block degradation events, frequency of P/E cycles, number of writes to new blocks, and so forth to identify the contribution of various operations or operating parameters to the device or component wear over time. In addition to the operations and operating parameters, embodiments may gather data on storage device degradation over time as well as device failure events to correlate the operations and operating parameters with storage device health and failures. In some embodiments, the system may further provide the information collected above to generate a framework (e.g., a model produced through various machine learning methods, a set of heuristics, or a combination thereof) for using sequential data of the collected information to predict device degradation and eventual failures. For example, embodiments may include training a recurrent neural network (RNN), using the collected information, to identify patterns that indicate how device degradation may progress over time due to the various operating parameters. For example, the RNN may be trained to predict a rate of device degradation based on the operating parameters and to estimate when the disk has more than a threshold likelihood of reaching critical wear levels (e.g., with a moderate to high risk of failure). Based on the estimates of the RNN, the system may proactively provide notifications or alerts when a device may be nearing failure and may need to be replaced, and provides opportunities for migrating data or avoiding writes of new data to failing or degraded storage devices or parts of storage devices, thus reducing the potential for data loss or more expensive recoveries resulting from such failures. Thus, embodiments provide for better device lifecycle management with a reduction in unexpected failures, and a reduction in both data loss and higher overhead data rebuilds, which improves system uptime, data availability, and maintenance planning. Although embodiments herein are described as operating with a recurrent neural network (RNN) it should be noted that any framework for handling sequential data may be used, such as transformer models, temporal convolutional network (TCN), or any other model capable of observing and accounting for state changes of a variety of parameters across time steps that precede a fault or a degraded condition.

In some embodiments, a failure prediction model may be trained by gathering statistically sampled field data over time that may be relevant for detecting early or eventual storage component failure (e.g., die, package, interconnect, capacitor, device controller, or other partial or total storage device failures) and providing the sampled data along with component failure data to an RNN, to train or develop a statistical failure prediction model for early or eventual component failures. For example, the initial failure prediction model may estimate, model, or predict early failures and then collect additional component failure data to further update and train the failure prediction model. As more failure data and corresponding sampled field data is collected and provided to update the model, the more accurate the failure prediction model may become.

In some embodiments, the statistically gathered data may be tied, for example, to specific component model numbers and hardware revisions from specific manufacturers. Additionally, the sampled data may be tied further to specific batches of devices or components so that the model can extrapolate the variables that led to actual failures to the rest of the fleet of storage systems and storage devices (e.g., based in part on the components utilized in the manufacture of each storage system and storage device).

The RNN may be fed data gathered relatively frequently, potentially continuously as events occur, from the field, updating its models accordingly over time. The resulting trained model may be deployed as a local neural network on all storage systems or storage devices. Alternatively, the trained model may be used together with a tuned algorithm (e.g., including various rules or heuristics) to predict failures which could run on storage systems or storage devices. For example, the trained model may be used to identify a subset of useful metrics (e.g., the metrics correlating the most with failure or degradation) and filter out those metrics that are not useful or metrics that are determined to be redundant. The subset of refined metrics may then be used as inputs to the tuned algorithm. The deployment of the trained model or the tuned algorithm may depend on how simple of a model can be generated (e.g., the size of the model, including the number of inputs and outputs of the model and computing resources required for executing the model) and the available computational resources for running the produced model.

In some embodiments, collecting data associated with the operation and failure of the storage components may include randomly selecting a subset of components, of all deployed devices and components, to obtain a sample size that is large enough to be statistically useful. For example, the sample size should be large enough that a usefully large number of components failures among the set would be expected. Embodiments may then gather samples throughout the lifespan of the monitored storage devices containing the selected subset of components until a monitored component fails. A failure may include complete failure of the component or failures that lose data requiring a rebuild but where the component may still be rehabilitated. In some examples, the amount of captured data associated with the various metrics and operating parameters of numerous devices, components, nodes, and systems may be extremely large. Accordingly, in some embodiments, the data may be down-sampled or aggregated to reduce the amount of data stored and processed by a failure prediction system. Additionally, to assist in processing such large amounts of collected data, a larger model may be trained to first distill the inputs to a smaller model. For example, the larger model may be trained to reduce the inputs from the collected data into a smaller number of inputs for the smaller model.

Local storage systems or storage devices may also record detailed data for all constituent components and maintain such data for a period of time after which some portion of the data may be deleted or removed. The locally maintained data may be provided to train the failure prediction model when a component fails or loses data. The data regarding the failed components may be input into a machine learning model or time series machine learning model for training. Data from similarly detailed traces for components that didn’t fail may be provided to the trained failure prediction model to identify additional statistical predictions of failure cases that could be detected soon before they would fail. In some examples, up to a few tens of millions of data samples for locally recorded data on everything on a storage system or even an individual storage device may be collected and maintained at any given time. In other words, the sampled data may be maintained as a rolling window of data such that the data immediately preceding a failure can be compared with time windows that didn’t result in a failure with the combination used to train the model.

In some embodiments, the data sampled from storage devices and components may include voltage table changes, read errors that can be corrected using ECC, read errors that can be corrected after adjusting voltage levels, including the history of the specific voltage levels for writes and for reads and which voltage levels did and did not work for reads, read patterns, power failure/restarts with included clock values or with measured durations of run-time and down time, programming modes, patterns of programming the flash, patterns of erases, latency jitters in programming or erase operations or in read requests, wear level imbalances, interrupted programs or erases, monitored temperatures using whatever temperature sensors are available, voltage fluctuations on the storage devices themselves, or any other measurements or operational parameters associated with a storage device or component. Similarly, the data sampled may further include a position or location within a flash strings that a failed component is located and the position or location within an overall geometry of a storage component and storage device (e.g., NAND geometry), the states of neighboring components at a time of failure of a component, time intervals between PE cycles, and counts of reads including read disturb tracking. Furthermore, as storage devices are tuned during operation, data may be read and flash pages or flash word lines that are operating abnormally can be identified and tracked. Another aspect that may be tracked includes power loss protection (PLP) health of the storage devices, including for example supercapacitors and regular capacitors. For example, declines in available energy or changes in charging times can be tracked and can be associated with particular modules, models, or batches, or differences between expected available energy and actual available energy can be measured and used as an indicator. Additionally, embodiments may also monitor on-board humidity and magnetic fields at various physical locations within a storage system as well as acoustic and other vibration data such as using microphones or accelerometers as well as radiation such as counting high energy particles.

Accordingly, embodiments may apply to smart storage devices that can gather statistics and run a loaded prediction model, and it could apply to managed flash storage devices, where statistics are larger gathered by the storage system controllers even if it is the managed flash storage devices that do most of the data monitoring.

Embodiments may also be deployed on a scalable storage infrastructure, including gathering the data, storing the statistically sampled data, and running the machine learning and recurrent neural network trainings, and producing failure prediction models. The failure prediction models may then be loaded into local storage nodes or local storage devices in their environment. The data fed into the models could then include data from sensors in the scalable environment, including rack voltage levels and temperatures, and humidity.

Additionally, external sensors for collecting environmental condition data for devices and components may include low-power sensors running on battery power that can gather temperature, humidity and magnetic fields data during transport, such as during shipment to a customer. Furthermore, collected data may include data on when and where the storage devices were manufactured and what the temperatures, humidity levels, and/or magnetic fields were throughout the manufacturing process. Accordingly, embodiments may collect and consider various operational and environmental metrics to train and deploy a device and component failure prediction model to provide notifications of imminent failures, reducing storage system downtime, maintaining consistent storage capacity, avoiding data loss, reducing expensive data rebuild times, and providing additional efficiencies in storage system hardware management.

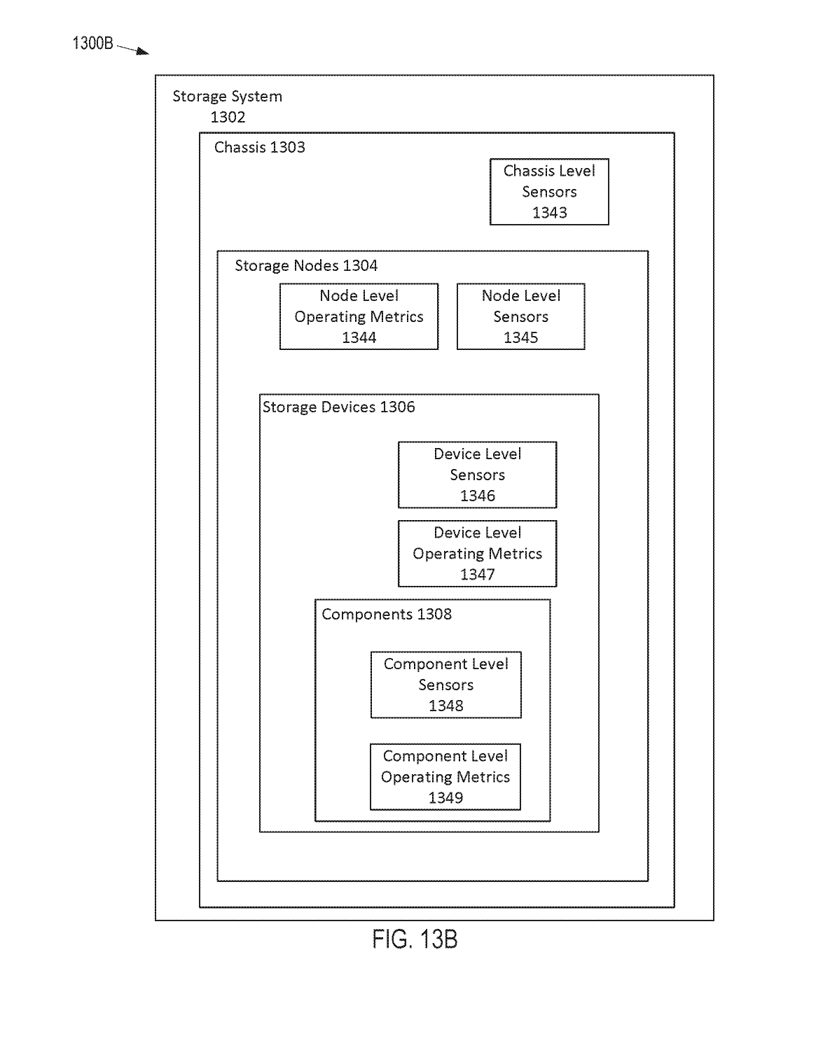

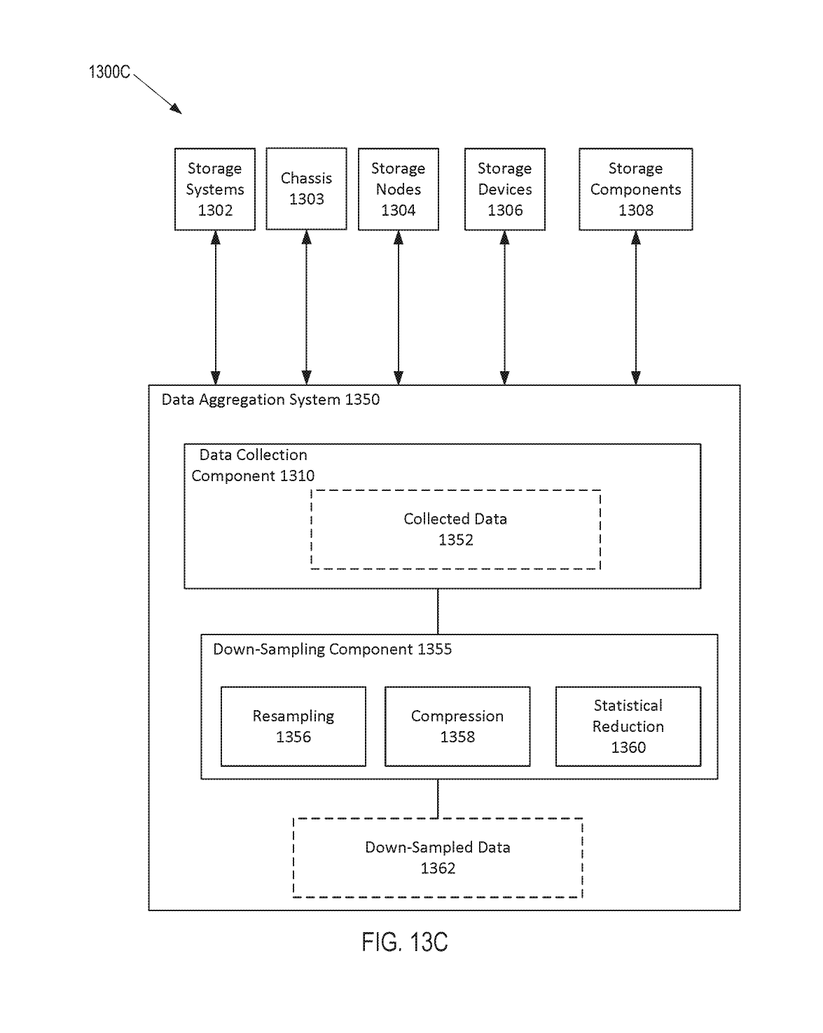

FIG. 13A is a block diagram illustrating a system 1300A for training a neural network to predict storage device and/or storage component lifecycle and failure, in accordance with embodiments described herein. As discussed above, embodiments may include collecting data, including operating data, environment data (e.g., temperature, humidity, etc.), for various storage devices or components, which may include collecting data at various levels within a storage system in order to train a machine learning model to predict storage component and/or storage device failures. For example, operating data, environmental data, failure data, and the like, may be collected at the storage system level, storage node level, storage device level, and/or from the individual storage component level, all or a portion of which, may be used to train a machine learning model.

As depicted in FIG. 13A, system 1300A includes a model training system 1305 for collecting data from one or more sources and training a machine learning model to predict storage device or storage component failures. In particular, system 1300A may collect data from various sources or levels within a storage architecture, such as storage systems 1302, storage nodes 1304, storage devices 1306, and/or storage components 1308. Model training system 1305 may include a data collection component 1310 to monitor, request, retrieve, or otherwise obtain data associated with operation of storage devices and storage components. For example, the data collection component 1310 may collect storage operation metrics 1312, device health metrics 1314, as well as device and component failures 1316 from a large number of storage systems 1302, storage nodes 1304, storage devices 1306, and storage components 1308. The storage operation metrics 1312 may include both internally tracked metrics associated with a storage device 1306 and storage components 1308, such as read/write voltages, error correction, and so forth, in addition to external metrics (e.g., detected by external sensors during operation) that indicate an operating environment and any other variables that may affect the lifespan of a storage device and its components, as discussed in more detail below with respect to FIG. 13B. The device health metrics 1314 may include device or component wear levels, block level wear, device or component failures (e.g., device and component failures 1316), performance and performance anomalies, indications of device or component data loss, or any other indicators of device health and remaining device or component lifespan, as discussed in more detail below with respect to FIG. 13B.

For example, as depicted in system 1300B of FIG. 13B, operating data and metrics may be collected from various sources within a storage system for training of and use by a failure prediction model. In some embodiments, a storage system 1302 may include one or more chassis 1303, storage nodes 1304, and storage devices 1306 including storage components 1308. Sensors may be deployed at any, or all, of these levels to collect operating and environmental data. For example, chassis level sensors 1343 may be deployed to collect data at the chassis level, such as temperature, humidity, electromagnetic fields, acoustic levels (e.g., noise), vibration, etc., of the chassis. Similarly, node level sensors 1345 may be deployed on one or more nodes 1304 of the storage system 1302 to collect data, such as temperature, humidity, electromagnetic fields, acoustic levels (e.g., noise), vibration, orientation, etc., of the corresponding node. Furthermore, node level operation metrics 1344 may be collected for one or more nodes 1304 of the storage system 1302, such as I/O operations received and performed, patterns of I/O operations, and so forth. More granular data for one or more devices 1306 may be collected at the device level and for one or more components 1308 of the device. For example, device level sensors 1346 may collect and monitor data, such as temperature, humidity, electromagnetic fields, acoustic levels (e.g., noise), vibration, etc., of each device while device level operating metrics 1347 that are collected may include voltage table changes, read errors that can be corrected using ECC, read errors that can be corrected after adjusting voltage levels, including the history of the specific voltage levels for writes and for reads and which voltage levels did and did not work for reads, read patterns, power failure/restarts with included clock values or with measured durations of run-time and down time, programming modes, patterns of programming the flash, patterns of erases, latency jitters in programming or erase operations or in read requests, wear level imbalances, interrupted programs or erases, or any other monitored operating metrics.

Additionally, component level sensors 1348 may monitor environmental conditions of components, such as temperature, humidity, electromagnetic fields, acoustic levels (e.g., noise), vibration, etc., of the components. Component level operating metrics 1349 may include similar data as collected at the device level, in addition to any additional data that may be collected. Similarly, the device and component level operating metrics 1347 and 1348 may further include a position or location within a flash string where a failed page or word line or erase block is located and the position or location within an overall geometry of a storage component and storage device (e.g., NAND geometry), the states of neighboring components at a time of failure of a component, time intervals between PE cycles, and counts of PE cycles and/or reads, including read disturb tracking. Furthermore, as storage devices are tuned during operation, data may be read and pages or word lines that are operating abnormally can be identified and tracked based on the read data. For example, when tuning voltage levels for a block, NAND characterization may be used to identify pages or word lines that are likely to be weak spots. The pages or word lines may then be tracked for a period of time after the tuning to determine the quality of the tuning (e.g., if the tuning was poor) which may indicate degradation of tuned voltage levels. Pages or word lines identified as yielding poor results from the tuning can then be used as part of a profile history that can be used herein to further train a model or be used to infer a time to failure, as described herein. Another aspect that may be tracked includes power loss protection (PLP) health of storage devices (e.g., how often PLP is necessary for a device and its components and the effectiveness of the PLP operations). For example, embodiments may monitor particular capacitor modules, models, or batches of capacitors (supercapacitor, regular capacitor, etc.), which may be used to detect patterns of certain variations of modules failing earlier than others. In particular, failures of particular modules, models, or batches of capacitors may be identified as being tied with other tracked parameters that may result in the failures, or degraded performance, of different module variants. Thus, PLP may assist with recognition of patterns of the collected data that indicate failures for particular capacitor modules, models, batches, etc.

Using the collected data discussed above, training component 1320 may provide at least a portion of the collected data as training data for a machine learning model 1325, such as a recurrent neural network (RNN) or other time-based machine learning model. For example, the data collected above may be collected as time series data (e.g., data points collected over a period of time with corresponding timestamps) which may be used to train a RNN or other time dependent neural network or machine learning model. Accordingly, the model training system 1305 may produce a failure prediction model 1330 that is trained to predict device and component degradation and estimated time of failure. In some embodiments, data may be continuously, frequently, or periodically collected to train and retrain, or update, the failure prediction model 1330 based on newly collected data. Thus, the failure prediction model 1330 may increase its effectiveness over time as additional device and component failures are detected and therefore more useful training data becomes available. It should be noted that any combination or variation of the environmental metrics and operating metrics may be used for training and executing the failure prediction model 1330.

In some embodiments, the collected data may further be reduced or “down-sampled” to reduce the amount of data that is stored by the failure prediction system and to reduce the size of the trained model. For example, FIG. 13C depicts a data aggregation system 1350 that may collect operating and environmental data of a storage system, aggregate that data and reduce the data to a more management size. Data aggregation system 1350 may include data collection component 1310, as described with respect to FIG. 13A to collect and aggregate data 1352 from the various components of one or more storage systems, as discussed above. Additionally, the data aggregation system 1350 may include down-sampling component 1355 which may perform one or more operations to reduce the amount of data used by the failure prediction system described herein. For example, the down-sampling component 1355 may include operations for resampling 1356, compression 1358, and/or statistical reduction 1360.

Resampling 1356 the collected data 1352 may include sampling a subset of the collected data 1352. For example, resampling 1356 may include selecting data collected from a subset of devices or components, a subset of sequential data (e.g., at various intervals), or any other subset of the collected data 1352, and removing the unselected data. Compression 1358 may include any form of compression, including but not limited to, deduplication of redundant data, conventional data compression, removal of significant outliers or unreliable data, etc. Statistical reduction 1360 may include performing one or more operations to reduce the data into representative data. For example, statistical reduction 1360 may include taking averages, standard deviations, histograms, or other statistical operation for a set of data collected over a certain time interval (e.g., data statistically reduced for one or more metrics over a period of seconds, minutes, hours, days, or any larger or smaller interval). Accordingly, by performing one or more of the resampling 1356, compression 1358, and statistical reduction 1360, the collected data 1352 may be significantly reduced to a down-sampled data set 1362 which may be used for training a failure prediction model or as an input to an already trained failure prediction model, as described herein.

In some embodiments, one or more data aggregation systems 1350 may be deployed within a large-scale storage platform, such as large-scale storage platform 396 of FIG. 3G. For example, data may be collected from sensors located at storage nodes, as described herein, and aggregated by data aggregation system 1350 located within the large-scale storage platform. Similarly, the model training system 1305 of FIG. 13A may also be deployed within a large-scale storage platform (e.g., in conjunction with data aggregation system 1350) to generate and deploy predictive models for estimating time to failure of components, devices, nodes, etc. within the large-scale storage platform. In some embodiments, the local aggregation system 1350 may provide summarized data (e.g., the down-sampled data set 1362) to a storage node of the large-scale storage platform, or to a storage device vendor, which may then generate and return a trained model back to the large-scale storage platform.

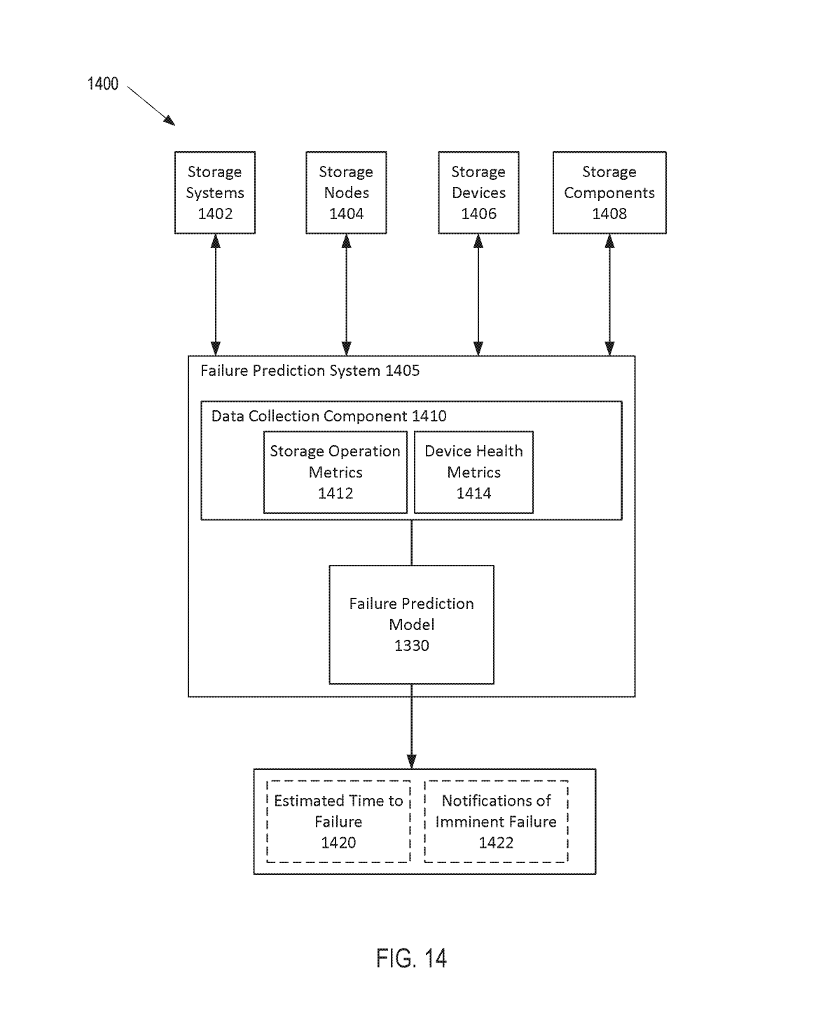

FIG. 14 is a block diagram illustrating a system 1400 for applying a failure predication model to estimate storage device lifecycle and failure, in accordance with embodiments described herein. System 1400 includes a failure prediction system 1405 which may be any type of computing system, device, or entity capable of deploying and executing failure prediction model 1330. As depicted in FIG. 14, failure prediction system 1405 may be external to storage devices 1406 and may also be separate from storage systems 1402 and storage nodes 1404, or deployed within one or more monitored storage systems 1402. For example, failure prediction system 1405 may be deployed within a cloud computing environment. The failure prediction system 1405 may include a data collection component 1410 to collect, retrieve, receive, or otherwise obtain storage operation metrics 1412 and device health metrics 1414 from one or more of storage systems 1402, storage nodes 1404, storage devices 1406, and storage components 1408, as described above. The failure prediction system 1405 may then input the storage operation metrics 1412 and device health metrics 1414 collected for storage devices 1406 and/or storage components 1408 to the failure prediction model 1330. In some embodiments, the storage operation metrics 1412 and device health metrics 1414 may be pre-processed to remove anomalous data, redundant data, or any other data unused or irrelevant to the failure prediction model 1330. The failure prediction model 1330 may generate an output indicating an estimated time to failure 1420 that a corresponding storage device 1406 or storage component 1408 may fail. Additionally, if the predicted time to failure is imminent (e.g., less than a threshold amount of time), then the failure prediction system may further provide a notification of the imminent failure 1422.

In some embodiments, the failure prediction model 1330 may include a two-tiered system in which a first machine learning model receives the storage operation metrics 1412 and device health metrics 1414 and outputs a reduced number of metrics or outputs that are then input into another machine learning model, or a tuned heuristic algorithm. For example, if the outputs of the first machine learning model are provided to another machine learning model, then that second machine learning model may be trained in conjunction with the first machine learning model to receive the reduced set of metrics or outputs and to generate the estimated time to failure 1420. In the embodiments in which the outputs of the first machine learning model are provided as inputs to a heuristic algorithm, the outputs of the first machine learning model may include a set of reduced operating metrics and health metrics from the entire set of storage operation metrics 1412 and device health metrics 1414 provided to the first machine learning model. In particular, the outputs should match the necessary inputs for the heuristic algorithm. Accordingly, the heuristic algorithm may then calculate an estimated time to failure 1420 of a storage node, storage device, storage component, etc.

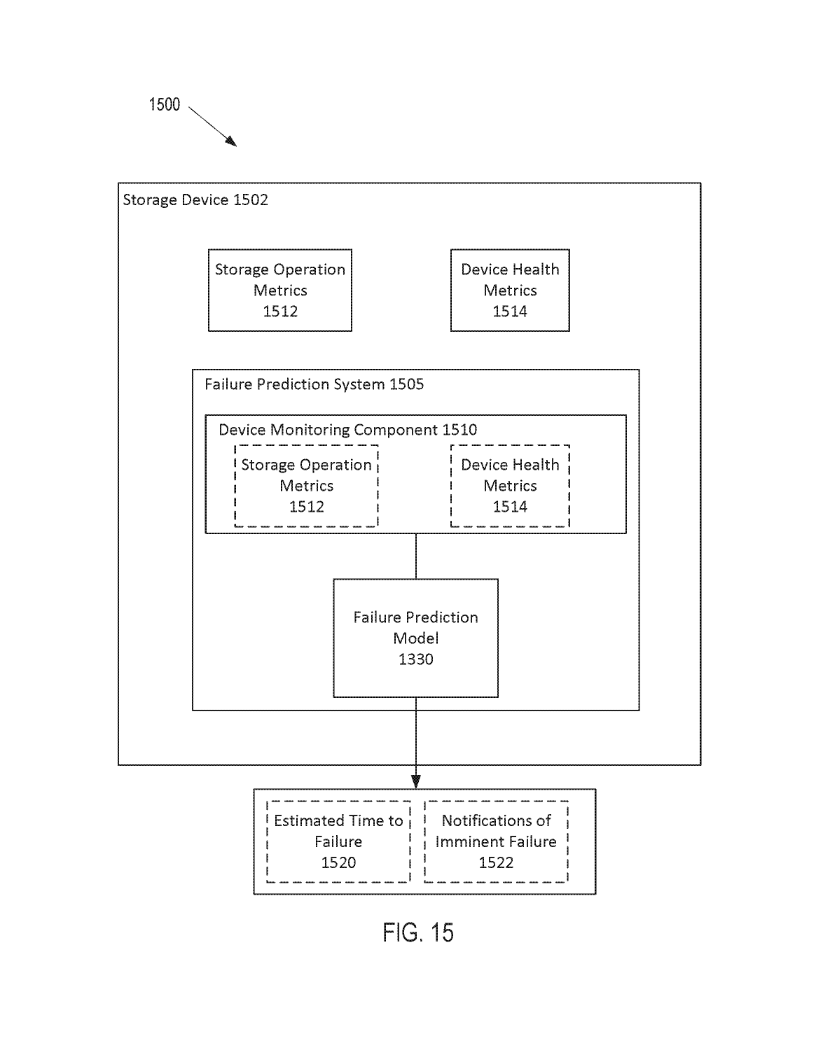

FIG. 15 is a block illustrating a local deployment 1500 of a failure prediction model to a storage device to estimate lifecycle and failure of the storage device, in accordance with embodiments described herein. As depicted, the failure prediction system 1505 and the failure prediction model 1330 may be deployed locally to a storage device 1502 (e.g., may be executed within the storage device 1502). The storage device 1502 may collect storage operation metrics 1512 and health metrics 1514 for the storage device 1502 and for various storage components of the storage device (e.g., die, package, capacitor, device controller, and so forth). For example, the failure prediction system 1505 may include a device monitoring component 1510 which retrieves, receives, or otherwise obtains the storage operation metrics 1512 and the device health metrics 1514 during operation of the storage device 1502. The failure prediction system 1505 may provide the storage operation metrics 1512 and device health metrics 1514 as inputs to the failure prediction model 1330. The failure prediction model 1330 may then produce an estimated time to failure 1520 for the storage device 1502. Additionally, the failure prediction system 1505 may generate notifications of imminent failure 1522 (e.g., to a storage system administrator) indicating that the storage device 1502 or components of the storage device 1502 are in danger of imminent failure. The failure prediction model 1330 may be a trained machine learning model (e.g., a configured recurrent neural network trained to infer and estimate a time to failure of a storage device) or may be an algorithm that is optimized by a machine learning model to estimate time to failure. For example, a failure prediction algorithm may utilize fewer compute resources to operate, and may therefore be deployed to storage devices with limited compute resources.

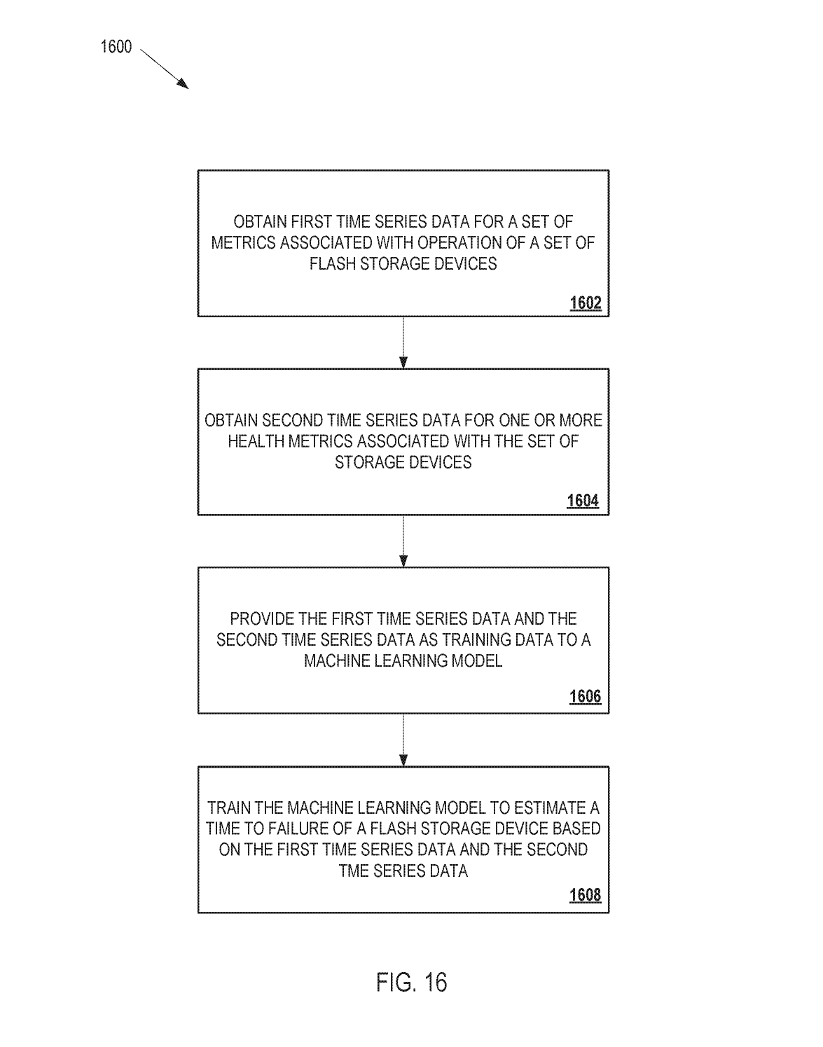

FIG. 16 is a flow diagram of a method of training a neural network to predict storage device lifecycle and failure, in accordance with embodiments described herein. In general, the method 1600 may be performed by processing logic that may include hardware (e.g., processing device, circuitry, dedicated logic, programmable logic, microcode, hardware of a device, integrated circuit, etc.), software (e.g., instructions run or executed on a processing device), or a combination thereof. In some embodiments, processing logic of a processing device of model training system 1305 of FIG. 13A may perform the method 1600.

Method 1600 may begin at block 1602, where the processing logic obtains first time series data for a set of metrics associated with operation of a set of flash storage devices. In some embodiments, the metrics may include operating metrics measuring various operations and conditions. Additionally, the metrics may include environmental metrics obtained, for example, from sensors deployed to the device or components of the device. For example, the operating metrics may include voltage table changes, read errors that can be corrected using ECC, read errors that can be corrected after adjusting voltage levels, including the history of the specific voltage levels for writes and for reads and which voltage levels did and did not work for reads, read patterns, power failure/restarts with included clock values or with measured durations of run-time and down time, programming modes, patterns of programming the flash, patterns of erases, latency jitters in programming or erase operations or in read requests, wear level imbalances, interrupted programs or erases, or any other monitored operating metrics. Similarly, the data sampled may further include a position or location within a flash strings that a failed component is located and the position or location within an overall geometry of a storage component and storage device (e.g., NAND geometry), the states of neighboring components at a time of failure of a component, time intervals between PE cycles, and counts of reads including read disturb tracking. Furthermore, as storage devices are tuned during operation, data may be read and flash pages or flash word lines that are operating abnormally can be identified and tracked for further anomalous behavior. Another aspect that may be tracked includes power loss protection (PLP) health of the storage devices. Additionally, the environmental metrics may include temperature, humidity, electromagnetic fields, acoustic levels (e.g., noise), vibration, or any other environmental conditions during operation of the device and components of the device.

At block 1604, processing logic obtains second time series data for one or more health metrics associated with the set of storage devices. The one or more health metrics may include device or component wear levels, device or component failures, indications of device or component data loss, or any other indicators of device health and remaining device lifespan.

In some embodiments health metrics may include a profile of voltage tuning results for various components. For example, as storage devices are tuned during operation, data may be read and pages or word lines that are operating abnormally can be identified and tracked based on the read data. For example, when tuning voltage levels for a block, NAND characterization may be used to identify pages or word lines that are likely to be weak spots. The pages or word lines may then be tracked for a period of time after the tuning to determine the quality of the tuning (e.g., if the tuning was poor) which may indicate degradation of tuned voltage levels. Pages or word lines identified as yielding poor results from the tuning can then be used as part of a profile history that can be used herein to further train a model or be used to infer a time to failure, as described herein. Another aspect that may be tracked includes power loss protection (PLP) health of storage devices (e.g., how often PLP is necessary for a device and its components and the effectiveness of the PLP operations). For example, embodiments may monitor particular capacitor modules, models, or batches of capacitors (supercapacitor, regular capacitor, etc.), which may be used to detect patterns of certain variations of modules failing earlier than others. In particular, failures of particular modules, models, or batches of capacitors may be identified as being tied with other tracked parameters that may result in the failures, or degraded performance, of different module variants. Thus, PLP may assist with recognition of patterns of the collected data that indicate failures for particular capacitor modules, models, batches, etc.

At block 1606, processing logic provides the first time series data and the second time series data as training data to a machine learning model. In some embodiments, the machine learning model includes a time series based machine learning model. For example, the machine learning model may include a recurrent neural network (RNN).

At block 1608, processing logic trains the machine learning model to estimate a time to failure of a flash storage device based on the first time series data and the second time series data. In some embodiments, the machine learning model may be deployed to storage devices to monitor and predict lifespan of the storage device and the components of the storage device. In other embodiments the trained machine learning model may be deployed to a device, platform, or other computing system external to the storage devices to monitor one or more storage devices via the operating metrics and health metrics collected for each storage device to estimate a time to failure. For example, processing logic may deploy the trained machine learning model may be deployed to monitor a flash storage device and collect operating metrics and health metrics for the flash storage device. The processing logic may further provide the operating metrics and the health metrics for the flash storage device to the trained machine learning model and receive, from the machine learning model, an estimated time of failure for the flash storage device. The processing logic may then provide a notification of a potential or imminent failure of the flash storage device, or component of the flash storage device, based on the estimated time to failure being below a threshold time to failure.

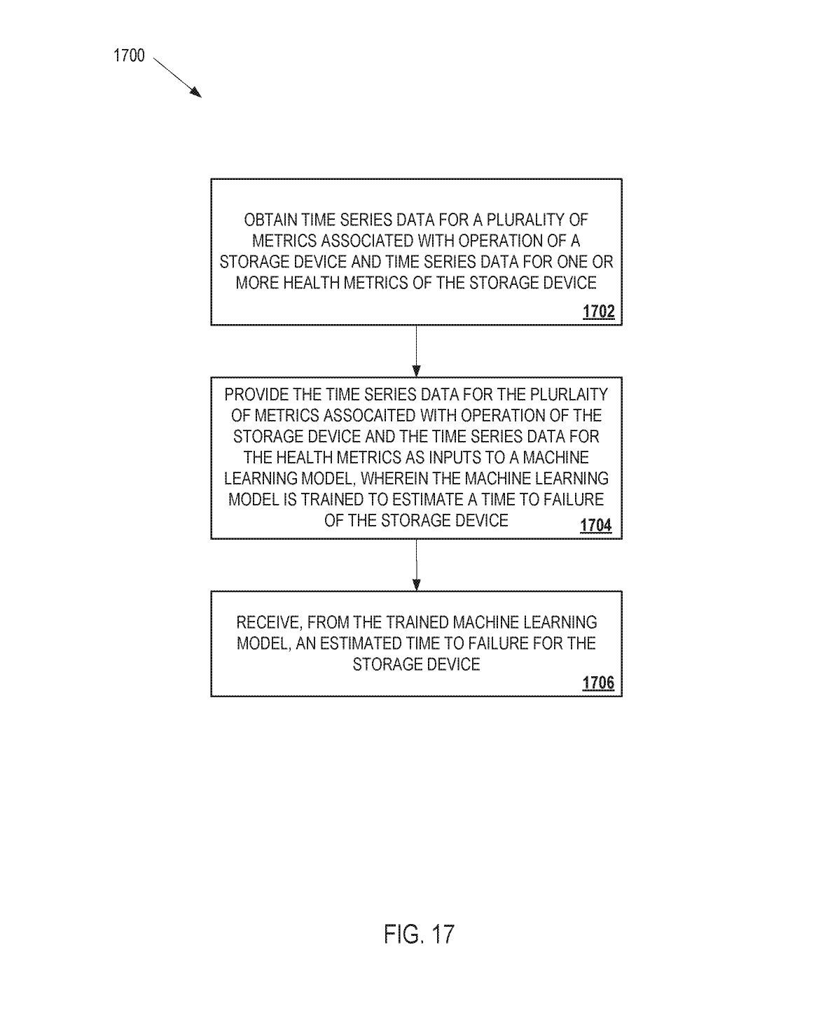

FIG. 17 is a flow diagram of a method of applying a trained neural network to storage device data to predict storage device lifecycle and failure, in accordance with embodiments described herein. In general, the method 1700 may be performed by processing logic that may include hardware (e.g., processing device, circuitry, dedicated logic, programmable logic, microcode, hardware of a device, integrated circuit, etc.), software (e.g., instructions run or executed on a processing device), or a combination thereof. In some embodiments, processing logic of a processing device of failure prediction system 1405 of FIG. 14 or failure prediction system 1505 of FIG. 15 may perform the method 1700.

Method 1700 may begin at block 1702, where the processing logic obtains first time series data for a set of metrics associated with operation of a storage device, or storage component, and time series data for one or more health metrics of the storage device.

At block 1704, processing logic provides the first time series data and the second time series data as inputs to a machine learning model, wherein the machine learning model is trained to estimate a time to failure of the storage device, or storage component.

At block 1706, processing logic receives, from the trained machine learning model, as estimated time to failure for the storage device.

Storage systems that distribute data across a plurality of storage devices commonly rely on redundancy mechanisms, such as striping with parity or erasure coding, to tolerate individual device failures. Such systems may provide for recovery of lost data as long as no more than a threshold number of devices supporting a data stripe fails (e.g., based on the particular erasure coding scheme or number of parity bits). Such mechanisms typically assume that failures of different devices occur independently. In practice, however, storage devices that participate in the same stripe or segment are often subject to correlated behavior due to synchronized write operations, shared software execution timing, or uniform lifecycle management policies. For example, data shards written contemporaneously to different devices may share similar block ages, page offsets, or refresh schedules. As a result, time-based failure mechanisms, including retention degradation, open-block aging, or firmware-level execution faults, may manifest across multiple devices within a similar time window, reducing the effectiveness of redundancy and increasing the risk of unrecoverable data loss (e.g., where the number of device failures exceed the threshold for recovery supported by the erasure coding and parity bits).

Embodiments described herein address the above, and other deficiencies, by providing a storage system that reduces such temporal correlation by varying, on a per-shard basis, one or more data storage parameters associated with storing shards of a stripe across a plurality of storage devices. The varied data storage parameters may include any storage parameters that may affect a time at which a failure may occur for a device or the data of a stripe. For example the storage parameters that could be varied may include an initial block offsets at which shards are written, timing of data migration or refresh operations, initial age values associated with stored shards, block-closure timing for open blocks, or timing of device startup or software execution. By introducing controlled variation in these parameters, shards that logically belong to the same stripe may be stored, refreshed, or managed according to different temporal characteristics, even though they remain logically associated for purposes of data reconstruction. In some embodiments, such variation may be randomized, pseudo-randomized, or deterministically staggered, and may be applied at write time, during subsequent lifecycle management operations, or both.

The introduction of per-shard variation in data storage parameters therefore reduces the likelihood that multiple shards of a stripe experience adverse conditions at substantially the same time. As a result, correlated error events across devices are less likely to coincide, improving the probability that redundancy mechanisms can successfully reconstruct data when a device error occurs. Embodiments may thus increase overall system reliability without requiring additional redundancy, additional storage capacity, or changes to logical data layouts. Further, the described techniques may be implemented by a storage-system controller, a device-level controller, or a combination thereof, and may operate transparently to higher-level software, thereby providing improved fault tolerance while maintaining compatibility with existing storage architectures and data protection schemes.

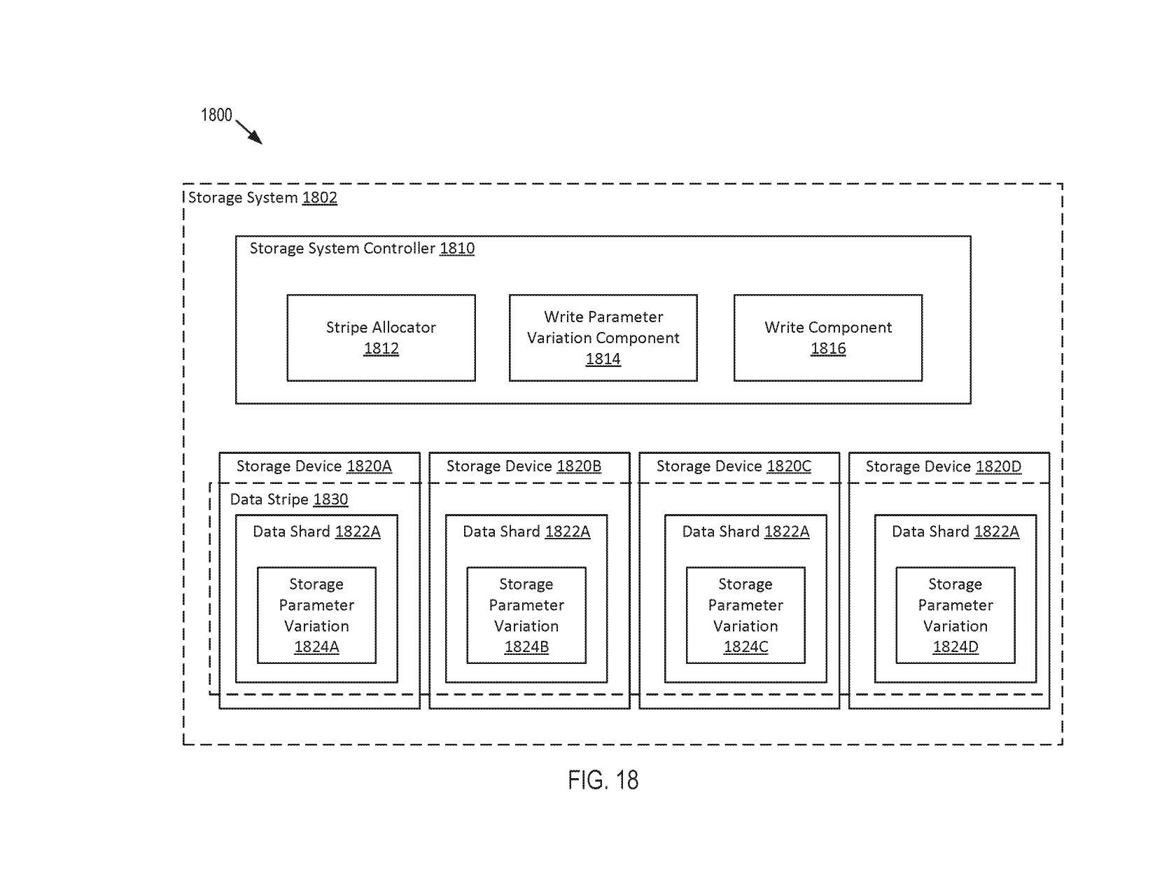

FIG. 18 illustrates a system 1800 configured to reduce temporal correlation among data shards stored across a plurality of storage devices. The system 1800 may include a storage system 1802 having a storage-system controller 1810 coupled to a plurality of storage devices 1820A–1820D. In some embodiments, the storage system 1802 may be implemented as a storage array, a storage cluster, or another distributed storage architecture in which user data is stored using striping, parity, or erasure coding across multiple devices. The storage-system controller 1810 may be implemented using one or more processors executing system-level storage software, firmware, or a combination thereof, and may coordinate write operations, data placement, and lifecycle management operations across the storage devices 1820A–1820D.

In some embodiments, the storage-system controller 1810 may include a stripe allocator 1812, a storage-parameter variation component 1814, and a write component 1816. The stripe allocator 1812 may receive data to be stored and to divide the data into a plurality of data shards 1822A that collectively form a data stripe 1830. In some embodiments, the stripe allocator 1812 may also generate parity or erasure-coded shards, select participating storage devices based on availability or failure-domain constraints, and determine a logical association among the shards of the data stripe 1830 for purposes of data reconstruction. The stripe allocator 1812 may operate in coordination with metadata structures maintained by the storage system 1802 to track shard placement, device assignments, and stripe membership.

In some embodiments, the storage-parameter variation component 1814 may determine, for each data shard 1822A, one or more data storage parameters associated with storing and managing the corresponding shard at its assigned storage device. In some embodiments, the data storage parameters may include write-time parameters, such as an initial offset within a block or erase unit at which the data shard is written, padding or dummy data insertion, or selection of a particular block or allocation unit. In some embodiments, the data storage parameters may include lifecycle parameters, such as an initial age value associated with the data shard, timing of block closure for blocks that remain open during sequential writes, timing of data migration operations, or timing of refresh or read-refresh operations associated with retention management. In some embodiments, the data storage parameters may include execution-timing parameters, such as timing of device startup, timing of software execution on device controllers, or scheduling of background maintenance operations. The storage-parameter variation component 1814 may determine values for any combination of such parameters using randomized, pseudo-randomized, or deterministically staggered techniques, and may ensure that different data shards 1822A of the same data stripe 1830 are associated with different temporal characteristics. In some embodiments, the storage-parameter variation component 1814 may vary each parameter, a subset of parameters, a single parameter, or any variation of parameters to minimize or reduce the temporal correlation of failure modes of the shards and devices across which the shards are stored.

In some embodiments, the write component 1816 may cause the data shards 1822A to be written to the storage devices 1820A–1820D in accordance with the data storage parameters determined by the storage-parameter variation component 1814. In some embodiments, the write component 1816 may issue write commands, block allocation commands, or metadata updates to the storage devices 1820A–1820D that reflect different offsets, block selections, or timing characteristics for different shards. In further embodiments, the write component 1816 may schedule or trigger subsequent lifecycle management operations, such as refresh or migration, according to different schedules for different shards, even though the shards are logically associated as part of the same data stripe 1830.

In some embodiments, each storage device 1820A–1820D may store a corresponding data shard 1822A of the data stripe 1830 and may apply a corresponding storage-parameter variation 1824A–1824D when storing or managing the data shard. In some embodiments, the storage-parameter variations 1824A–1824D may be applied by device-level controllers executing firmware or software on the storage devices 1820A–1820D. In other embodiments, the storage-parameter variations 1824A–1824D may be enforced by the storage-system controller 1810 through system-level control of block allocation, write ordering, refresh scheduling, or migration timing. The storage-parameter variations 1824A–1824D may differ among the storage devices such that data shards 1822A of the same data stripe 1830 are written at different times, begin at different block offsets, age differently over time, or are refreshed or migrated at different times.

By applying different storage-parameter variations 1824A–1824D to data shards 1822A that are logically associated within the same data stripe 1830, the system 1800 reduces temporal correlation among the shards stored across the plurality of storage devices 1820A–1820D. As a result, time-based failure mechanisms, such as retention degradation, open-block aging, or software-level execution faults, are less likely to affect multiple shards of the same stripe at substantially the same time. In this manner, the system 1800 improves the effectiveness of redundancy mechanisms, such as parity or erasure coding, without increasing redundancy overhead or altering logical data layouts, thereby improving long-term system reliability.

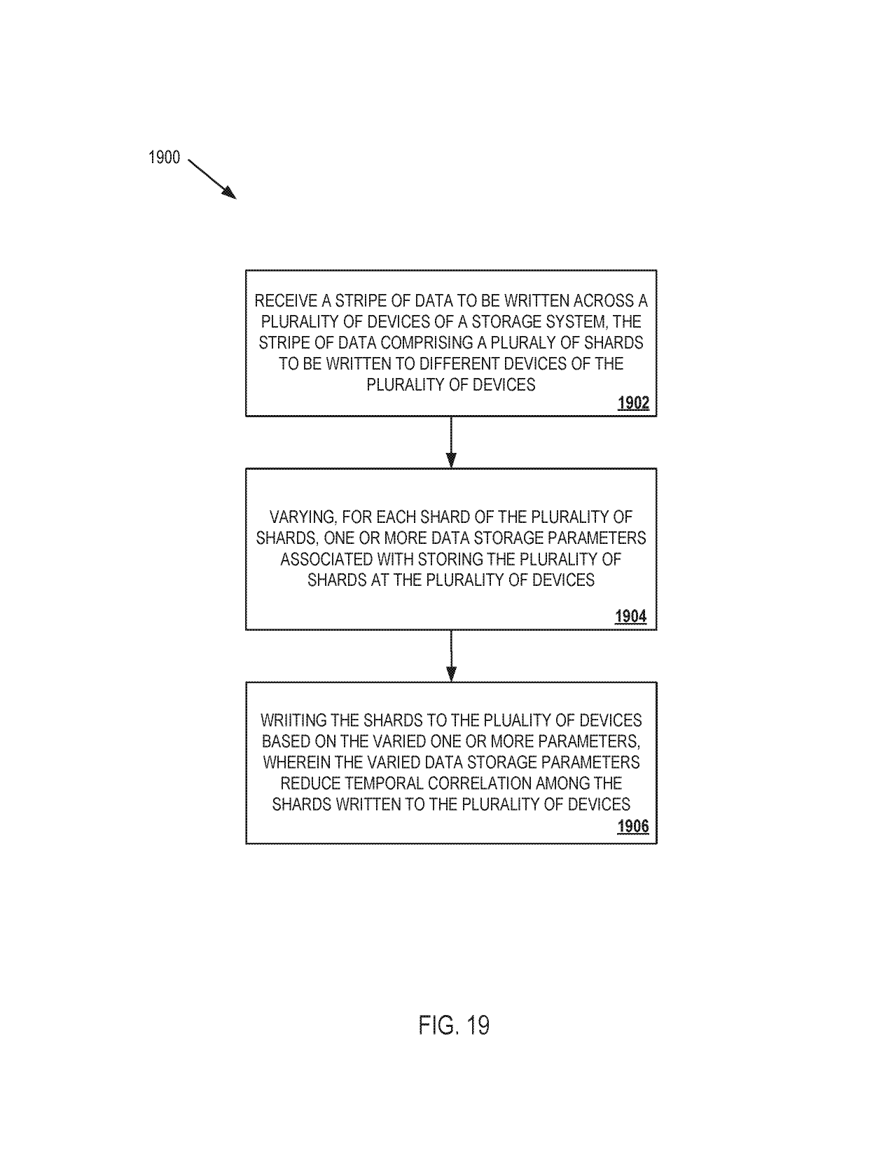

FIG. 19 is a flow diagram illustrating a method 1900 for reducing temporal correlation among data shards written across a plurality of storage devices of a storage system. The method 1900 may be performed by processing logic that comprises hardware, software, firmware, or a combination thereof. In some embodiments, the method 1900 may be performed by a storage-system controller, such as the storage-system controller 1810 of FIG. 18, operating alone or in cooperation with one or more device-level controllers of a plurality of storage devices. In further embodiments, portions of the method 1900 may be performed by distributed components of a storage system, including system-level software and device-resident firmware.

Method 1900 begins at block 1902, where processing logic receives a stripe of data to be written across a plurality of storage devices of a storage system, the stripe of data comprising a plurality of shards to be written to different devices of the plurality of storage devices. In some embodiments, receiving the stripe of data may include receiving user data, system data, or metadata that is to be stored using striping, parity, or erasure coding across multiple storage devices. For example, the data may first be separated into segments of data which may then be striped across a plurality of storage devices. The stripe of data may be divided into a plurality of shards, where each shard represents a portion of the data or a parity shard storing parity bits associated with the stripe. Each shard may be assigned to a different storage device of the plurality of storage devices, such that the stripe may be reconstructed (e.g., based on the parity bits) even if one or more devices become unavailable. In some embodiments, receiving the stripe of data may further include selecting the participating devices based on availability, failure-domain constraints, or storage policies maintained by the storage system.

At block 1904, processing logic varies, for each shard of the plurality of shards, one or more data storage parameters associated with storing the plurality of shards at the plurality of storage devices. In some embodiments, varying the one or more data storage parameters may include determining different write-time parameters for different shards, such as different initial offsets within blocks or allocation units of the respective storage devices, insertion of padding or dummy data, or selection of different blocks or erase units. In some embodiments, varying the one or more data storage parameters may include determining different lifecycle-related parameters for different shards, such as different initial age values associated with the shards, different timing for block closure of open blocks, or different timing for data migration or refresh operations associated with retention management. In further embodiments, varying the one or more data storage parameters may include determining different execution-timing parameters, such as different device startup timing, different scheduling of software execution, or different timing of background maintenance operations across the plurality of storage devices. The variation of data storage parameters may be randomized, pseudo-randomized, or deterministically staggered, and may be performed such that shards belonging to the same stripe are associated with different temporal characteristics.

At block 1906, processing logic writes the shards to the plurality of storage devices based on the varied one or more data storage parameters, wherein the varied data storage parameters reduce temporal correlation among the shards written to the plurality of storage devices. In some embodiments, writing the shards may include issuing write commands to the plurality of storage devices that cause the shards to be written at different offsets, at different times, or into different blocks according to the varied data storage parameters. In some embodiments, writing the shards may further include initiating or scheduling subsequent lifecycle management operations, such as refresh or migration, according to different schedules for different shards. By writing and managing the shards based on the varied data storage parameters, the shards of the same stripe are less likely to share the same age, block position, or maintenance timing over time. As a result, time-based failure mechanisms are less likely to affect multiple shards of the stripe at substantially the same time, thereby reducing temporal correlation among the shards and improving the likelihood that redundancy mechanisms of the storage system can successfully recover data in the presence of device errors.

It should be understood that although the terms first, second, etc. may be used herein to describe various steps or calculations, these steps or calculations should not be limited by these terms. These terms are only used to distinguish one step or calculation from another. For example, a first calculation could be termed a second calculation, and, similarly, a second step could be termed a first step, without departing from the scope of this disclosure. As used herein, the term “and/or” and the “/” symbol includes any and all combinations of one or more of the associated listed items.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

With the above embodiments in mind, it should be understood that the embodiments might employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing. Any of the operations described herein that form part of the embodiments are useful machine operations. The embodiments also relate to a device or an apparatus for performing these operations. The apparatus can be specially constructed for the required purpose, or the apparatus can be a general-purpose computer selectively activated or configured by a computer program stored in the computer. In particular, various general-purpose machines can be used with computer programs written in accordance with the teachings herein, or it may be more convenient to construct a more specialized apparatus to perform the required operations.

A module, an application, a layer, an agent or other method-operable entity could be implemented as hardware, firmware, or a processor executing software, or combinations thereof. It should be appreciated that, where a software-based embodiment is disclosed herein, the software can be embodied in a physical machine such as a controller. For example, a controller could include a first module and a second module. A controller could be configured to perform various actions, e.g., of a method, an application, a layer or an agent.

The embodiments can also be embodied as computer readable code on a tangible non-transitory computer readable medium. The computer readable medium is any data storage device that can store data, which can be thereafter read by a computer system. Examples of the computer readable medium include hard drives, network attached storage (NAS), read-only memory, random-access memory, CD-ROMs, CD-Rs, CD-RWs, magnetic tapes, and other optical and non-optical data storage devices. The computer readable medium can also be distributed over a network coupled computer system so that the computer readable code is stored and executed in a distributed fashion. Embodiments described herein may be practiced with various computer system configurations including hand-held devices, tablets, microprocessor systems, microprocessor-based or programmable consumer electronics, minicomputers, mainframe computers and the like. The embodiments can also be practiced in distributed computing environments where tasks are performed by remote processing devices that are linked through a wire-based or wireless network.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

In various embodiments, one or more portions of the methods and mechanisms described herein may form part of a cloud-computing environment. In such embodiments, resources may be provided over the Internet as services according to one or more various models. Such models may include Infrastructure as a Service (IaaS), Platform as a Service (PaaS), and Software as a Service (SaaS). In IaaS, computer infrastructure is delivered as a service. In such a case, the computing equipment is generally owned and operated by the service provider. In the PaaS model, software tools and underlying equipment used by developers to develop software solutions may be provided as a service and hosted by the service provider. SaaS typically includes a service provider licensing software as a service on demand. The service provider may host the software, or may deploy the software to a customer for a given period of time. Numerous combinations of the above models are possible and are contemplated.

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware--for example, circuits, memory storing program instructions executable to implement the operation, etc. Reciting that a unit/circuit/component is “configured to” perform one or more tasks, or is “configurable to” perform one or more tasks, is expressly intended not to invoke 35 U.S.C. 112, sixth paragraph, for that unit/circuit/component. Additionally, “configured to” or “configurable to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks. “Configurable to” is expressly intended not to apply to blank media, an unprogrammed processor or unprogrammed generic computer, or an unprogrammed programmable logic device, programmable gate array, or other unprogrammed device, unless accompanied by programmed media that confers the ability to the unprogrammed device to be configured to perform the disclosed function(s).

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

What is claimed is:

1. A method comprising:
receiving a stripe of data to be written across a plurality of storage devices, the stripe of data comprising a plurality of shards to be written to different devices of the plurality of storage devices;
varying, for each shard of the plurality of shards, one or more data storage parameters associated with storing the plurality of shards at the plurality of storage devices; and
writing the plurality of shards to the plurality of storage devices based on the varied one or more data storage parameters, wherein the varied one or more data storage parameters reduce temporal correlation among the plurality of shards written to the plurality of storage devices.

2. The method of claim 1, wherein varying the one or more data storage parameters comprises varying an initial offset associated with a block of each device to which a corresponding shard of the stripe of data is written.

3. The method of claim 1, wherein varying the one or more data storage parameters comprises varying timing of data migration or refresh associated with the plurality of shards written to the plurality of storage devices.

4. The method of claim 3, wherein varying the timing of data migration comprises randomizing an initial age associated with the plurality of shards when written to the plurality of storage devices.

5. The method of claim 3, wherein varying the timing of refresh comprises randomizing timing of one or more subsequent refresh events associated with the plurality of shards written to the plurality of storage devices.

6. The method of claim 1, wherein varying the one or more data storage parameters comprises randomizing block-closure timing for blocks associated with the plurality of shards written to the plurality of storage devices.

7. The method of claim 1, further comprising randomizing device startup timing or software execution timing across the plurality of storage devices.

8. A non-transitory computer-readable storage medium having instructions stored thereon which, when executed by a processing device, cause the processing device to:
receive a stripe of data to be written across a plurality of storage devices of a storage system, the stripe of data comprising a plurality of shards to be written to different devices of the plurality of storage devices;
vary, for each shard of the plurality of shards, one or more data storage parameters associated with storing the plurality of shards at the plurality of storage devices; and
write the plurality of shards to the plurality of storage devices based on the varied one or more data storage parameters, wherein the varied one or more data storage parameters reduce temporal correlation among the plurality of shards written to the plurality of storage devices.

9. The non-transitory computer-readable storage medium of claim 8, wherein to vary the one or more data storage parameters, the processing device is configured to:
vary an initial offset associated with a block of each device to which a corresponding shard of the stripe of data is written.

10. The non-transitory computer-readable storage medium of claim 8, wherein to vary the one or more data storage parameters, the processing device is configured to:
vary timing of data migration or refresh associated with the plurality of shards written to the plurality of storage devices.

11. The non-transitory computer-readable storage medium of claim 10, wherein to vary the timing of data migration, the processing device is configured to:
randomize an initial age associated with the plurality of shards when written to the plurality of storage devices.

12. The non-transitory computer-readable storage medium of claim 10, wherein to vary the timing of refresh, the processing device is configured to:
randomize timing of one or more subsequent refresh events associated with the plurality of shards written to the plurality of storage devices.

13. The non-transitory computer-readable storage medium of claim 8, wherein to vary the one or more data storage parameters, the processing device is configured to:
randomize block-closure timing for blocks associated with the plurality of shards written to the plurality of storage devices.

14. The non-transitory computer-readable storage medium of claim 8, further comprising randomizing device startup timing or software execution timing across the plurality of storage devices.

15. A storage system comprising:
a plurality of storage devices; and
a storage system controller, operatively coupled to the plurality of storage devices, configured to:
receive a stripe of data to be written across the plurality of storage devices, the stripe of data comprising a plurality of shards to be written to different devices of the plurality of storage devices;
vary, for each shard of the plurality of shards, one or more data storage parameters associated with storing the plurality of shards at the plurality of storage devices; and
write the plurality of shards to the plurality of storage devices based on the varied one or more data storage parameters, wherein the varied one or more data storage parameters reduce temporal correlation among the plurality of shards written to the plurality of storage devices.

16. The system of claim 15, wherein to vary the one or more data storage parameters, the processing device is configured to:
vary an initial offset associated with a block of each device to which a corresponding shard of the stripe of data is written.

17. The system of claim 15, wherein to vary the one or more data storage parameters, the processing device is configured to:
vary timing of data migration or refresh associated with the plurality of shards written to the plurality of storage devices.

18. The system of claim 17, wherein to vary the timing of data migration, the processing device is configured to:
randomize an initial age associated with the plurality of shards when written to the plurality of storage devices.

19. The system of claim 17, wherein to vary the timing of refresh, the processing device is configured to:
randomize timing of one or more subsequent refresh events associated with the plurality of shards written to the plurality of storage devices.

20. The system of claim 15, wherein to vary the one or more data storage parameters, the processing device is configured to:
randomize block-closure timing for blocks associated with the plurality of shards written to the plurality of storage devices.
